(19) United States
(12) Patent Application Publication
(10) Pub. No.: US 2026/0182243 A1
(43) Pub. Date: Jun. 25, 2026

(54) MATERIALS FOR ORGANIC ELECTROLUMINESCENT DEVICES

(71) Applicant: Merck Patent GMBH, Darmstadt (DE)

(72) Inventors: Hanny Han, Shanghai (CN); Haitao Wang, Shanghai (CN); Tobias Grossmann, Shanghai (CN); Martin Kraska, Fischbachtal (DE)

(21) Appl. No.: 19/124,151

(22) PCT Filed: Oct. 31, 2023
(86) PCT No.: PCT/EP2023/080314

§ 371 Date: Apr. 24, 2025

(30) Foreign Application Priority Data
Nov. 4, 2022 (CN) 202211380569.6

(51) Int. Cl. H10K 85/60; H10K 50/11; H10K 85/30

(52) U.S. Cl. CPC H10K 85/631; H10K 50/11; H10K 85/342; H10K 85/633; H10K 85/6572

(57) ABSTRACT

The present invention relates to an electronic device comprising at least at least two subpixels, where the subpixels comprise a common hole-transport layer c-HTL and different electron-blocking layers EBL1 and EBL2, where the interface charge density ICD at the interface of c-HTL/EBL1 and c-HTL/EBL2, fulfils specific criteria.

The present invention relates to an electronic device comprising at least at least two subpixels, where the subpixels comprise a common hole-transport layer c-HTL and different electron-blocking layers EBL₁ and EBL₂, where the interface charge densities ICDs at the interface of c-HTL/EBL₁ and at the interface c-HTL/EBL₂ fulfils specific criteria.

The development of organic light-emitting diodes (OLEDs) for use in small portable devices like mobile phones and television screens is currently the subject of intensive search. The self-emissive nature of OLEDs is a highly desirable feature for display applications in a general way.

There are different types of OLED construction. For example, full-color OLED pixels can be fabricated by vertical stacking of a red-, green-, and blue-emitting unit. Full-color OLED pixels can also be fabricated by placing multiple, single-OLED stacks in a side-by-side configuration within a single pixel. More particularly, it is frequent in flat-panel displays, that each pixel consists of laterally separated red, green, and blue subpixels in a side-by-side geometry as disclosed, for example, in US 2004/0108818 A1, US2006/0244696 A1.

However, in case of OLED displays, side-by-side layouts can lead to crosstalk phenomenons among the subpixels. More particularly, undesired charge transport between two adjacent subpixels can occur, leading to a deterioration of the grey-scale at low luminescence of the pixel, e.g. unwanted red light emission even when only blue subpixels are switched on. In some cases, lateral conductivity can lead to a slight glowing of a switched-off subpixel due to a lateral charge transport from an adjacent switched-on subpixel.

A common hole-transport layer with low lateral conductivity can reduce the lateral current crossing between the subpixels. However, it is quite common that each subpixel also comprises an individual electron-blocking layer deposited on the hole-transport layer. The different electron-blocking layers might lead to lateral current crossing between the subpixels. More particularly, when the patterning of the subpixels is performed using a fine metal shadow mask technology, the alignement accuracy of the metal mask might be not perfect, so that the current can also cross the electron-blocking layer of an adjacent subpixel.

Therefore, further improvements are still necessary with respect to the fabrication of OLEDs, in particular with respect to the fabrication of RGB devices based on a side-by-side pixel layout. Of particular importance in this connection are the lifetime, the efficiency, the operating voltage, lateral charge transport properties and of course the colour gamut of the OLEDs.

The present invention is thus based on the technical object of providing electronic devices having pixels comprising subpixels placed in a side-by-side configuration. The present invention is also based on the technical object of providing compounds which are suitable for these electronic devices. Furthermore, the present invention is based on the technical object of providing processes for the manufacturing of these electronic devices.

In investigations on novel electronic devices having pixels or/and subpixels placed in a side-by-side geometry, it has now been found, that the electroluminescent devices as defined below are eminently suitable for use in display applications. In particular, they achieve one or more, preferably all, of the above-mentioned technical objects.

Thus, the invention relates to an electronic device comprising at least one pixel comprising:
a first subpixel comprising in the following sequence: an anode, at least one hole transport layer and an electron-blocking layer EBL₁,
a second subpixel comprising in the following sequence: an anode, at least one hole transport layer and an electron-blocking layer EBL₂,
where the at least one hole-transport layer in the first and second subpixel is a common hole-transport layer c-HTL, and the electron-blocking layer EBL₁ and layer EBL₂ adjoin the layer c-HTL, and
where the interface charge densities ICD₁ and ICD₂ fulfill the following conditions (1) and (2):

$$0 < {ICD}_{1} < 10 mC \cdot {m}^{- 2} \qquad ( 1 )$$

$$0 < {ICD}_{2} < 10 mC \cdot {m}^{- 2} \qquad ( 2 )$$

where
ICD₁ is the difference between the surface charge density of layer EBL₁ and the surface charge density of layer c-HTL;
ICD₂ is the difference between the surface charge density of the electron-blocking layer EBL₂ and the surface charge density of layer c-HTL;

$${ICD}_{1} = S C {D}_{E B L 1} - S C {D}_{c - HTL}$$

$${ICD}_{2} = S C {D}_{E B L 2} - S C {D}_{c - HTL}$$

where the surface charge density SCD of a layer is determined by dielectric spectroscopy measurements.

The surface charge density SCD of a layer comprising n materials corresponds to the sum of the surface charge densities SCDᵢ of each material i present in the corresponding layer multiplied by their proportion αᵢ in the layer:

$$S C D = {\sum }_{i = 1}^{n} {α}_{i} * {SCD}_{i}$$

where
αᵢ is the proportion of the material i in the corresponding layer by weight, based on the total weight of the corresponding layer; and where
SCDᵢ is the surface charge density of the material i as determined by dielectric spectroscopy measurements.

The surface charge density, SCDᵢ of a given material i is obtained from dielectric spectroscopy measurements, more particularly from dielectric spectroscopy measurements in concentration series and extrapolated to pure layers. The applied experimental method is based on the method described in Nowy et al., Impedance spectroscopy as a probe for the degradation of organic light-emitting diodes. J. Appl. Phys. 107, 1-9 (2010). The determination of the surface charge density of a layer is explained in more details in the examples section below.

Preferably, EBL₁ and EBL₂ are different electron-blocking layers.

Preferably, the interface charge density ICD₁ and the interface charge density ICD₂ as defined above fulfill the following conditions (1a) and/or (2a)

$$0 < {ICD}_{1} < 0.8 mC \cdot {m}^{- 2} \qquad ( 1 a )$$

$$0 < {ICD}_{2} < 0.8 mC \cdot {m}^{- 2} . \qquad ( 2 a )$$

More preferably, the interface charge density ICD₁ and the interface charge density ICD₂ as defined above fulfill the following conditions (1b) and/or (2b):

$$0 < {ICD}_{1} < 0.6 mC \cdot {m}^{- 2} \qquad ( 1 b )$$

$$0 < {ICD}_{2} < 0.6 mC \cdot {m}^{- 2} . \qquad ( 2 b )$$

Even more preferably, the interface charge density ICD₁ and the interface charge density ICD₂ as defined above fulfill the following conditions (1c) and/or (2c):

$$0 < {ICD}_{1} < 0.4 mC \cdot {m}^{- 2} \qquad ( 1 c )$$

$$0 < {ICD}_{2} < 0.4 mC \cdot {m}^{- 2} . \qquad ( 2 c )$$

Particularly more preferably, the interface charge density ICD₁ and the interface charge density ICD₂ as defined above fulfill the following conditions (1d) and/or (2d):

$$0 < {ICD}_{1} < 0.2 mC \cdot {m}^{- 2} \qquad ( 1 c )$$

$$0 < {ICD}_{2} < 0.2 mC \cdot {m}^{- 2} . \qquad ( 2 c )$$

It is preferred that the following condition (3) is fulfilled:

$${ICD}_{2} \geq {ICD}_{1} \qquad ( 3 )$$

In accordance with a preferred embodiment, the condition (4) below is fulfilled by ICD₁ and ICD₂:

$$0 \leq {ICD}_{2} - {ICD}_{1} < 1. \qquad ( 4 )$$

More preferably, the condition (4a) is fulfilled:

$$0.1 < {ICD}_{2} - {ICD}_{1} < 0.9 \qquad ( 4 a )$$

Even more preferably, the condition (4b) is fulfilled:

$$0.3 < {ICD}_{2} - {ICD}_{1} < 0.8 \qquad ( 4 b )$$

Particularly more preferably, the condition (4c) is fulfilled:

$$0.5 < {ICD}_{2} - {ICD}_{1} < 0.8 \qquad ( 4 c )$$

In accordance with a preferred embodiment, the first subpixel comprising an electron-blocking layer EBL₁ also comprises an emitting layer EML₁ and the second subpixel comprising an electron-blocking layer EBL₂ also comprises an emitting layer EML₂, where EML₁ and EML₂ are preferably different. The emitting layer EML₁ is preferably deposited directly on the electron-blocking layer EBL1 and the emitting layer EML₂ is preferably deposited directly on the electron-blocking layer EBL₂.

In accordance with a preferred embodiment, the pixel comprises a third subpixel comprising in the following sequence: an anode, at least one hole-transport layer and an electron-blocking layer EBL₃, where the at least one hole-transport layer in the third subpixel is the common hole-transport layer c-HTL as defined above, and the electron-blocking layer EBL₃ adjoins the layer c-HTL.

Layer EBL₃ is preferably different from EBL₁ and/or EBL₂.

The interface charge density ICD₃ preferably fulfills the following condition (5):

$$0 < {ICD}_{3} < 1. mC \cdot {m}^{- 2} \qquad ( 5 )$$

where ICD₃ is the difference between the surface charge density of layer EBL₃ and the surface charge density of layer c-HTL:

$${ICD}_{3} = {SCD}_{EBL 3} - {SCD}_{c - HTL}$$

Preferably, ICD₃ fulfills the following conditions (5a):

$$0 < {ICD}_{3} < 0.8 mC \cdot {m}^{- 2} \qquad ( 5 a )$$

More preferably, ICD₃ fulfills the following conditions (5b):

$$0 < {ICD}_{3} < 0.6 mC \cdot {m}^{- 2} \qquad ( 5 b )$$

Even more preferably, ICD₃ fulfills the following conditions (5c):

$$0 < {ICD}_{3} < 0.4 mC \cdot {m}^{- 2} \qquad ( 5 c )$$

Particularly more preferably, ICD₃ fulfills the following conditions (5d):

$$0 < {ICD}_{3} < 0.2 mC \cdot {m}^{- 2} \qquad ( 5 d )$$

It is preferred that the following condition (6) is fulfilled:

$${ICD}_{3} \geq {ICD}_{1} \qquad ( 6 )$$

In accordance with a preferred embodiment, the condition (7) below is fulfilled by ICD₁ and ICD₃:

$$0 \leq {ICD}_{3} - {ICD}_{1} < 1. \qquad ( 7 )$$

More preferably, the condition (7a) is fulfilled:

$$0 \text{.1} < {ICD}_{3} - {ICD}_{1} < 0.9 \qquad ( 7 a )$$

Even more preferably, the condition (7b) is fulfilled:

$$0.3 < {ICD}_{3} - {ICD}_{1} < 0.8 \qquad ( 7 b )$$

Particularly more preferably, the condition (4c) is fulfilled:

$$0.5 < {ICD}_{3} - {ICD}_{1} < 0.8 \qquad ( 7 c )$$

In accordance with a preferred embodiment, the third subpixel comprising an electron-blocking layer EBL₃ also comprises an emitting layer EML₃, where EML₃ is preferably different from EML₁ and/or EML₂ as defined above.

Preferably, the emitting layer EML₃ is deposited directly on the electron-blocking layer EBL₃.

Preferably, the emitting layer EML₃ has an emission maximum wavelength λ₃ which is higher than the emission maximum wavelength λ₂ of the emitting layer EML₂ as follows

$${3}_{} > {2}_{}$$

In accordance with a preferred embodiment, the common hole-transport layer c-HTL comprises a hole-transport material selected from compounds of formula (A)

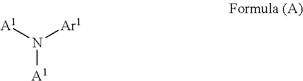

where:
A¹ is the same or different at each instance and is H, an alkyl group which has 1 to 20 carbon atoms and may be substituted by one or more R¹ radicals, or Ar¹;
Ar¹ is the same or different at each instance and is an aromatic ring system which has 6 to 60 aromatic ring atoms and may be substituted by one or more R¹ radicals, or a heteroaromatic ring system which has 5 to 60 aromatic ring atoms and may be substituted by one or more R¹ radicals; Ar¹ and/or A¹ groups here may be bonded to one another via R¹ radicals;
R¹ is the same or different at each instance and is selected from H, D, F, C(═O)R², CN, Si(R²)₃, P(═O)(R²)₂, OR², S(═O)R², S(═O)₂R², straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R¹ radicals may be joined to one another and may form a ring; where the alkyl, alkoxy, alkenyl and alkynyl groups mentioned and the aromatic ring systems and heteroaromatic ring systems mentioned may each be substituted by one or more R² radicals; and where one or more CH₂ groups in the alkyl, alkoxy, alkenyl and alkynyl groups mentioned may be replaced by —R²C═CR²—, —C≡C—, Si(R²)₂, C═O, C═NR², —C(═O)O—, —C(═O)NR²—, P(═O)(R²), —O—, —S—, SO or SO₂;
R² is the same or different at each instance and is selected from H, D, F, CN, alkyl groups having 1 to 20 carbon atoms, aromatic ring systems having 6 to 40 aromatic ring atoms and heteroaromatic ring systems having 5 to 40 aromatic ring atoms; where two or more R² radicals may be joined to one another and may form a ring; and where the alkyl groups, aromatic ring systems and heteroaromatic ring systems mentioned may be substituted by F or CN.

General definitions of chemical groups in the context of the present application follow:

An aromatic ring system in the context of this invention contains 6 to 60 carbon atoms in the ring system. It does not comprise any heteroatoms as aromatic ring atoms. An aromatic ring system in the context of this invention therefore does not contain any heteroaryl groups. An aromatic ring system in the context of this invention shall be understood to mean a system which does not necessarily contain only aryl groups but in which it is also possible for a plurality of aryl groups to be bonded by a single bond or by a non-aromatic unit, for example one or more optionally substituted C, Si, N, O or S atoms. In this case, the nonaromatic unit comprises preferably less than 10% of the atoms other than H, based on the total number of atoms other than H in the system. For example, systems such as 9,9′-spirobifluorene, 9,9′-diarylfluorene, triarylamine, diaryl ethers and stilbene are also to be regarded as aromatic ring systems in the context of this invention, and likewise systems in which two or more aryl groups are joined, for example, by a linear or cyclic alkyl, alkenyl or alkynyl group or by a silyl group. In addition, systems in which two or more aryl groups are joined to one another via single bonds are also to be regarded as aromatic ring systems in the context of this invention, for example systems such as biphenyl and terphenyl.

A heteroaromatic ring system in the context of this invention contains 5 to 60 aromatic ring atoms, at least one of which is a heteroatom. The heteroatoms of the heteroaromatic ring system are preferably selected from N, O and/or S. A heteroaromatic ring system corresponds to the abovementioned definition of an aromatic ring system, but has at least one heteroatom as one of the aromatic ring atoms. In this way, it differs from an aromatic ring system in the sense of the definition of the present application, which, according to this definition, cannot contain any heteroatom as aromatic ring atom.

An aryl group in the context of this invention contains 6 to 40 aromatic ring atoms of which none is a heteroatom. An aryl group in the context of this invention is understood to mean either a simple aromatic cycle, i.e. benzene, or a fused aromatic polycycle, for example naphthalene, phenanthrene or anthracene. A fused aromatic polycycle in the context of the present application consists of two or more simple aromatic cycles fused to one another. Fusion between cycles is understood here to mean that the cycles share at least one edge with one another.

A heteroaryl group in the context of this invention contains 5 to 40 aromatic ring atoms of which at least one is a heteroatom. The heteroatoms of the heteroaryl group are preferably selected from N, O and S. A heteroaryl group in the context of this invention is understood to mean either a simple heteroaromatic cycle, for example pyridine, pyrimidine or thiophene, or a fused heteroaromatic polycycle, for example quinoline or carbazole. A fused heteroaromatic polycycle in the context of the present application consists of two or more simple heteroaromatic cycles fused to one another. Fusion between cycles is understood to mean that the cycles share at least one edge with one another.

An aromatic ring system having 6 to 40 aromatic ring atoms or a heteroaromatic ring system having 5 to 40 aromatic ring atoms are especially understood to mean groups derived from the groups mentioned above under aryl groups and heteroaryl groups, and from biphenyl, terphenyl, quaterphenyl, fluorene, spirobifluorene, dihydrophenanthrene, dihydropyrene, tetrahydropyrene, indenofluorene, truxene, isotruxene, spirotruxene, spiroisotruxene, indenocarbazole, or from combinations of these groups.

An aryl or heteroaryl group, each of which may be substituted by the abovementioned radicals and which may be joined to the aromatic or heteroaromatic system via any desired positions, is especially understood to mean groups derived from benzene, naphthalene, anthracene, phenanthrene, pyrene, dihydropyrene, chrysene, perylene, triphenylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

In the context of the present invention, a straight-chain alkyl group having 1 to 20 carbon atoms and a branched or cyclic alkyl group having 3 to 20 carbon atoms and an alkenyl or alkynyl group having 2 to 20 carbon atoms in which individual hydrogen atoms or CH₂ groups may also be replaced by the groups mentioned above in the definition of the radicals are preferably understood to mean the methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl radicals.

An alkoxy or thioalkyl group having 1 to 20 carbon atoms in which individual hydrogen atoms or CH₂ groups may also be replaced by the groups mentioned above in the definition of the radicals is preferably understood to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio.

The wording that two or more radicals together may form a ring, in the context of the present application, shall be understood to mean, inter alia, that the two radicals are joined to one another by a chemical bond. In addition, however, the abovementioned wording shall also be understood to mean that, if one of the two radicals is hydrogen, the second radical binds to the position to which the hydrogen atom was bonded, forming a ring.

The compound of formula (A) is preferably a monoarylamine. A monoarylamine is understood here to mean a compound having a single arylamino group and not more than one. Preferably, the compound is a monotriarylamino compound, meaning that it has a single triarylamino group. The term “triarylamino group” is preferably also understood to mean compounds containing heteroaryl groups bonded to the amino nitrogen. Further preferably, the compound of formula (A) has a single amino group. It should be noted that, according to the definition of the present application, carbazole groups do not count as arylamino groups or amino groups.

According to a further preferred embodiment of the invention, the compound of formula (A) does not contain a fused aryl group having more than 10 aromatic ring atoms nor a fused heteroaryl group having more than 14 aromatic ring atoms.

Preferably, A¹ is the same or different at each instance and is an alkyl group which has 1 to 20 carbon atoms and may be substituted by one or more R¹ radicals, or Ar¹. Preferably, at least one A¹ group in the compound of formula (A) is Ar¹; more preferably, both A¹ groups in the compound of formula (A) are Ar¹.

Ar¹ is preferably the same or different at each instance and is an aromatic ring system which has 6 to 40 aromatic ring atoms and may be substituted by one or more R¹ radicals, or a heteroaromatic ring system which has 5 to 40 aromatic ring atoms and may be substituted by one or more R¹ radicals.

Preferably, at least one Ar¹ group in the compound of the formula (A) is a group which is optionally substituted by one or more R¹ radicals and is selected from phenyl, biphenyl, terphenyl, quaterphenyl, naphthyl, phenanthryl, fluoranthenyl, fluorenyl, indenofluorenyl, spirobifluorenyl, furanyl, benzofuranyl, isobenzofuranyl, dibenzofuranyl, thiophenyl, benzothiophenyl, isobenzothiophenyl, dibenzothiophenyl, indolyl, isoindolyl, carbazolyl, indolocarbazolyl, indenocarbazolyl, pyridyl, quinolinyl, isoquinolinyl, acridyl, phenanthridyl, benzimidazolyl, pyrimidyl, pyrazinyl and triazinyl; particular preference among these is given to phenyl, biphenyl, terphenyl, quaterphenyl, naphthyl, phenanthryl, fluoranthenyl, fluorenyl, indenofluorenyl, spirobifluorenyl, dibenzofuranyl, dibenzothiophenyl, carbazolyl, acridyl and phenanthridyl.

R¹ is preferably the same or different at each instance and is selected from H, D, F, CN, Si(R²)₃, straight-chain alkyl or alkoxy groups having 1 to 10 carbon atoms, branched or cyclic alkyl or alkoxy groups having 3 to 10 carbon atoms, aromatic ring systems having 6 to 40 aromatic ring atoms and heteroaromatic ring systems having 5 to 40 aromatic ring atoms; where the alkyl and alkoxy groups mentioned, the aromatic ring systems mentioned and the heteroaromatic ring systems mentioned may each be substituted by one or more R² radicals; and where one or more CH₂ groups in the alkyl or alkoxy groups mentioned may be replaced by —C≡C—, —R²C═CR²—, Si(R²)₂, C═O, C═NR², —O—, —S—, —C(═O)O— or —C(═O)NR²—.

Preferably, at least one Ar¹ group, more preferably all the Ar¹ groups, in the compound of the formula (A) are the same or different at each instance and are selected from the following groups, each of which may be substituted by one or more R¹ radicals at any of the unsubstituted positions shown:

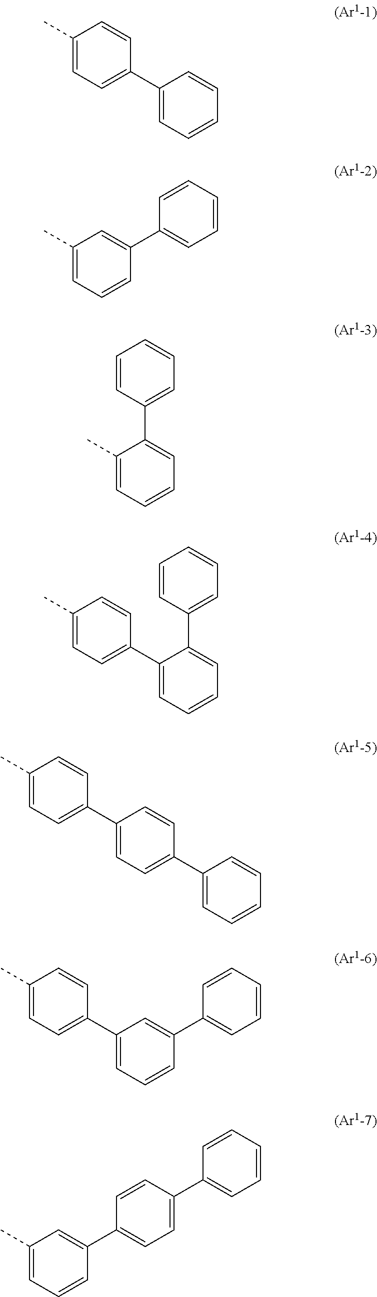

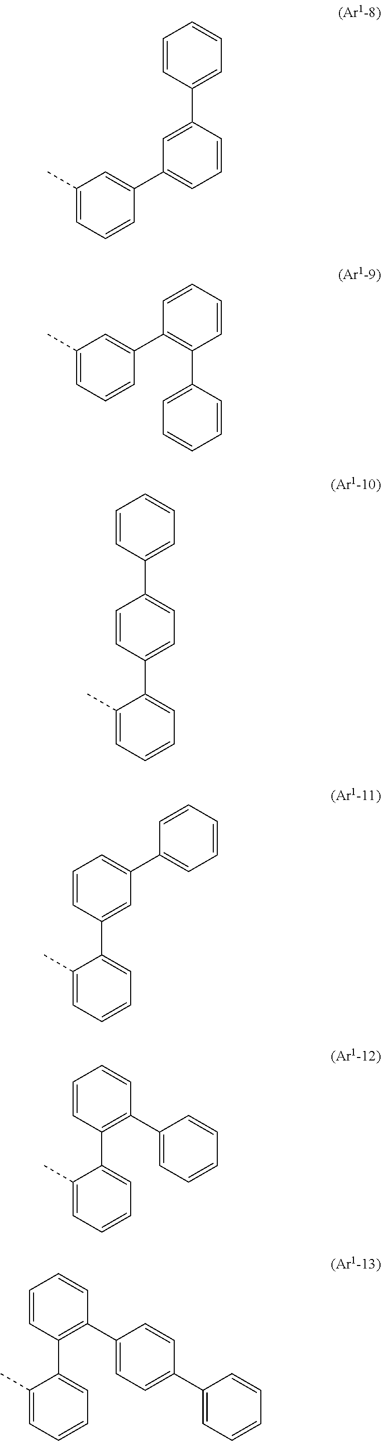

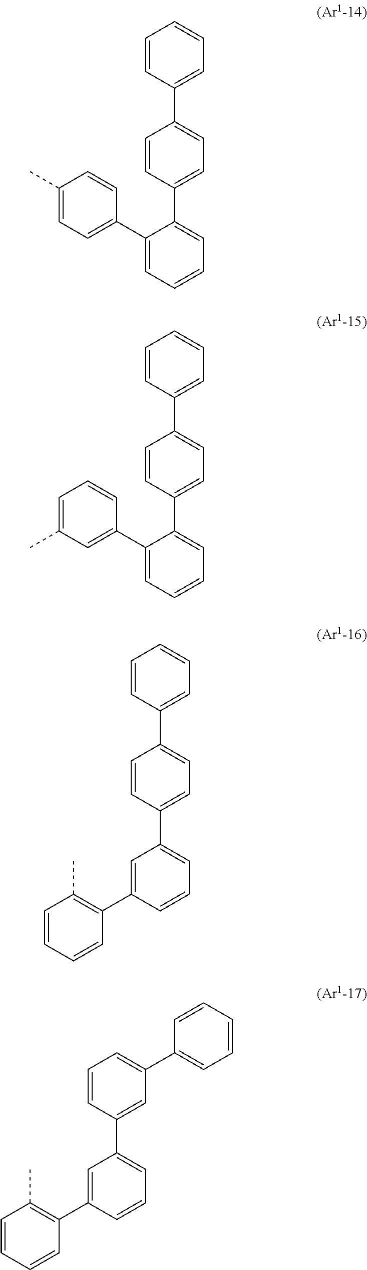

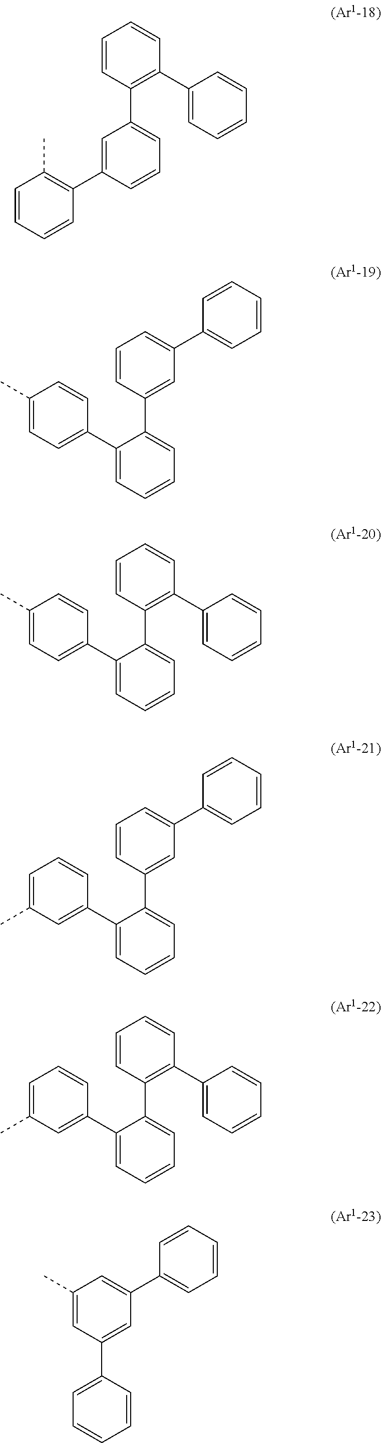

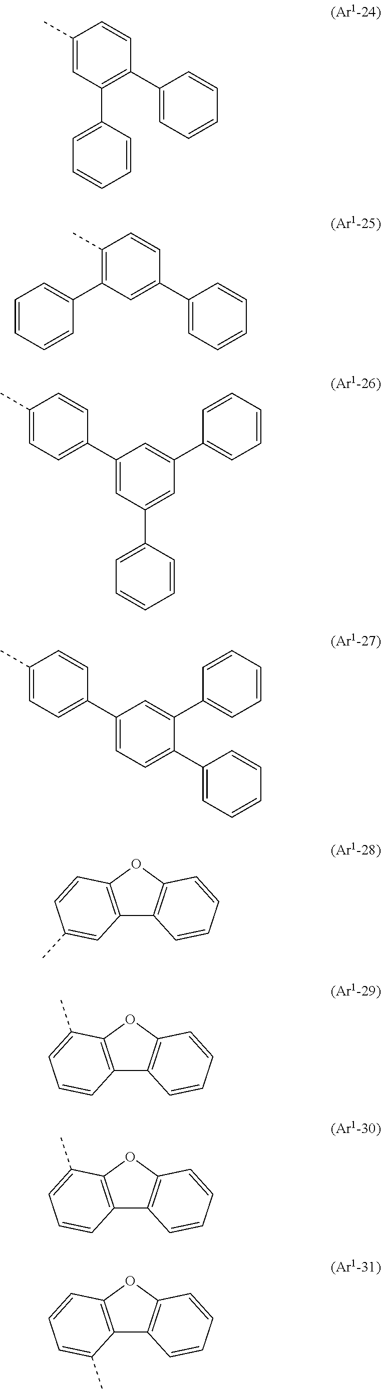

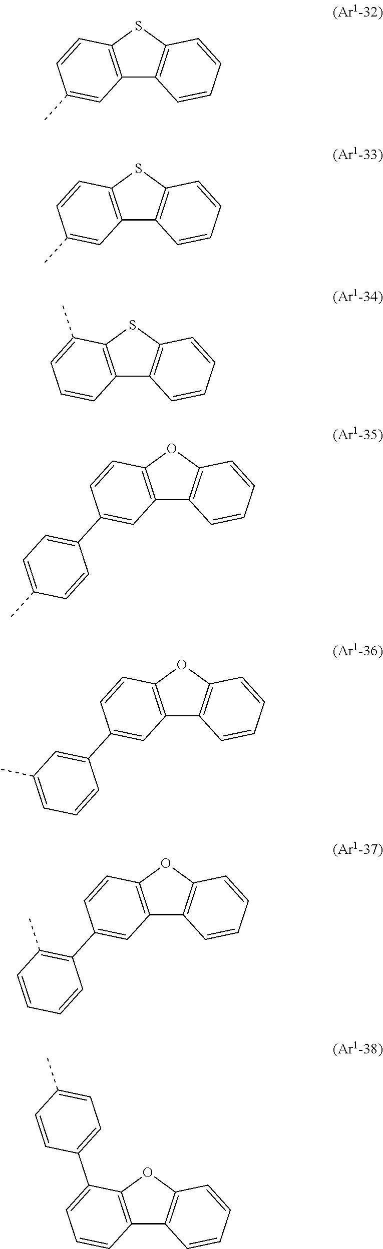

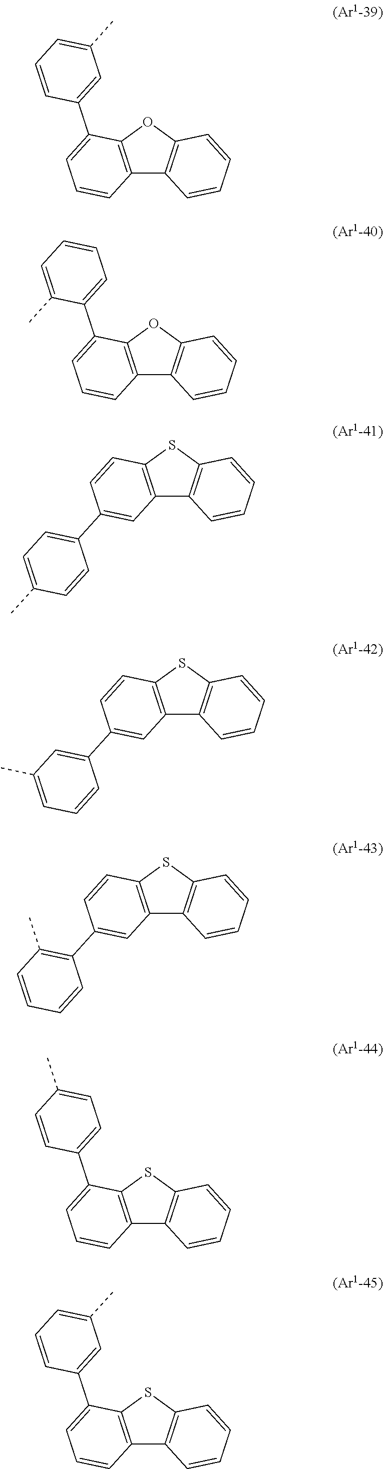

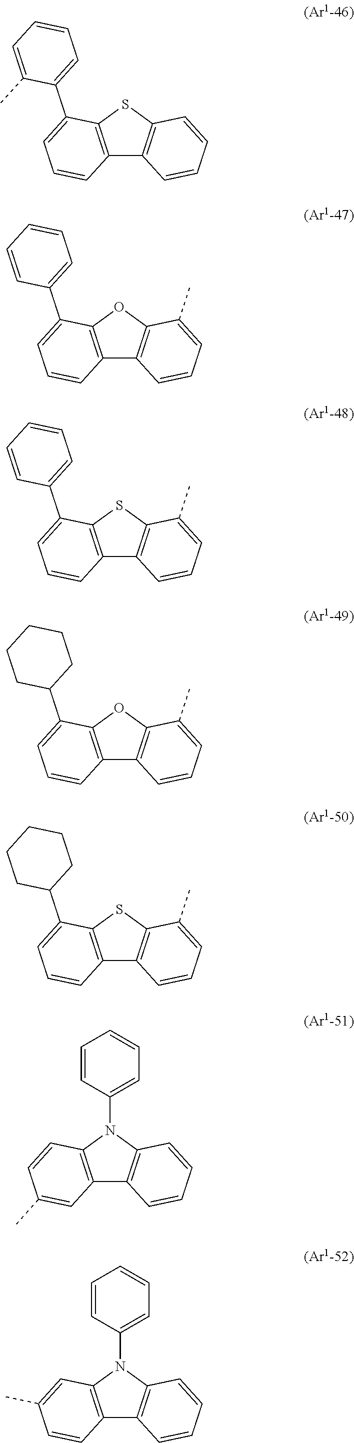

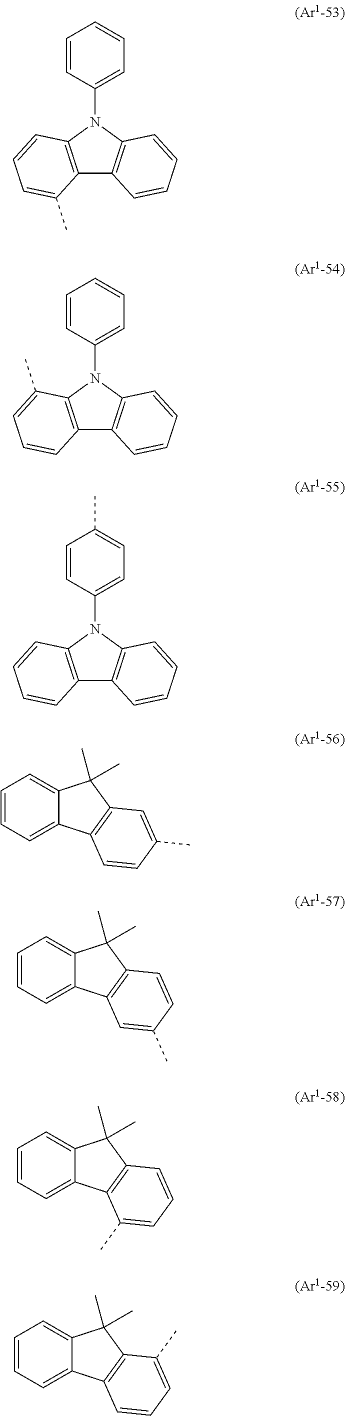

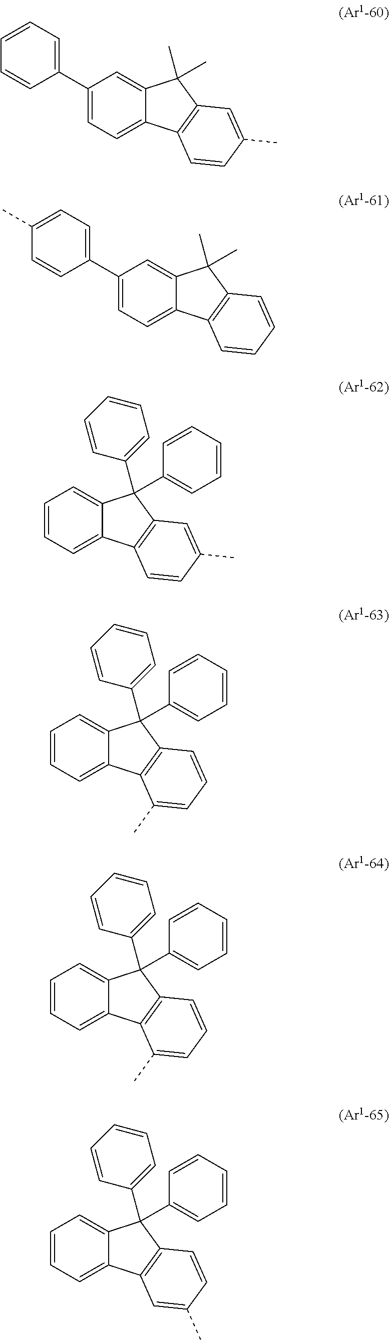

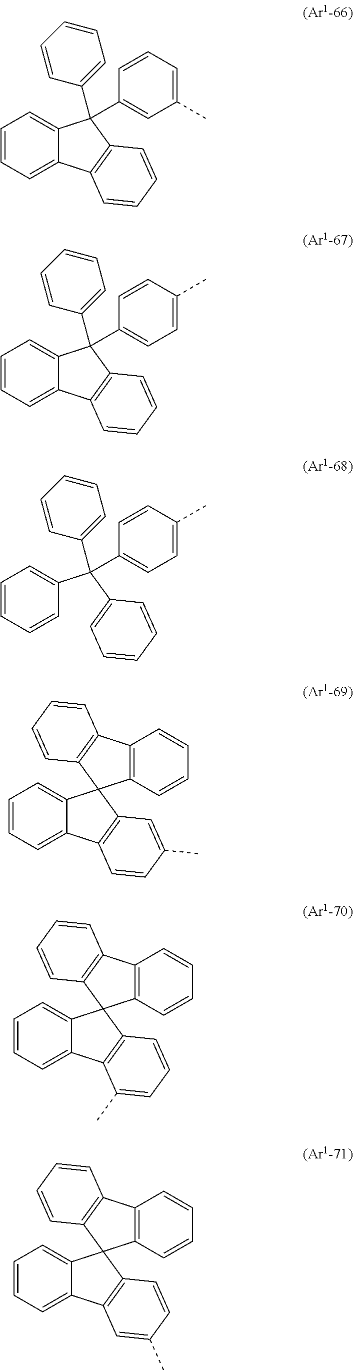

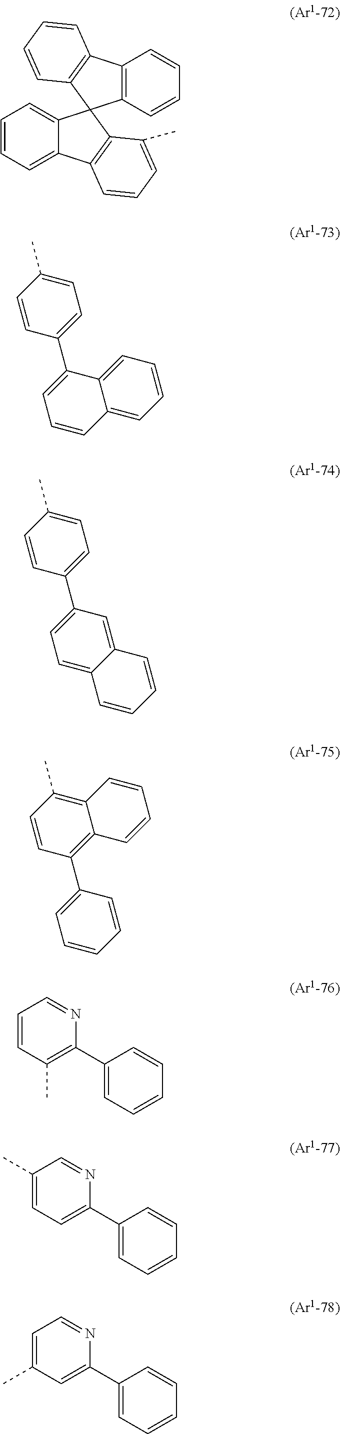

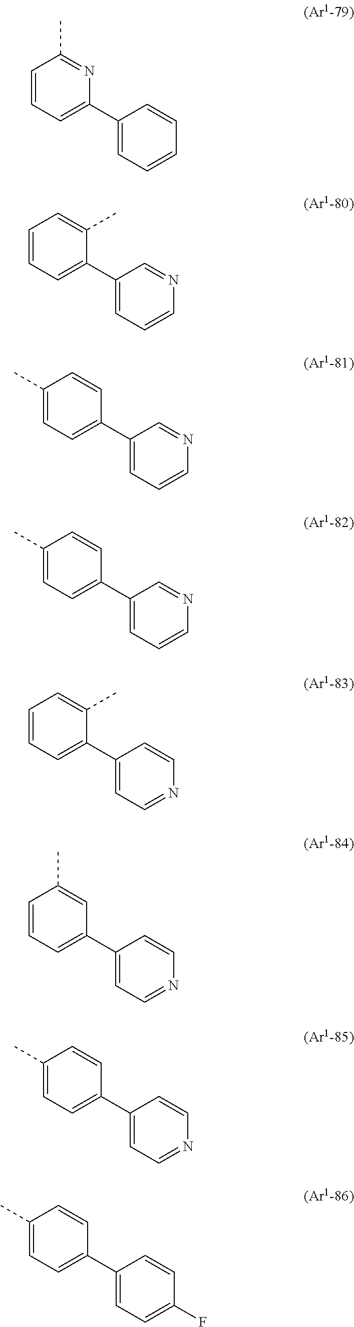

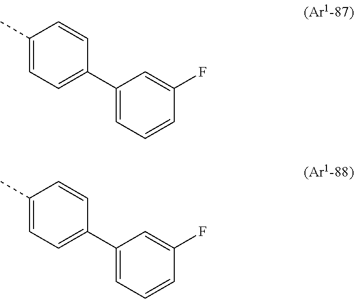

Preferably, the common hole-transport layer c-HTL comprises a hole-transport material selected from compounds of formula (A-I) to (A-IX):

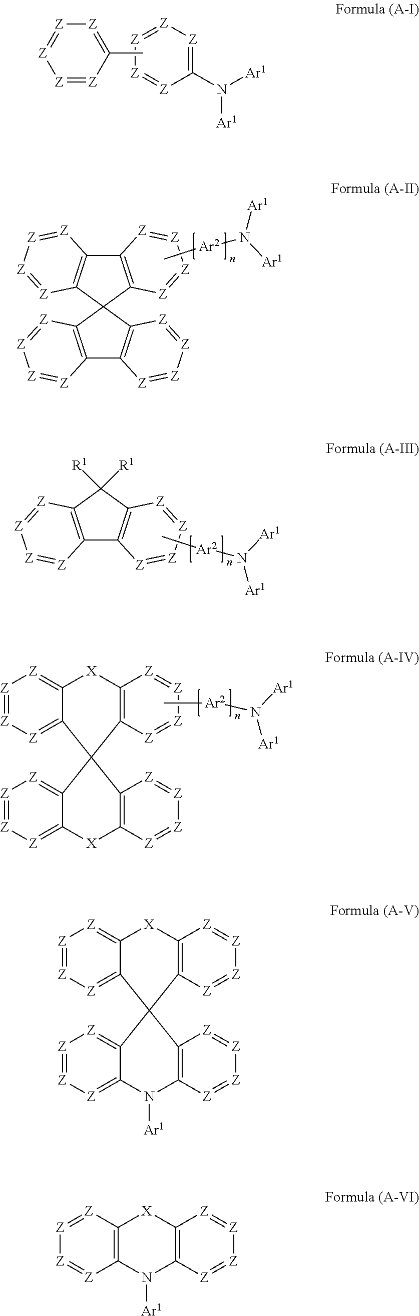

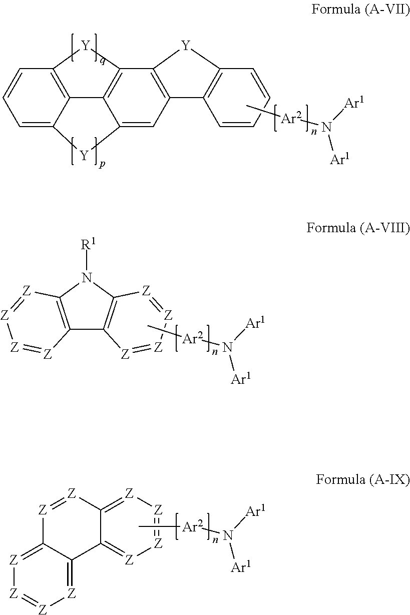

where one or more R¹ radicals may be bonded to any of the unsubstituted positions shown, and:
Z is the same or different at each instance and is CR¹ or N;
X is the same or different at each instance and is a single bond, O, S, C(R¹)₂, Si(R¹)₂, PR¹, C(R¹)₂—C(R¹)₂, or CR¹═CR¹;
Y is the same or different at each instance and is O, S, C(R¹)₂, Si(R¹)₂, PR¹, NR¹, C(R¹)₂—C(R¹)₂, or CR¹═CR¹;
Ar¹ is as defined above;
Ar² is an aromatic ring system which has 6 to 20 aromatic ring atoms and may be substituted by one or more R¹ radicals, or a heteroaromatic ring system which has 5 to 20 aromatic ring atoms and may be substituted by one or more R¹ radicals;
n, p, q are the same or different and are each 0 or 1.

It is preferable that not more than three Z groups in one ring are N. Preferably not more than 2 adjacent Z groups are N. More preferably, Z is CR¹.

It is preferable that X is the same or different at each instance and is a single bond, O, S or (CR¹)₂.

It is preferable that not more than three Z groups in one ring are N. Preferably not more than 2 adjacent Z groups are N. More preferably, Z is CR¹.

It is preferable that X is the same or different at each instance and is a single bond, O, S or (CR¹)₂.

Preferably, at least one of the indices p and q is 1. Preferably, the sum total of the indices p and q is 1.

Preferably, Ar¹ in the abovementioned formulae is (A-I) to (A-IX) selected from the abovementioned preferred embodiments of Ar¹.

Preferably, Ar² comprises at least one group selected from benzene, naphthalene, phenanthrene, fluoranthene, biphenyl, terphenyl, quaterphenyl, fluorene, indenofluorene, spirobifluorene, furan, benzofuran, isobenzofuran, dibenzofuran, thiophene, benzothiophene, isobenzothiophene, dibenzothiophene, indole, isoindole, carbazole, indolocarbazole, indenocarbazole, pyridine, quinoline, isoquinoline, acridine, phenanthridine, benzimidazole, pyrimidine, pyrazine and triazine, where the groups mentioned may be substituted by one or more R¹ radicals. Preferably, Ar² consists exclusively of one of the abovementioned groups or of a combination of a plurality of the abovementioned groups.

Preferably, Ar² is the same or different at each instance and is selected from the following groups, each of which may be substituted by one or more R¹ radicals at any of the unsubstituted positions shown:

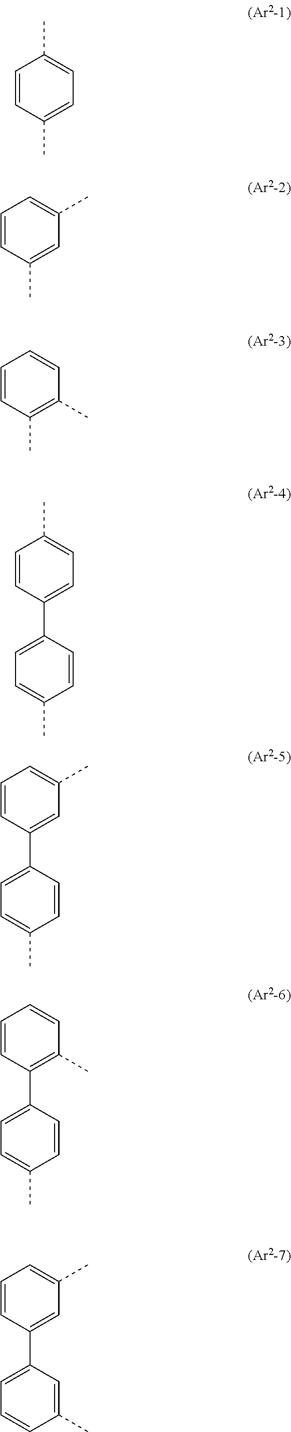

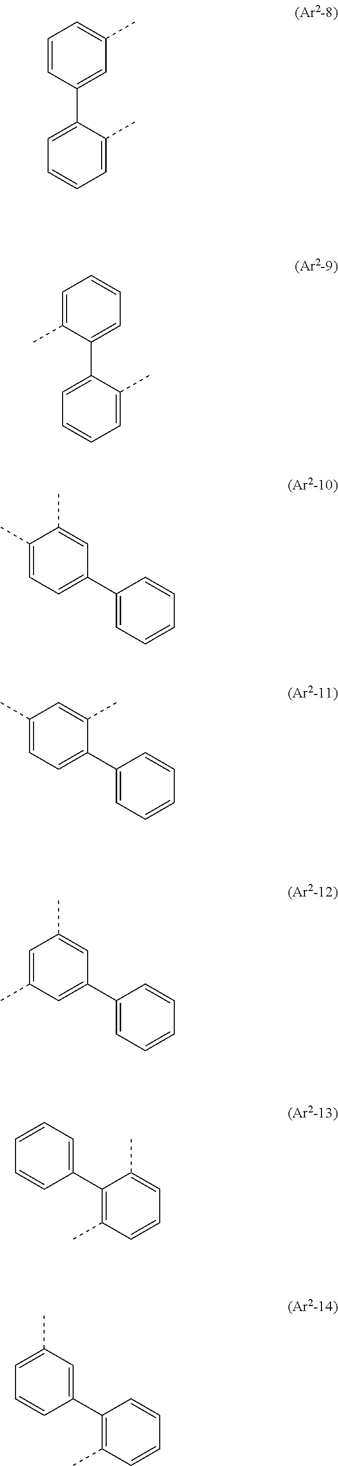

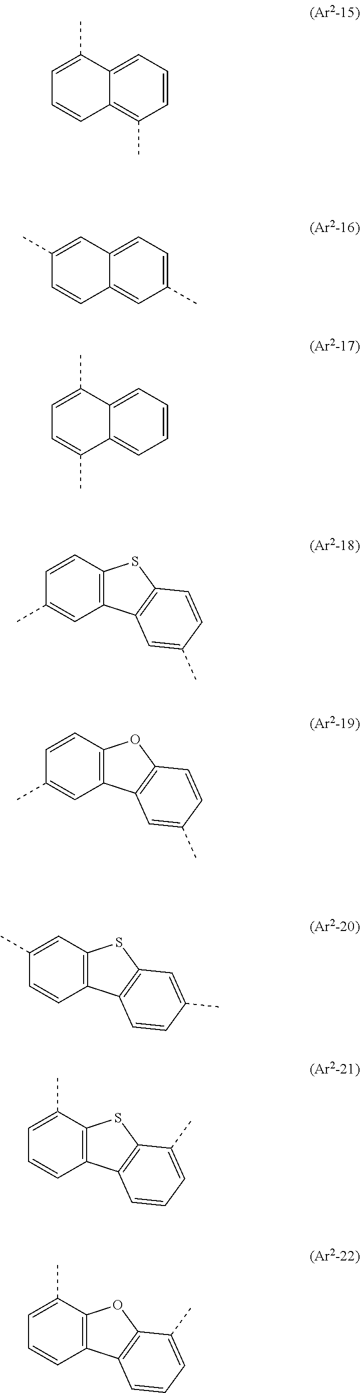

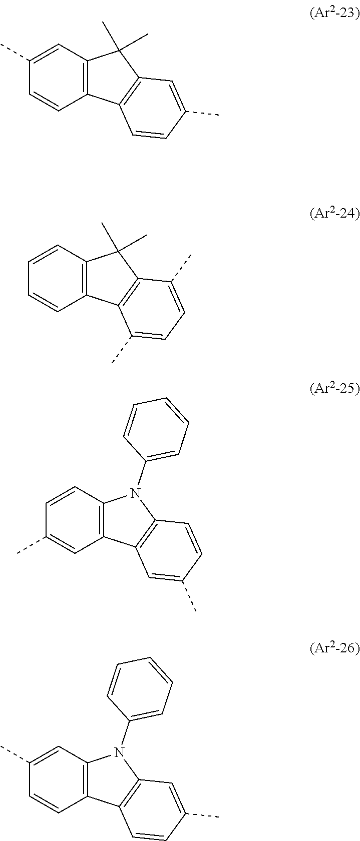

More preferably, the common hole-transport layer c-HTL comprises a hole-transport material selected from compounds of formula (A-I), (A-II), (A-III) and (A-IV), more preferably (A-II) and (A-III).

Suitable examples of compounds of the formula (A) are the compounds as depicted in the patent application WO 2016/062368 A1. Further suitable hole-transport materials which can be used in a hole-transport, hole-injection or electron-blocking layer in the electroluminescent device according to the invention are indenofluorenamine derivatives (for example in accordance with WO 06/122630 or WO 06/100896), the amine derivatives disclosed in EP 1661888, hexaazatriphenylene derivatives (for example in accordance with WO 01/049806), amine derivatives containing condensed aromatic rings (for example in accordance with U.S. Pat. No. 5,061,569), the amine derivatives disclosed in WO 95/09147, monobenzoindenofluorenamines (for example in accordance with WO 08/006449), dibenzoindenofluorenamines (for example in accordance with WO 07/140847), spirobifluorenamines (for example in accordance with WO 2012/034627 or WO 2013/120577), fluorenamines (for example in accordance with the as applications EP 2875092, EP 2875699 and EP 2875004), spirodibenzopyranamines (for example in accordance with WO 2013/083216) and dihydroacridine derivatives (for example in accordance with WO 2012/150001).

Particularly suitable examples of the compounds of formula (A) for the common hole-transport layer c-HTL are the compounds depicted below:

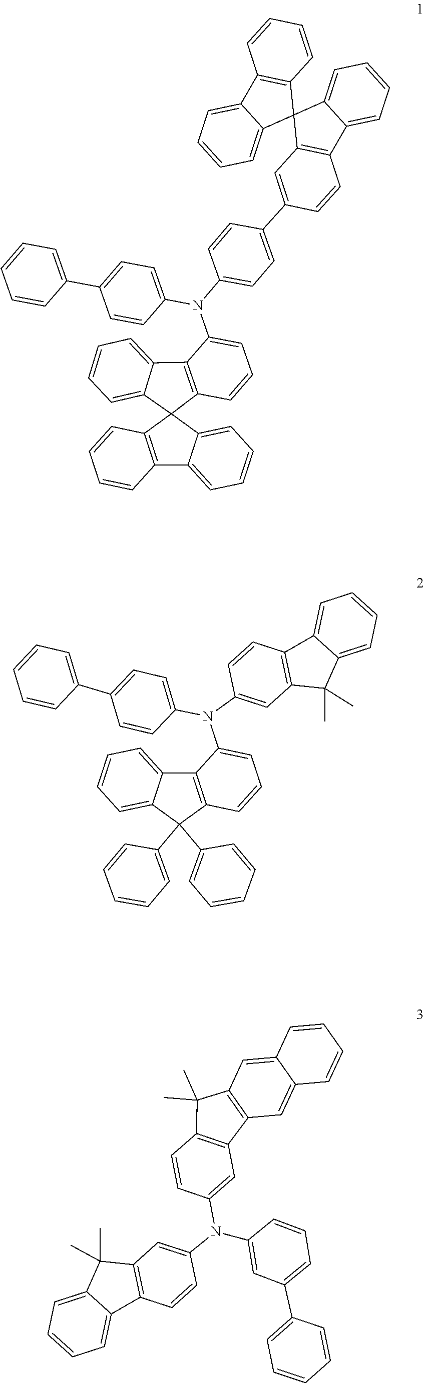 [SMILES: c1ccc(-c2ccc(N(c3ccc(-c4ccc5c(c4)C4(c6ccccc6-c6ccccc64)c4ccccc4-5)cc3)c3cccc4c3-c3ccccc3C43c4ccccc4-c4ccccc43)cc2)cc1 ; CC1(C)c2ccccc2-c2ccc(N(c3ccc(-c4ccccc4)cc3)c3cccc4c3-c3ccccc3C4(c3ccccc3)c3ccccc3)cc21 ; CC1(C)c2ccccc2-c2ccc(N(c3cccc(-c4ccccc4)c3)c3ccc4c(c3)-c3cc5ccccc5cc3C4(C)C)cc21]

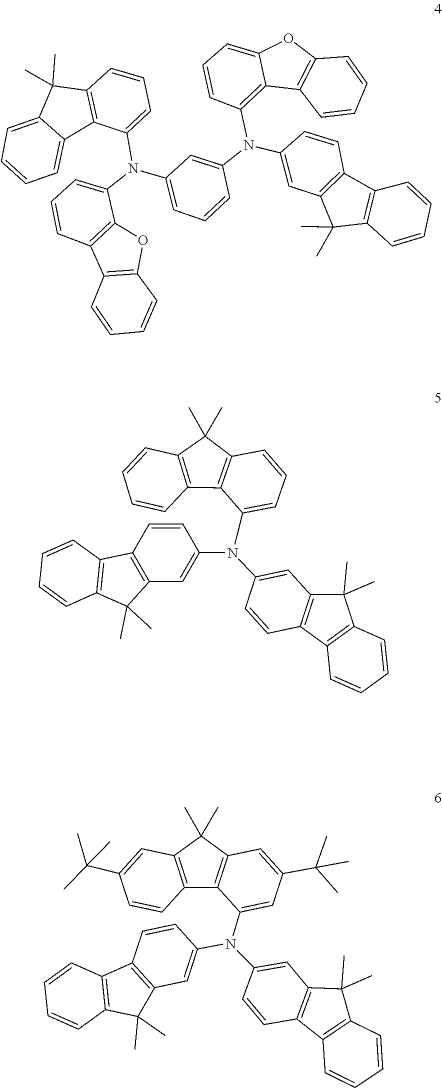 [SMILES: CC1(C)c2ccccc2-c2ccc(N(c3cccc(N(c4cccc5c4-c4ccccc4C5(C)C)c4cccc5c4oc4ccccc45)c3)c3cccc4oc5ccccc5c34)cc21 ; CC1(C)c2ccccc2-c2ccc(N(c3ccc4c(c3)C(C)(C)c3ccccc3-4)c3cccc4c3-c3ccccc3C4(C)C)cc21 ; CC(C)(C)c1ccc2c(c1)C(C)(C)c1cc(C(C)(C)C)cc(N(c3ccc4c(c3)C(C)(C)c3ccccc3-4)c3ccc4c(c3)C(C)(C)c3ccccc3-4)c1-2]

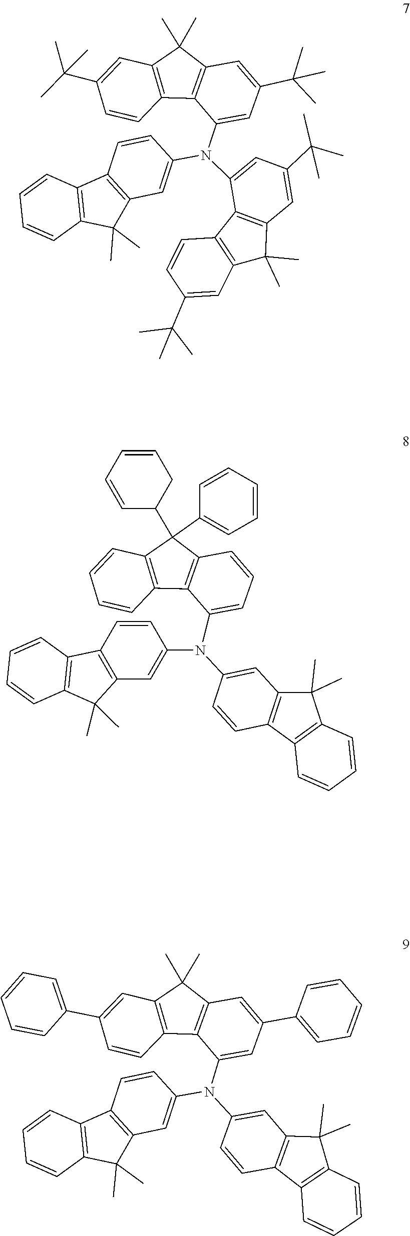 [SMILES: CC(C)(C)c1ccc2c(c1)C(C)(C)c1cc(C(C)(C)C)cc(N(c3ccc4c(c3)C(C)(C)c3ccccc3-4)c3cc(C(C)(C)C)cc4c3-c3ccc(C(C)(C)C)cc3C4(C)C)c1-2 ; CC1(C)c2ccccc2-c2ccc(N(c3ccc4c(c3)C(C)(C)c3ccccc3-4)c3cccc4c3-c3ccccc3C4(c3ccccc3)C3C=CC=CC3)cc21 ; CC1(C)c2ccccc2-c2ccc(N(c3ccc4c(c3)C(C)(C)c3ccccc3-4)c3cc(-c4ccccc4)cc4c3-c3ccc(-c5ccccc5)cc3C4(C)C)cc21]

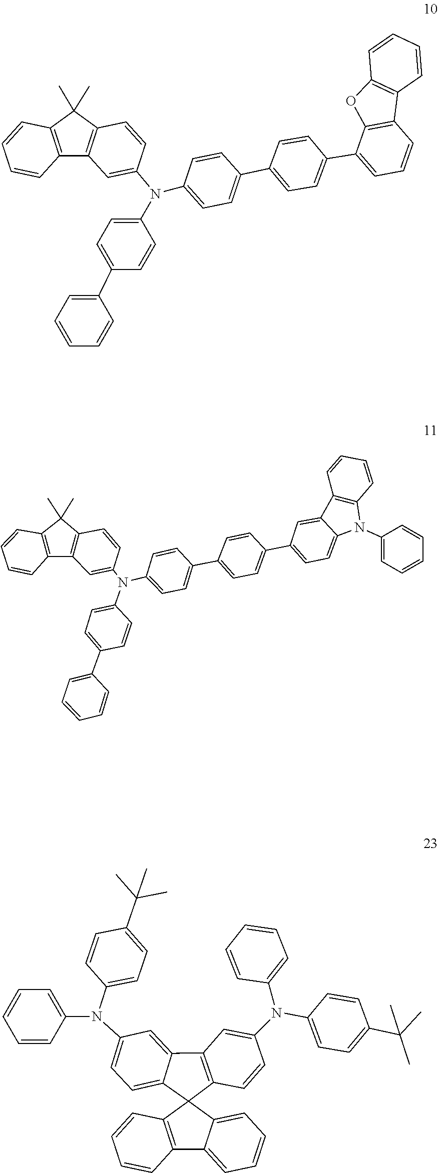 [SMILES: CC1(C)c2ccccc2-c2cc(N(c3ccc(-c4ccccc4)cc3)c3ccc(-c4ccc(-c5cccc6c5oc5ccccc56)cc4)cc3)ccc21 ; CC1(C)c2ccccc2-c2cc(N(c3ccc(-c4ccccc4)cc3)c3ccc(-c4ccc(-c5ccc6c(c5)c5ccccc5n6-c5ccccc5)cc4)cc3)ccc21 ; CC(C)(C)c1ccc(N(c2ccccc2)c2ccc3c(c2)-c2cc(N(c4ccccc4)c4ccc(C(C)(C)C)cc4)ccc2C32c3ccccc3-c3ccccc32)cc1]

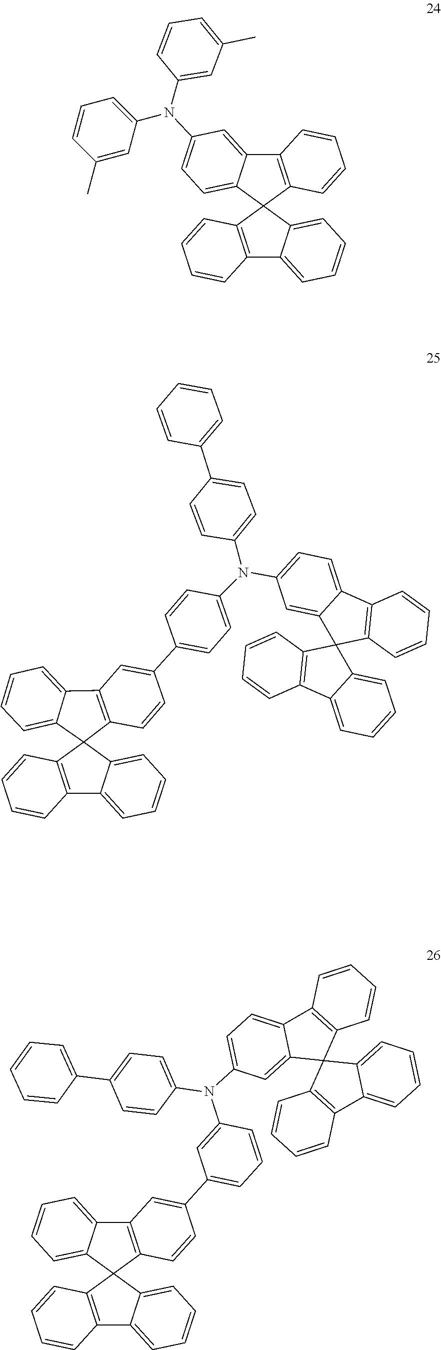 [SMILES: Cc1cccc(N(c2cccc(C)c2)c2ccc3c(c2)-c2ccccc2C32c3ccccc3-c3ccccc32)c1 ; c1ccc(-c2ccc(N(c3ccc(-c4ccc5c(c4)-c4ccccc4C54c5ccccc5-c5ccccc54)cc3)c3ccc4c(c3)C3(c5ccccc5-c5ccccc53)c3ccccc3-4)cc2)cc1 ; c1ccc(-c2ccc(N(c3cccc(-c4ccc5c(c4)-c4ccccc4C54c5ccccc5-c5ccccc54)c3)c3ccc4c(c3)C3(c5ccccc5-c5ccccc53)c3ccccc3-4)cc2)cc1]

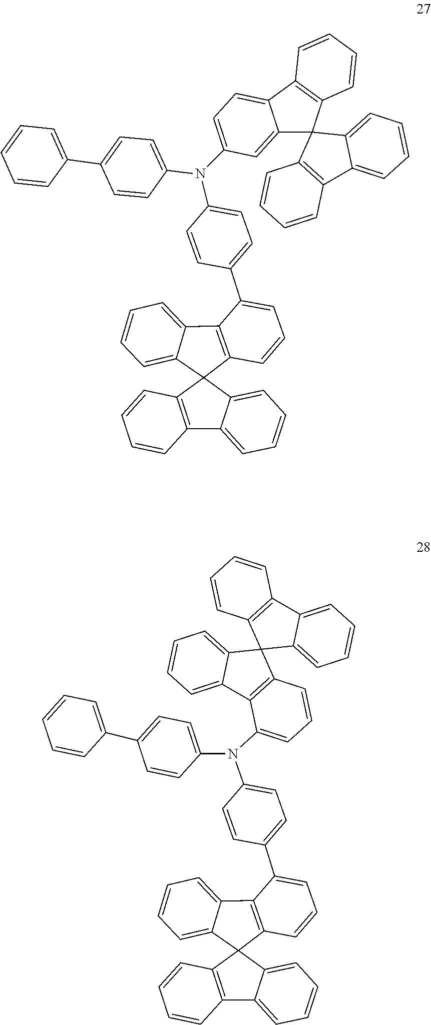 [SMILES: c1ccc(-c2ccc(N(c3ccc(-c4cccc5c4-c4ccccc4C54c5ccccc5-c5ccccc54)cc3)c3ccc4c(c3)C3(c5ccccc5-c5ccccc53)c3ccccc3-4)cc2)cc1 ; c1ccc(-c2ccc(N(c3ccc(-c4cccc5c4-c4ccccc4C54c5ccccc5-c5ccccc54)cc3)c3cccc4c3-c3ccccc3C43c4ccccc4-c4ccccc43)cc2)cc1]

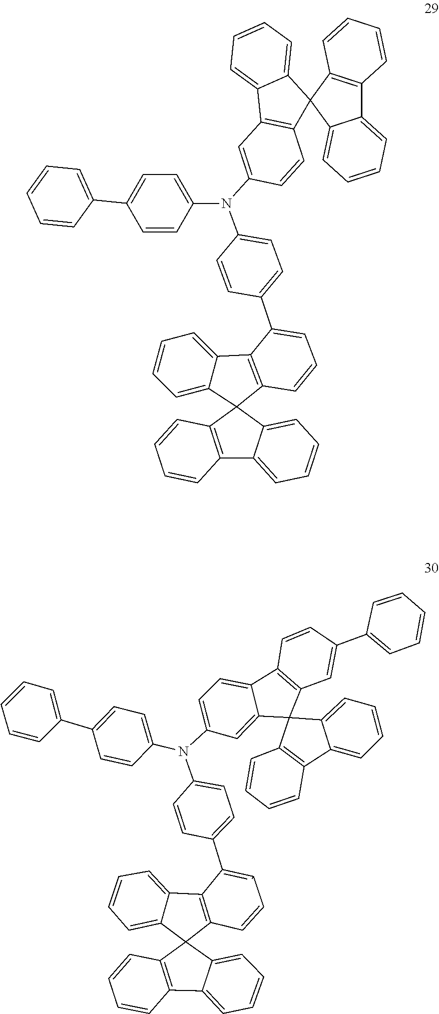

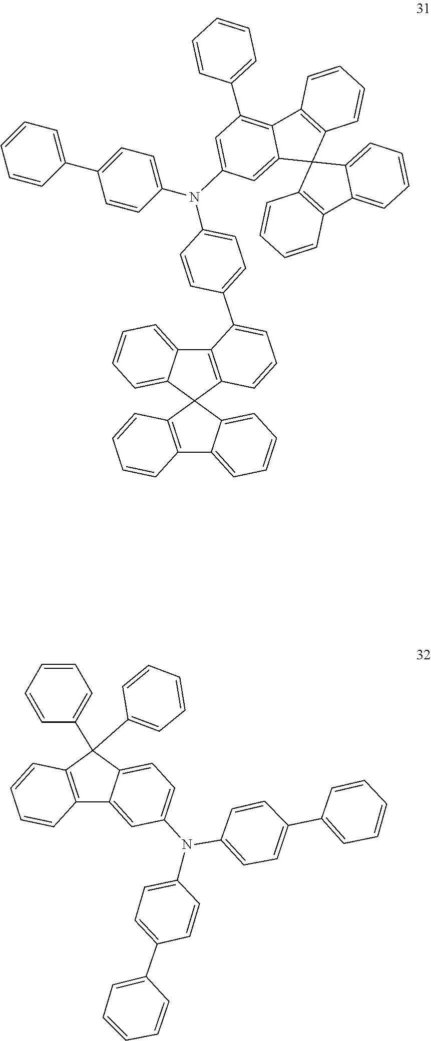 [SMILES: c1ccc(-c2ccc(N(c3ccc(-c4cccc5c4-c4ccccc4C54c5ccccc5-c5ccccc54)cc3)c3cc(-c4ccccc4)c4c(c3)C3(c5ccccc5-c5ccccc53)c3ccccc3-4)cc2)cc1 ; c1ccc(-c2ccc(N(c3ccc(-c4ccccc4)cc3)c3ccc4c(c3)-c3ccccc3C4(c3ccccc3)c3ccccc3)cc2)cc1]

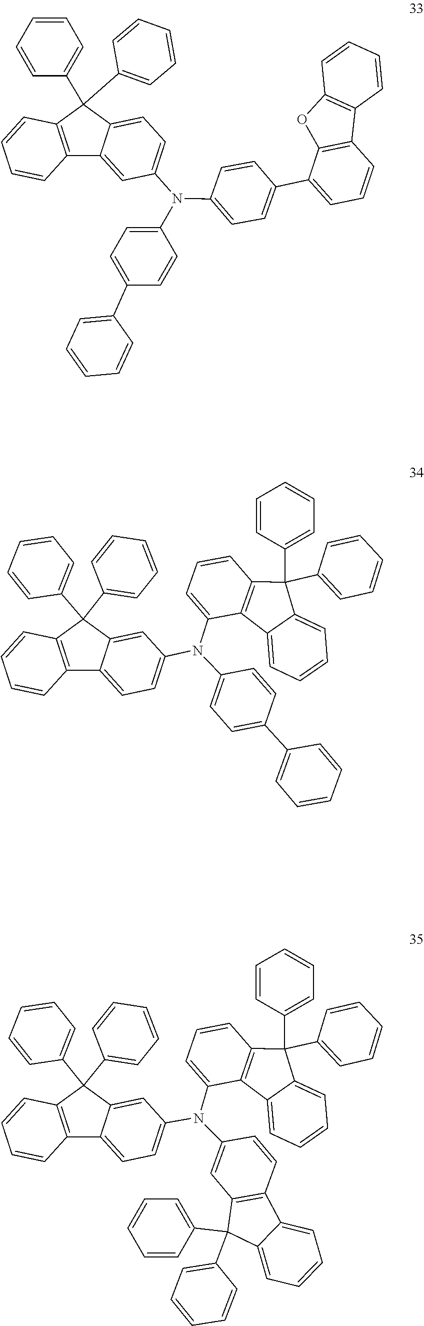 [SMILES: c1ccc(-c2ccc(N(c3ccc(-c4cccc5c4oc4ccccc45)cc3)c3ccc4c(c3)-c3ccccc3C4(c3ccccc3)c3ccccc3)cc2)cc1 ; c1ccc(-c2ccc(N(c3ccc4c(c3)C(c3ccccc3)(c3ccccc3)c3ccccc3-4)c3cccc4c3-c3ccccc3C4(c3ccccc3)c3ccccc3)cc2)cc1 ; c1ccc(C2(c3ccccc3)c3ccccc3-c3ccc(N(c4ccc5c(c4)C(c4ccccc4)(c4ccccc4)c4ccccc4-5)c4cccc5c4-c4ccccc4C5(c4ccccc4)c4ccccc4)cc32)cc1]

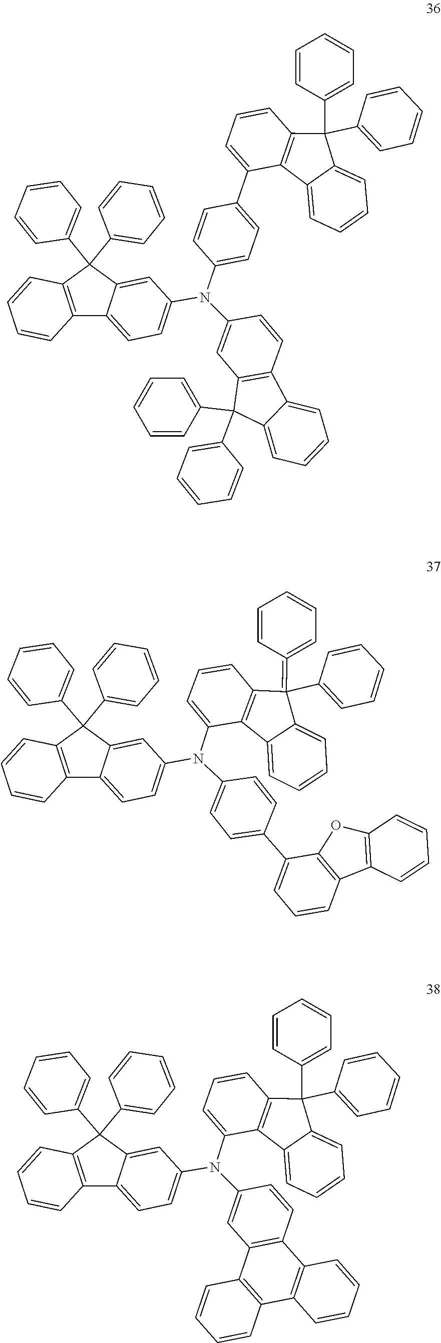

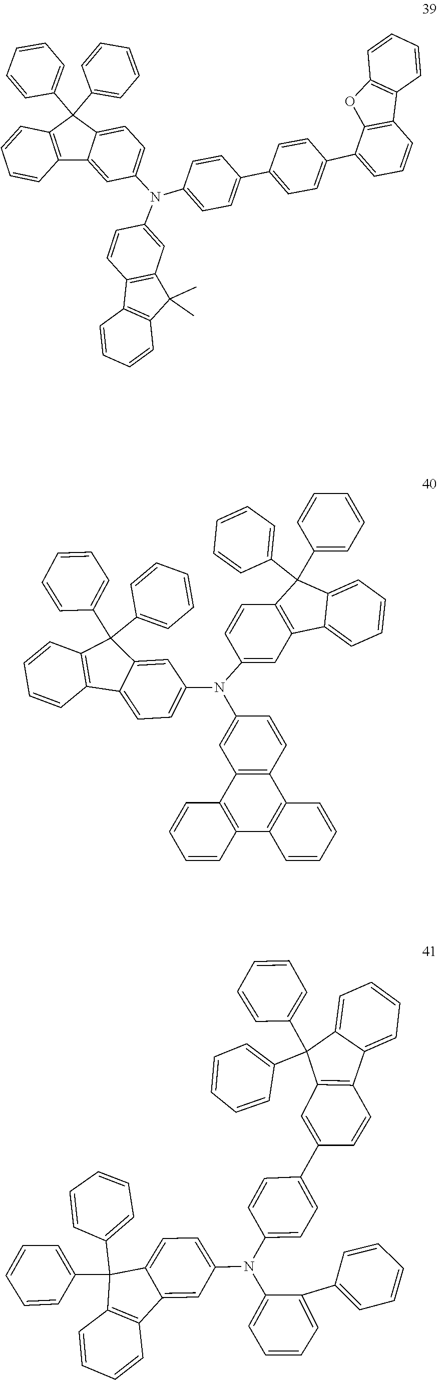 [SMILES: CC1(C)c2ccccc2-c2ccc(N(c3ccc(-c4ccc(-c5cccc6c5oc5ccccc56)cc4)cc3)c3ccc4c(c3)-c3ccccc3C4(c3ccccc3)c3ccccc3)cc21 ; c1ccc(C2(c3ccccc3)c3ccccc3-c3cc(N(c4ccc5c(c4)C(c4ccccc4)(c4ccccc4)c4ccccc4-5)c4ccc5c6ccccc6c6ccccc6c5c4)ccc32)cc1 ; c1ccc(-c2ccccc2N(c2ccc(-c3ccc4c(c3)C(c3ccccc3)(c3ccccc3)c3ccccc3-4)cc2)c2ccc3c(c2)-c2ccccc2C3(c2ccccc2)c2ccccc2)cc1]

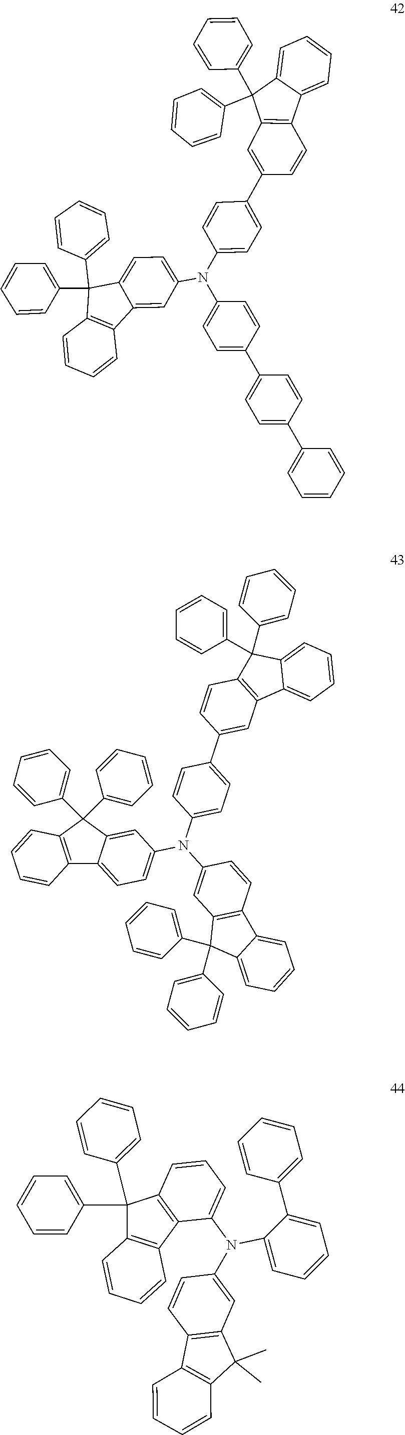 [SMILES: c1ccc(-c2ccc(-c3ccc(N(c4ccc(-c5ccc6c(c5)C(c5ccccc5)(c5ccccc5)c5ccccc5-6)cc4)c4ccc5c(c4)-c4ccccc4C5(c4ccccc4)c4ccccc4)cc3)cc2)cc1 ; c1ccc(C2(c3ccccc3)c3ccccc3-c3cc(-c4ccc(N(c5ccc6c(c5)C(c5ccccc5)(c5ccccc5)c5ccccc5-6)c5ccc6c(c5)C(c5ccccc5)(c5ccccc5)c5ccccc5-6)cc4)ccc32)cc1 ; CC1(C)c2ccccc2-c2ccc(N(c3ccccc3-c3ccccc3)c3cccc4c3-c3ccccc3C4(c3ccccc3)c3ccccc3)cc21]

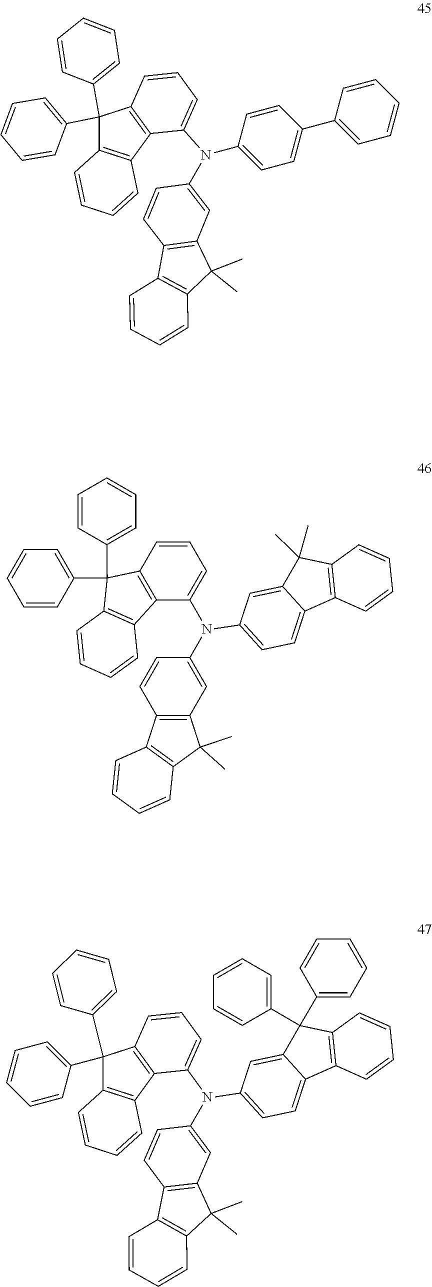 [SMILES: CC1(C)c2ccccc2-c2ccc(N(c3ccc(-c4ccccc4)cc3)c3cccc4c3-c3ccccc3C4(c3ccccc3)c3ccccc3)cc21 ; CC1(C)c2ccccc2-c2ccc(N(c3ccc4c(c3)C(C)(C)c3ccccc3-4)c3cccc4c3-c3ccccc3C4(c3ccccc3)c3ccccc3)cc21 ; CC1(C)c2ccccc2-c2ccc(N(c3ccc4c(c3)C(c3ccccc3)(c3ccccc3)c3ccccc3-4)c3cccc4c3-c3ccccc3C4(c3ccccc3)c3ccccc3)cc21]

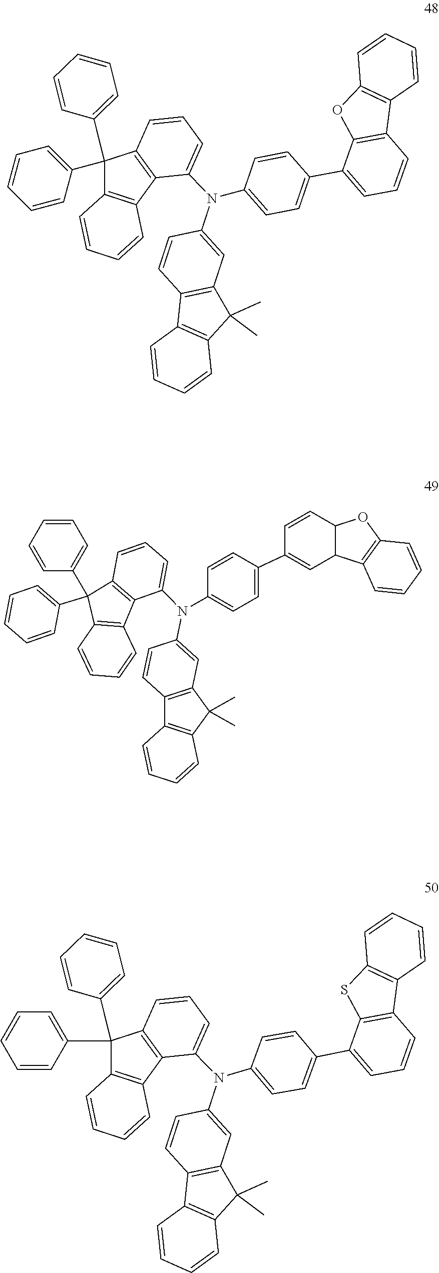 [SMILES: CC1(C)c2ccccc2-c2ccc(N(c3ccc(-c4cccc5c4oc4ccccc45)cc3)c3cccc4c3-c3ccccc3C4(c3ccccc3)c3ccccc3)cc21 ; CC1(C)c2ccccc2-c2ccc(N(c3ccc(C4=CC5c6ccccc6OC5C=C4)cc3)c3cccc4c3-c3ccccc3C4(c3ccccc3)c3ccccc3)cc21 ; CC1(C)c2ccccc2-c2ccc(N(c3ccc(-c4cccc5c4sc4ccccc45)cc3)c3cccc4c3-c3ccccc3C4(c3ccccc3)c3ccccc3)cc21]

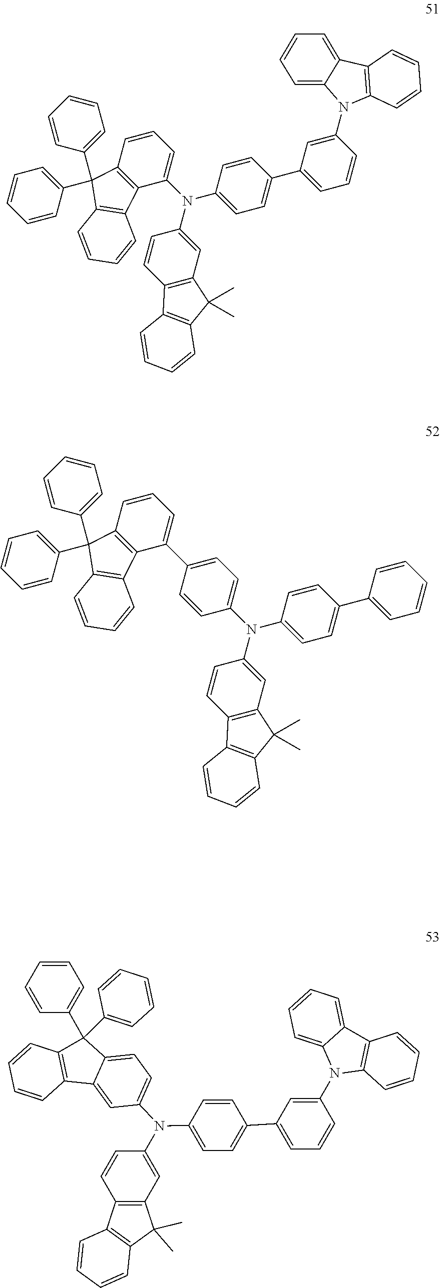 [SMILES: CC1(C)c2ccccc2-c2ccc(N(c3ccc(-c4cccc(-n5c6ccccc6c6ccccc65)c4)cc3)c3cccc4c3-c3ccccc3C4(c3ccccc3)c3ccccc3)cc21 ; CC1(C)c2ccccc2-c2ccc(N(c3ccc(-c4ccccc4)cc3)c3ccc(-c4cccc5c4-c4ccccc4C5(c4ccccc4)c4ccccc4)cc3)cc21 ; CC1(C)c2ccccc2-c2ccc(N(c3ccc(-c4cccc(-n5c6ccccc6c6ccccc65)c4)cc3)c3ccc4c(c3)-c3ccccc3C4(c3ccccc3)c3ccccc3)cc21]

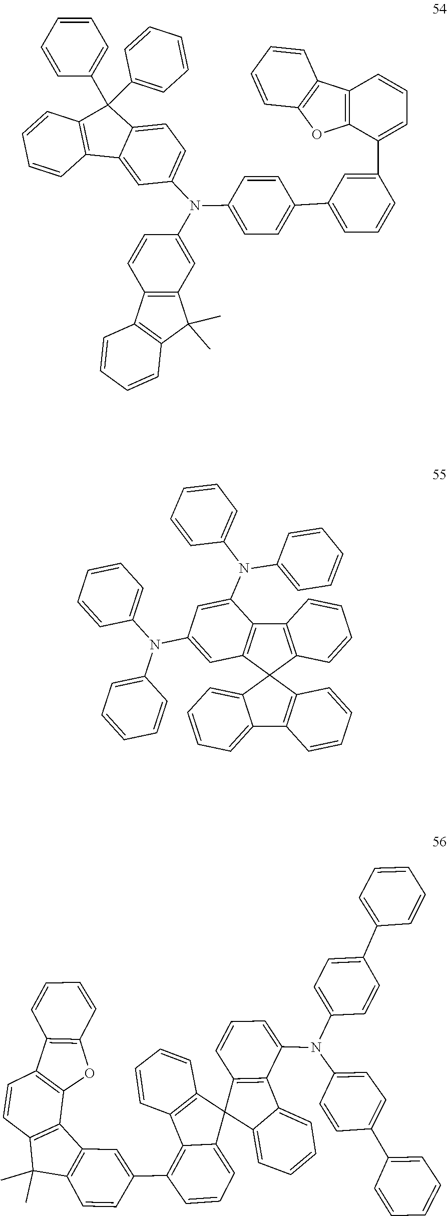 [SMILES: CC1(C)c2ccccc2-c2ccc(N(c3ccc(-c4cccc(-c5cccc6c5oc5ccccc56)c4)cc3)c3ccc4c(c3)-c3ccccc3C4(c3ccccc3)c3ccccc3)cc21 ; c1ccc(N(c2ccccc2)c2cc(N(c3ccccc3)c3ccccc3)c3c(c2)C2(c4ccccc4-c4ccccc42)c2ccccc2-3)cc1 ; CC1(C)c2ccc(-c3cccc4c3-c3ccccc3C43c4ccccc4-c4c(N(c5ccc(-c6ccccc6)cc5)c5ccc(-c6ccccc6)cc5)cccc43)cc2-c2c1ccc1c2oc2ccccc21]

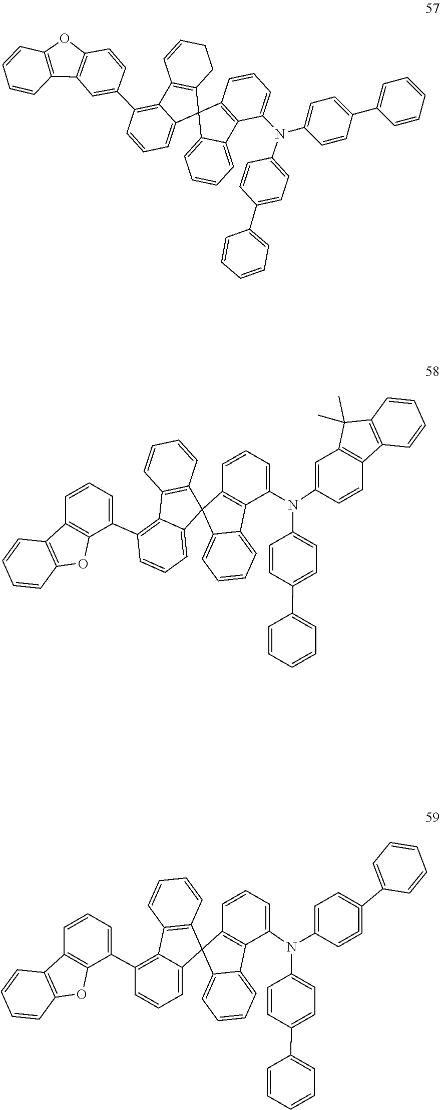

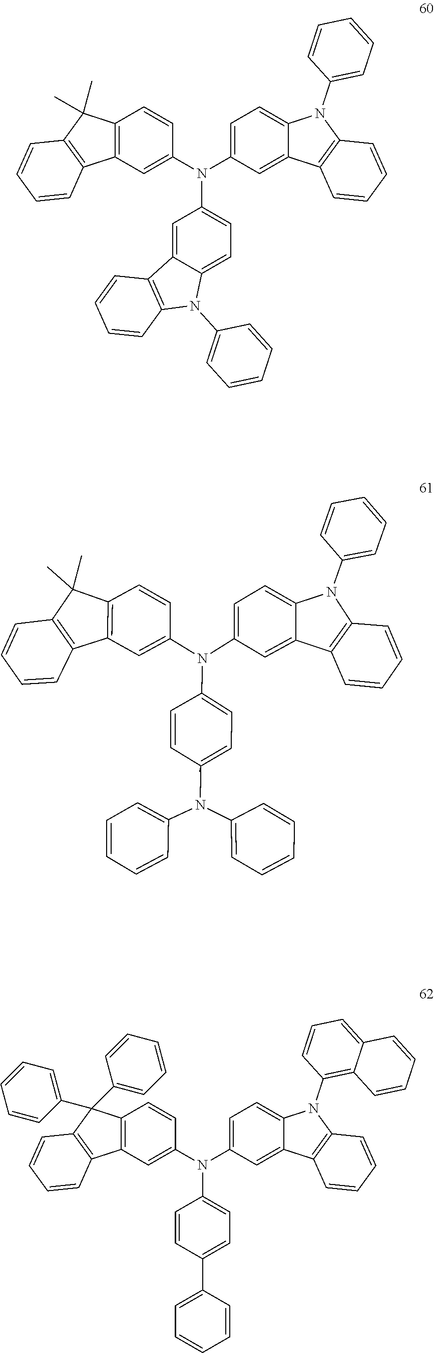

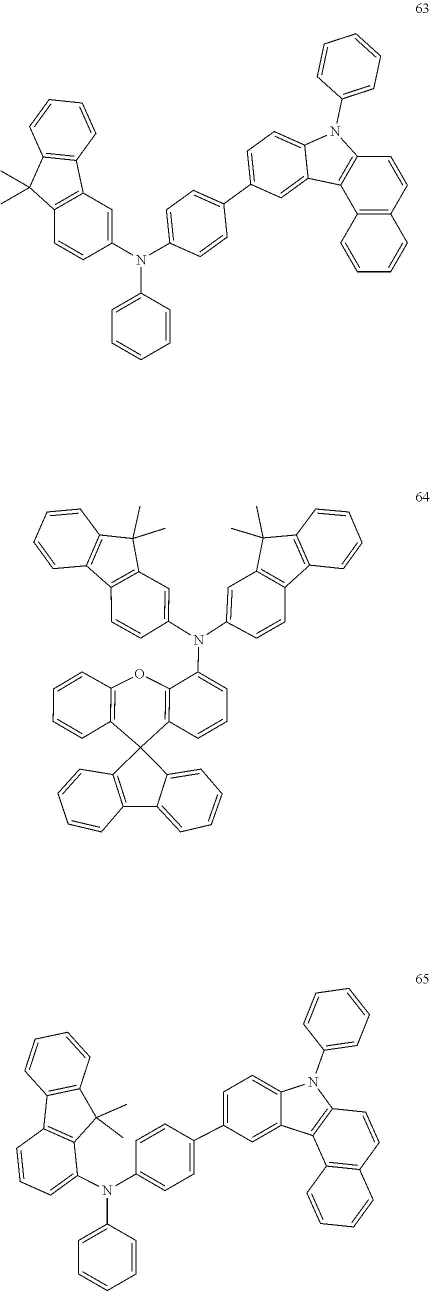 [SMILES: CC1(C)c2ccccc2-c2cc(N(c3ccccc3)c3ccc(-c4ccc5c(c4)c4c6ccccc6ccc4n5-c4ccccc4)cc3)ccc21 ; CC1(C)c2ccccc2-c2ccc(N(c3ccc4c(c3)C(C)(C)c3ccccc3-4)c3cccc4c3Oc3ccccc3C43c4ccccc4-c4ccccc43)cc21 ; CC1(C)c2ccccc2-c2cccc(N(c3ccccc3)c3ccc(-c4ccc5c(c4)c4c6ccccc6ccc4n5-c4ccccc4)cc3)c21]

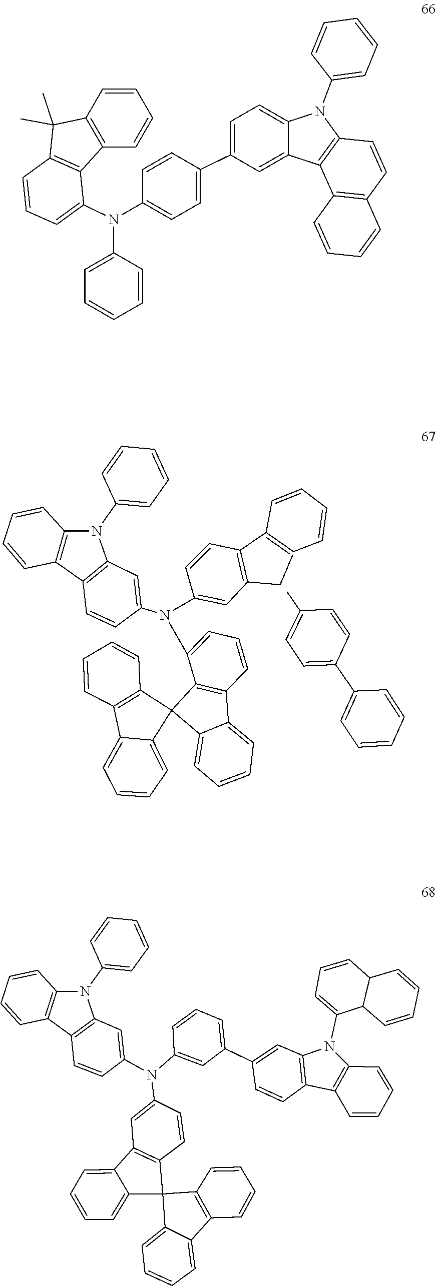

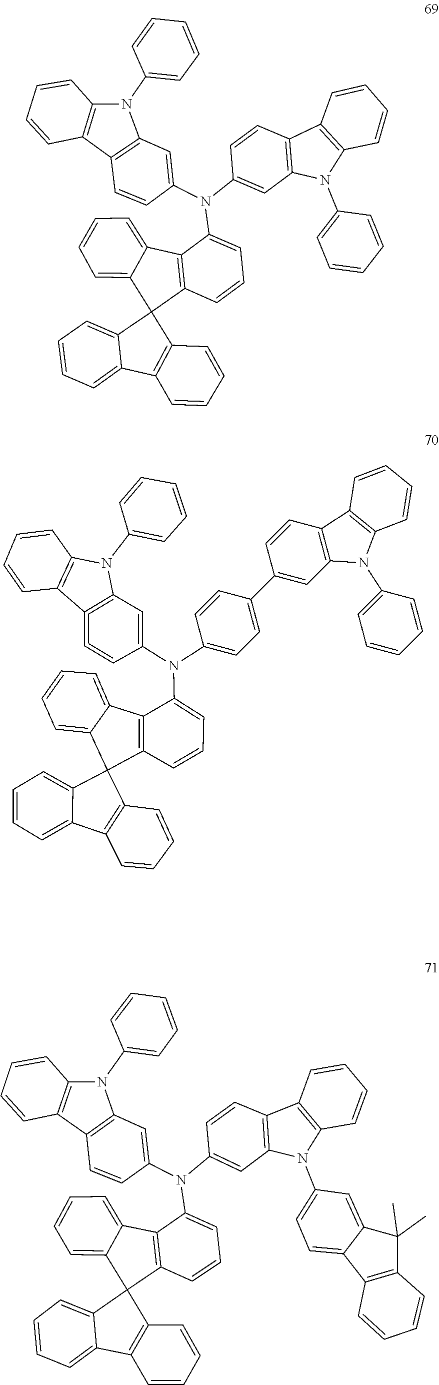

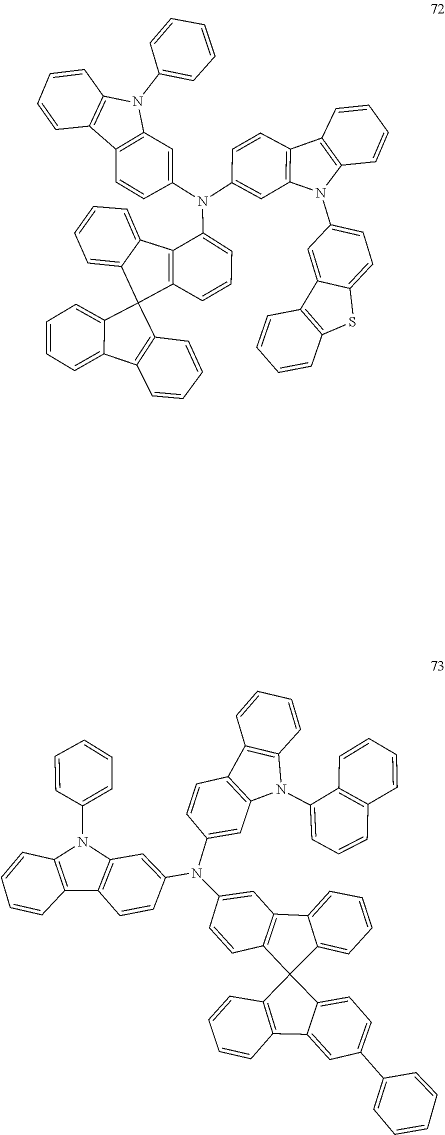 [SMILES: c1ccc(-n2c3ccccc3c3ccc(N(c4ccc5c6ccccc6n(-c6ccc7sc8ccccc8c7c6)c5c4)c4cccc5c4-c4ccccc4C54c5ccccc5-c5ccccc54)cc32)cc1 ; c1ccc(-c2ccc3c(c2)-c2ccccc2C32c3ccccc3-c3cc(N(c4ccc5c6ccccc6n(-c6ccccc6)c5c4)c4ccc5c6ccccc6n(-c6cccc7ccccc67)c5c4)ccc32)cc1]

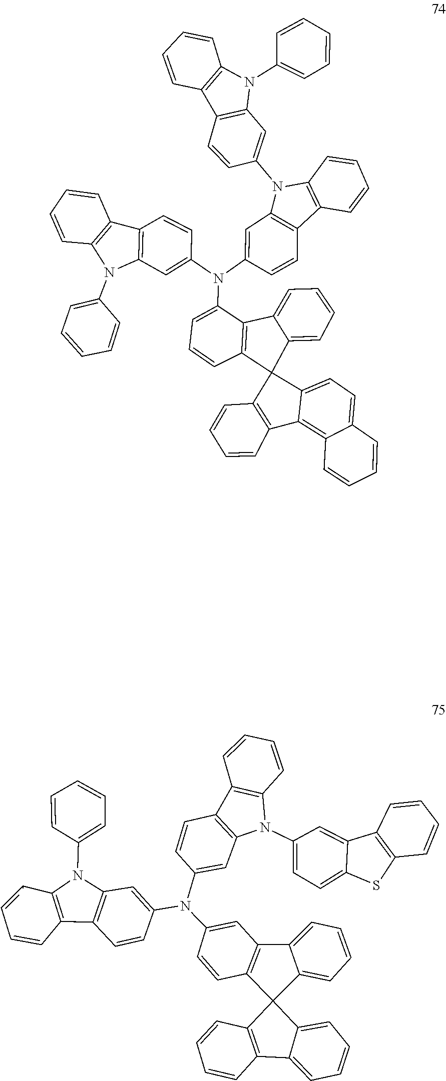

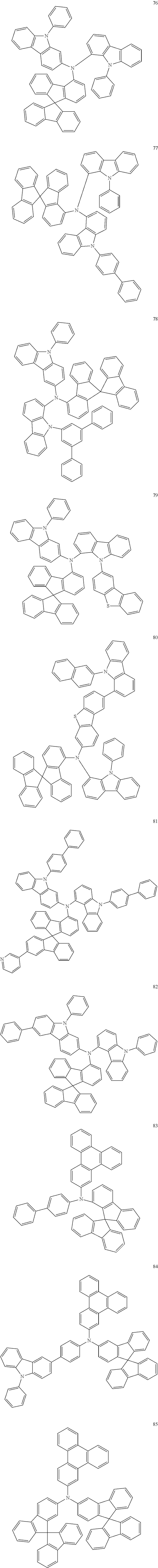

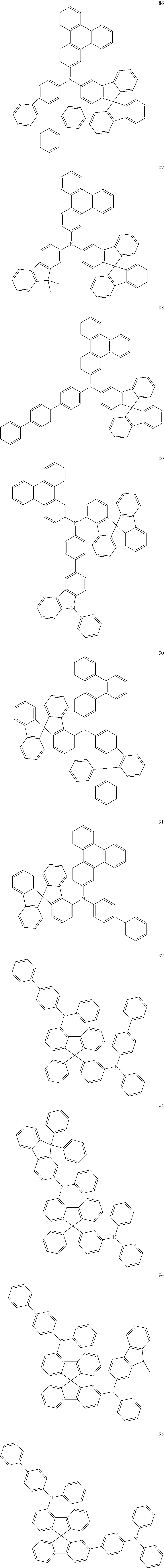

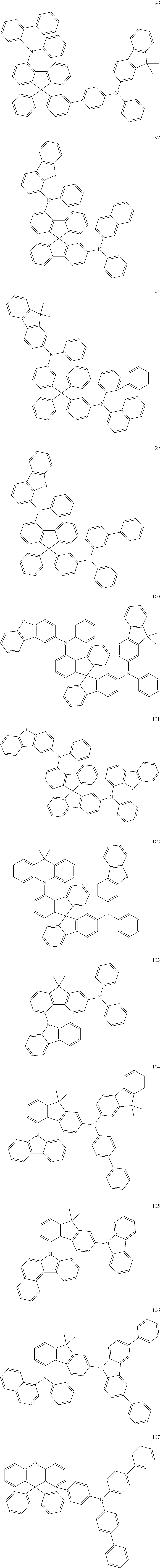

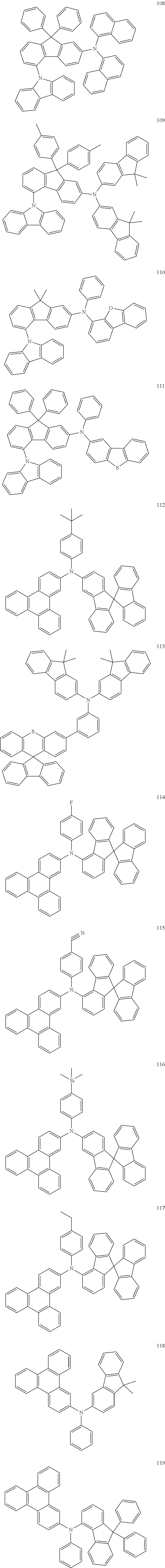

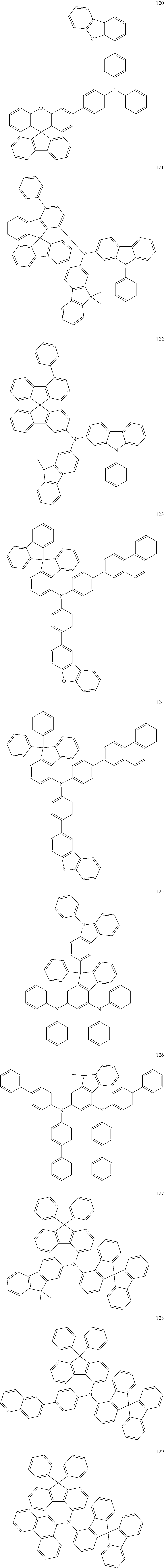

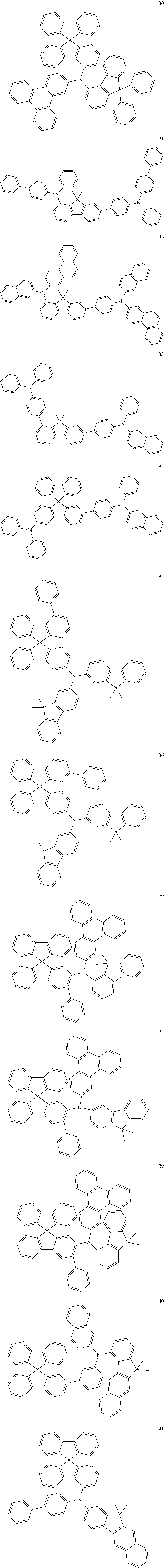

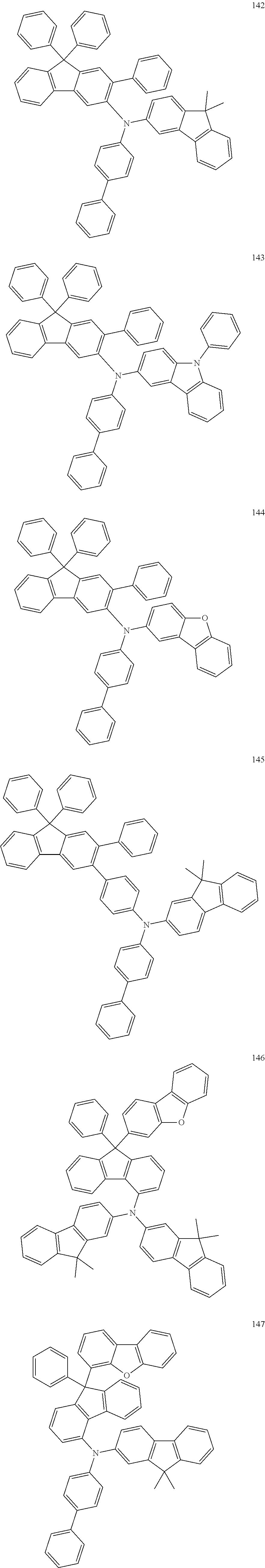

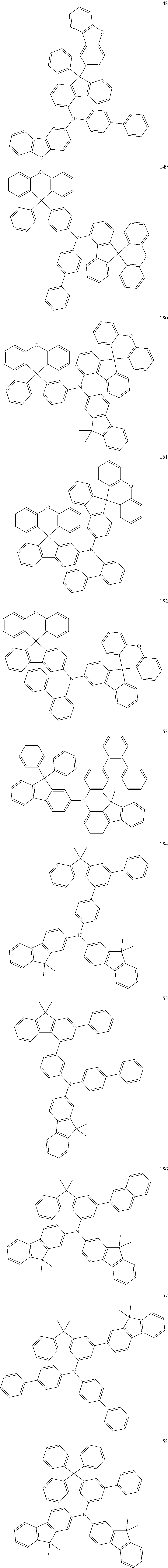

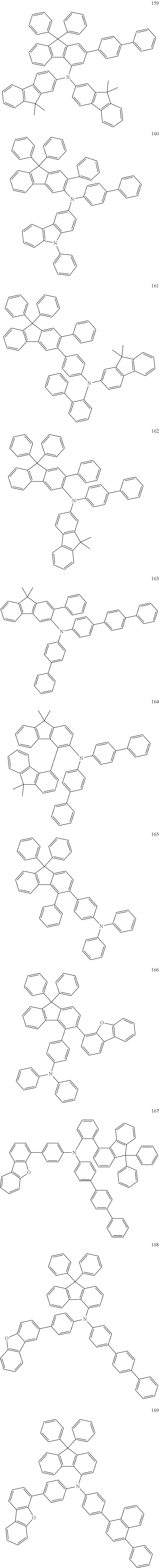

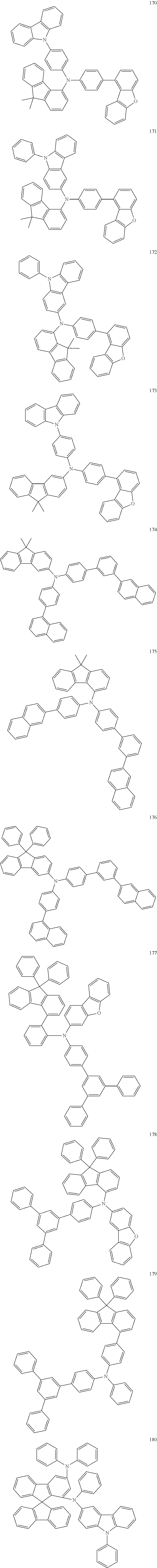

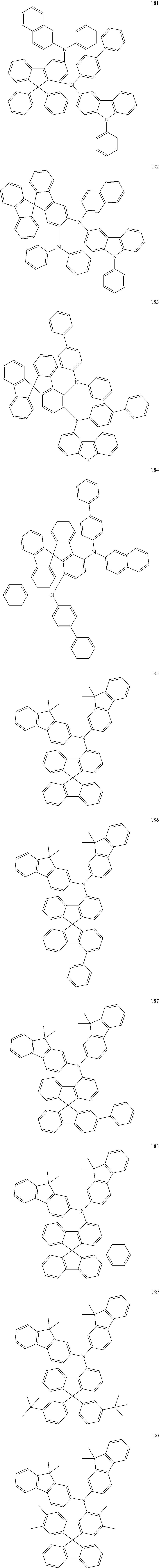

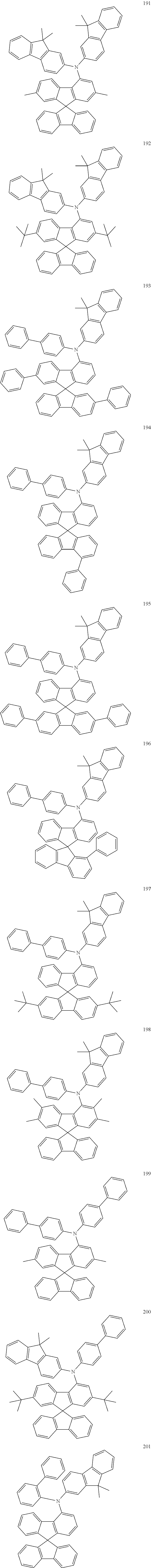

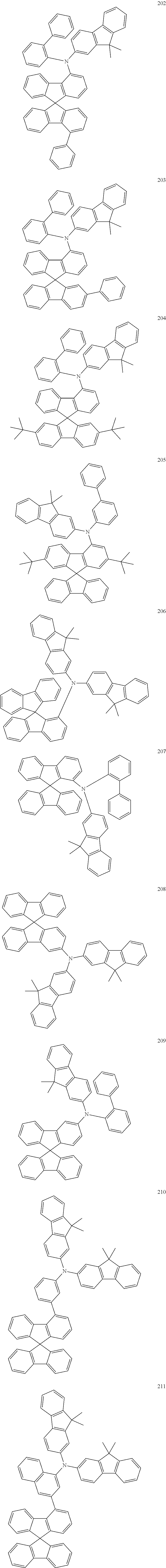

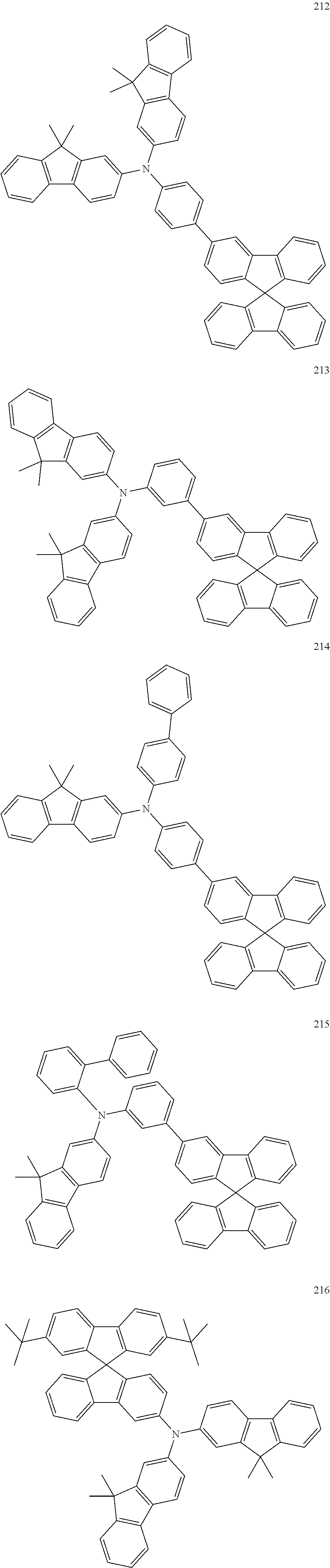

It is also preferred that the electron-blocking layers EBL1, EBL2 and/or EBL3 comprise, identically or differently, a hole-transport material selected from compounds of formula (A) as defined above. More preferably, the electron-blocking layers EBL1, EBL2 and/or EBL3 comprise, identically or differently, a hole-transport material selected from compounds of formula (A-I) to (A-IX) as defined above.

Suitable examples of hole-transport material for the electron-blocking layers EBL1, EBL2 and EBL3 are the compounds 301 to 565 as depicted above as well as the compounds depicted below:

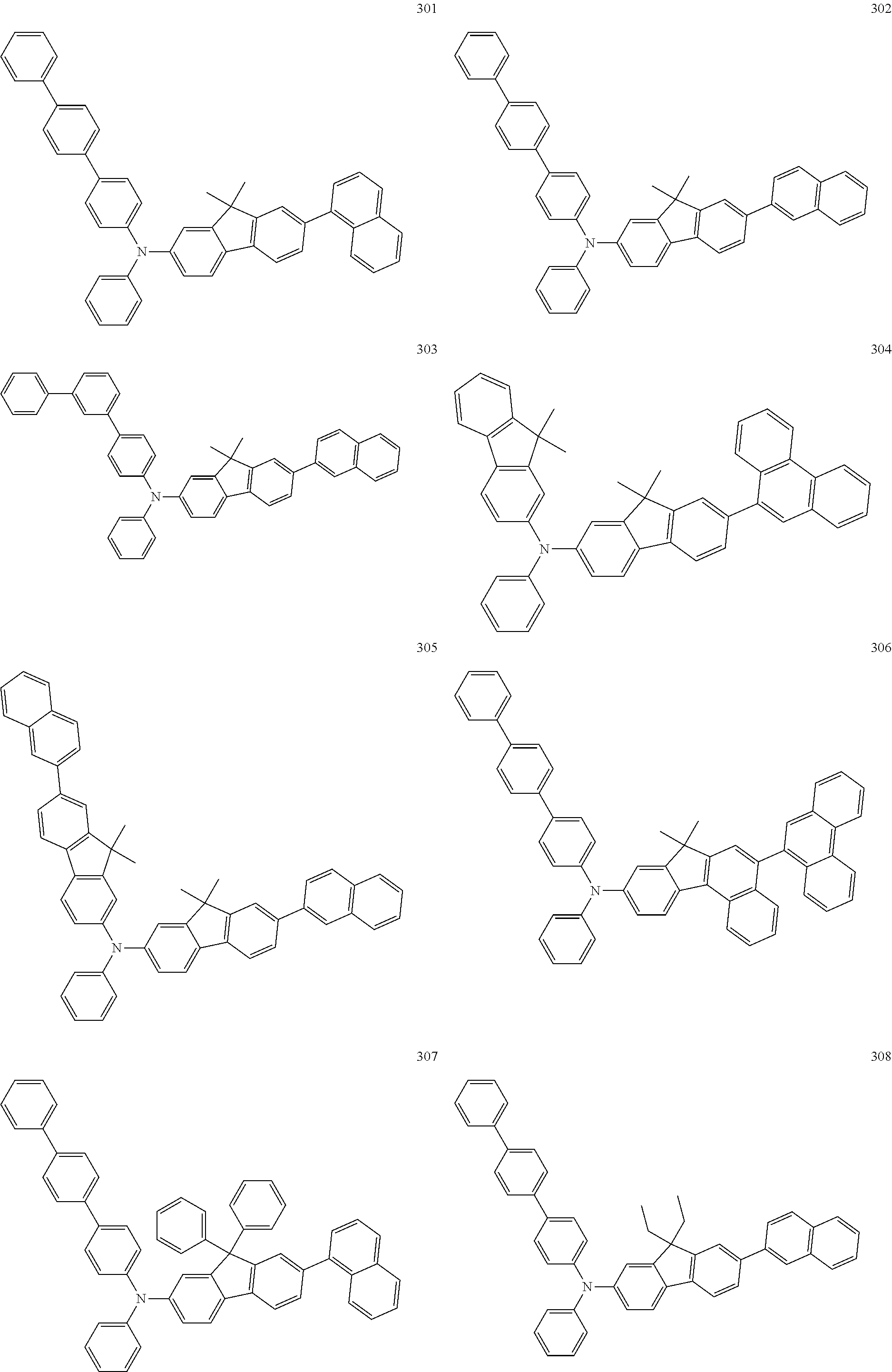

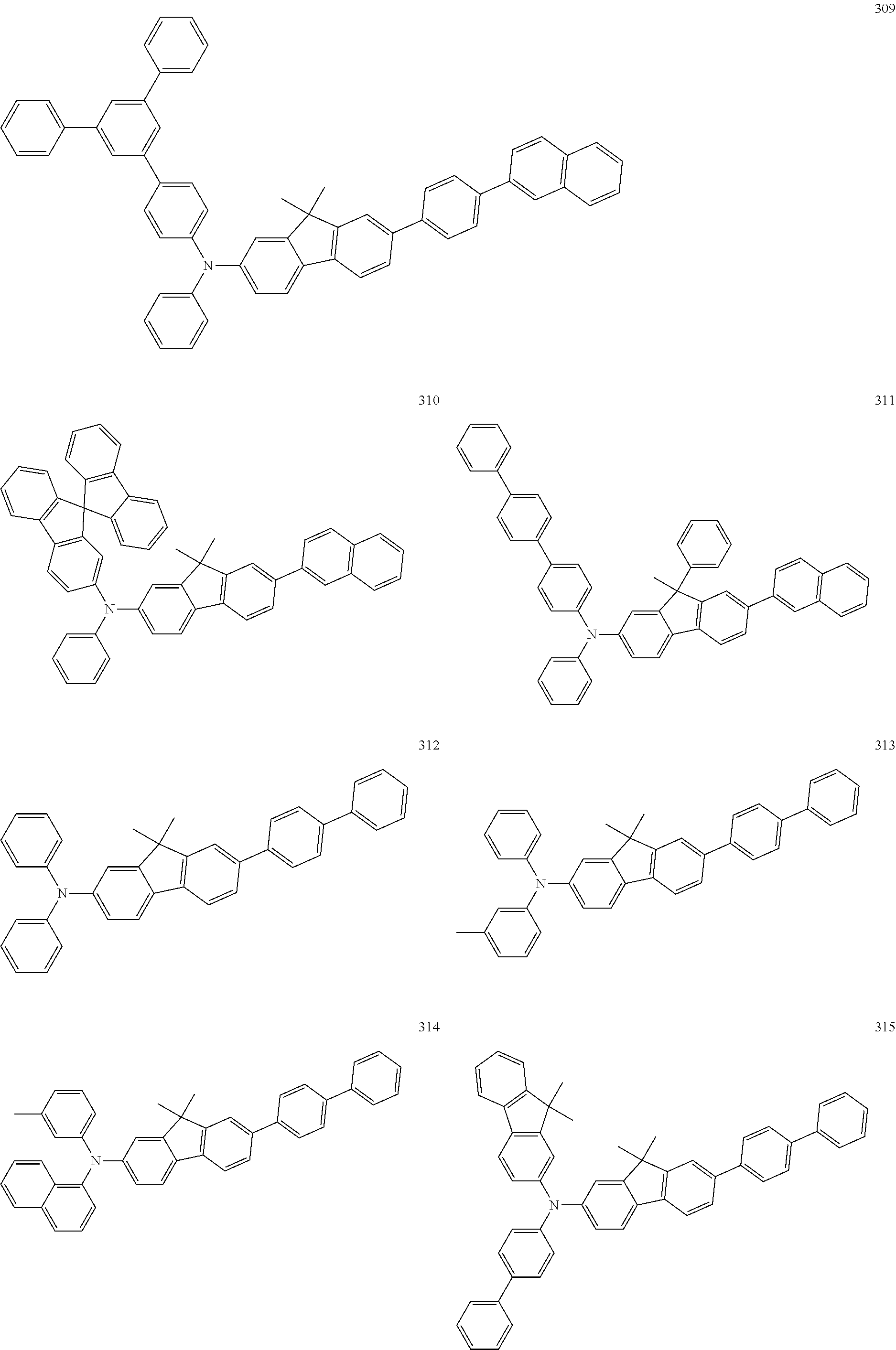

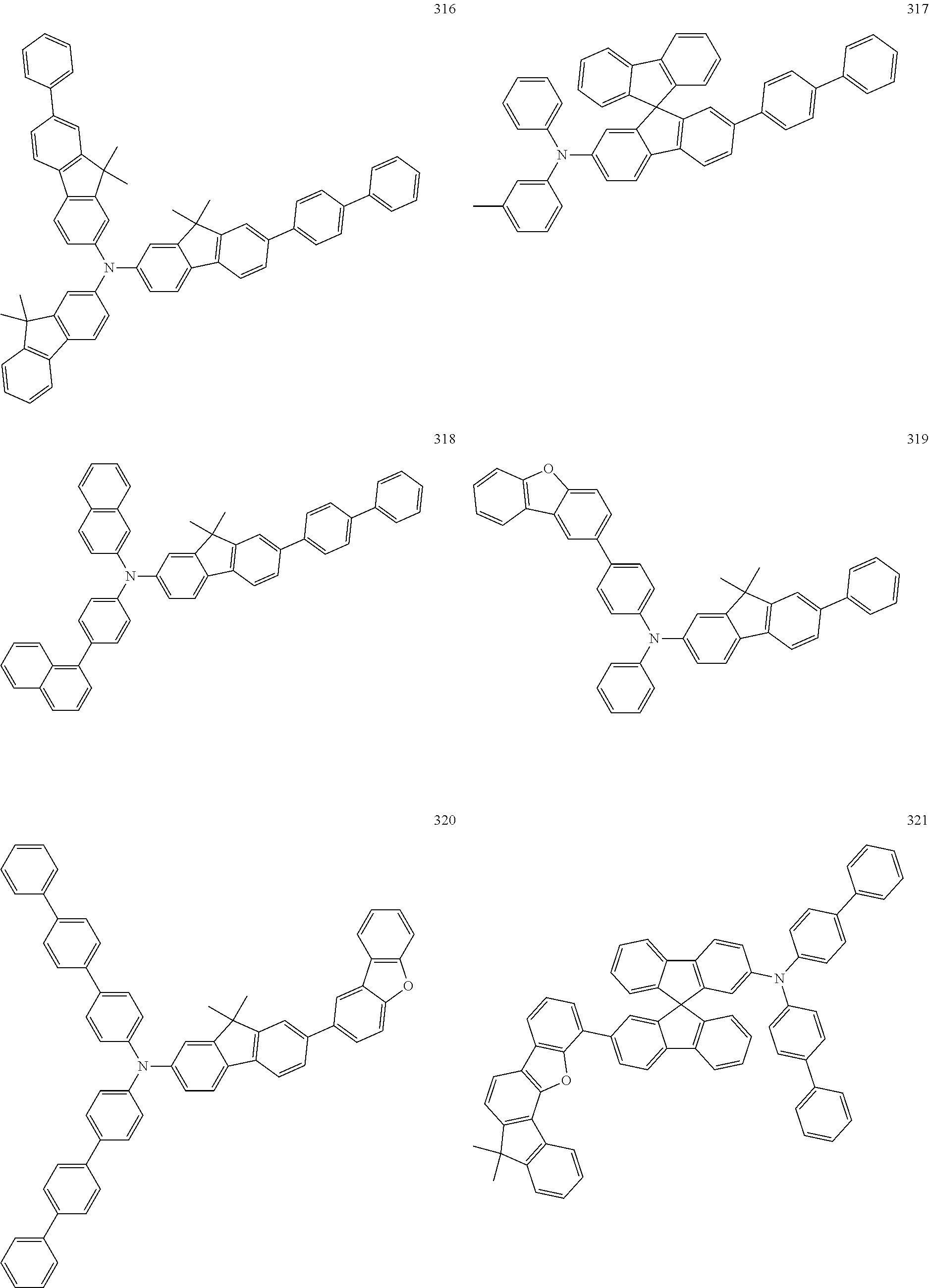

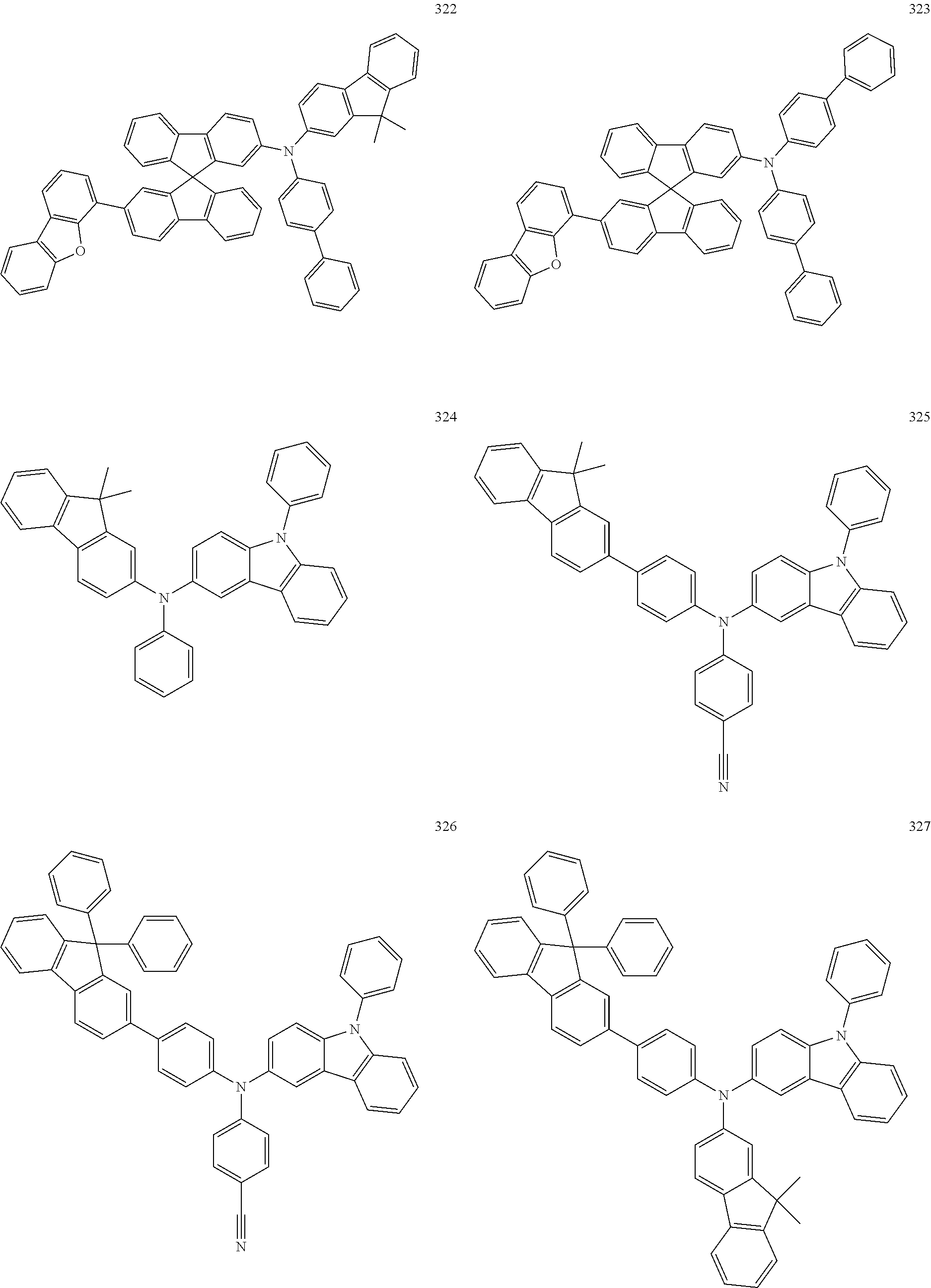

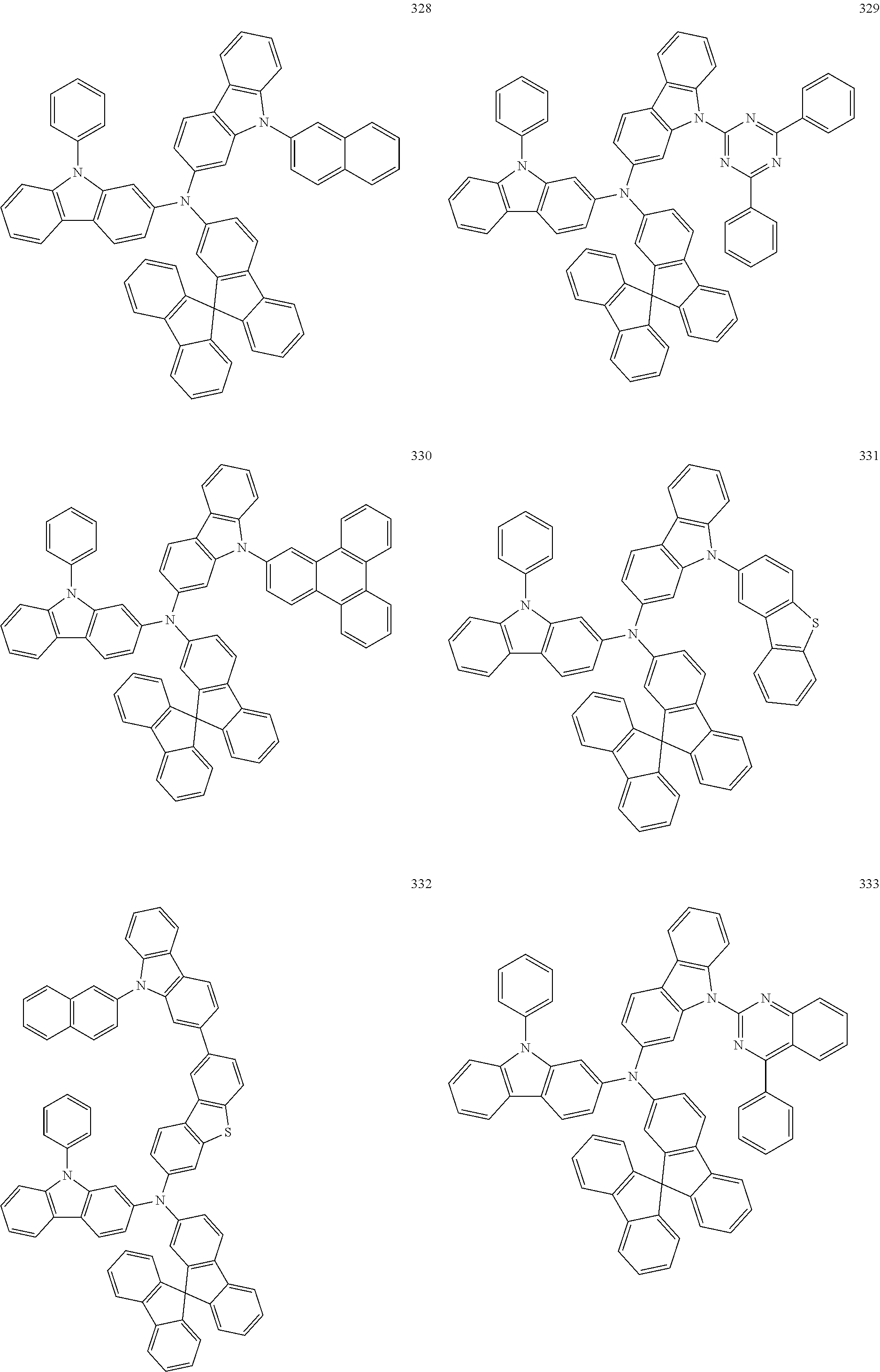

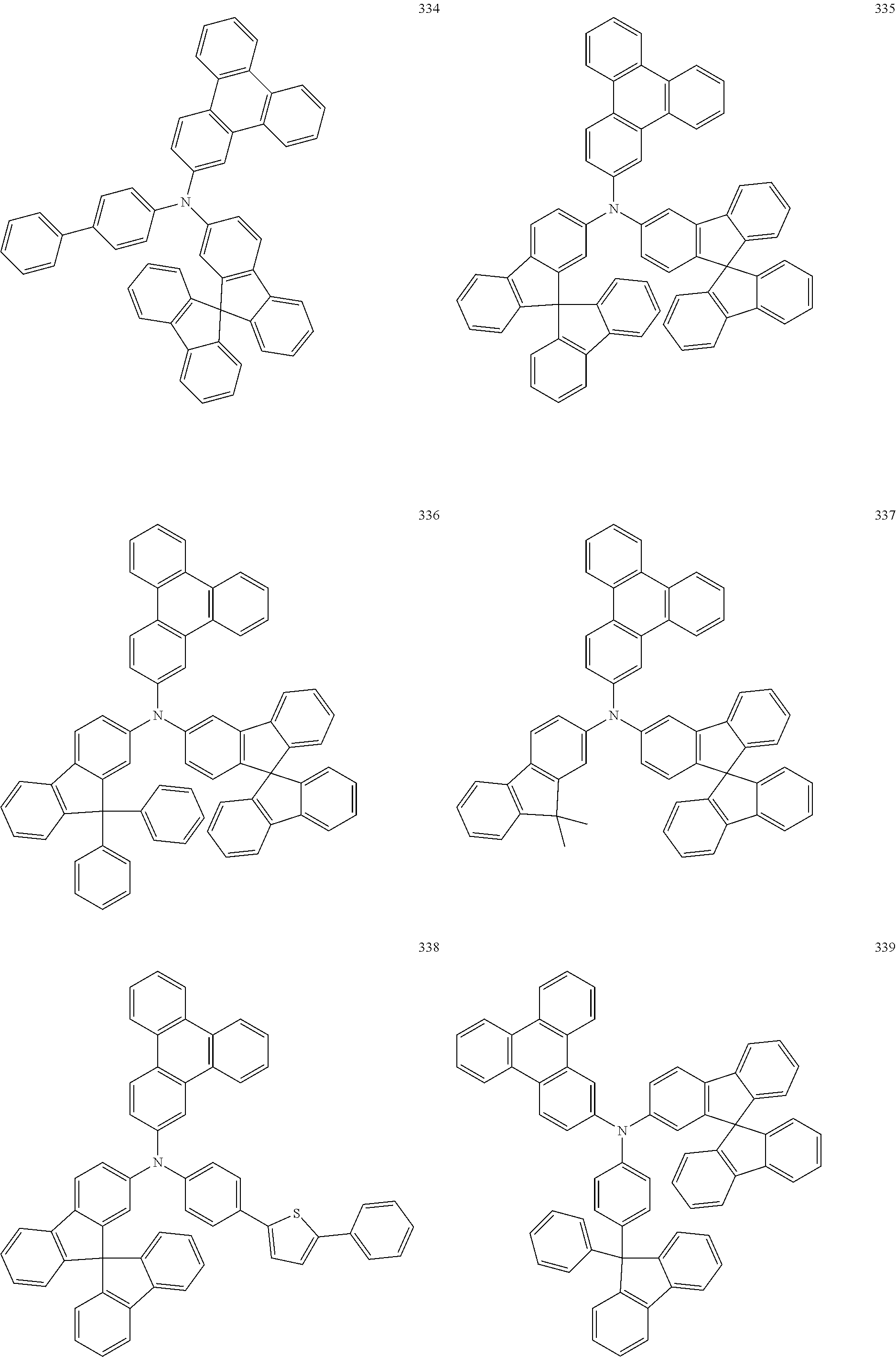

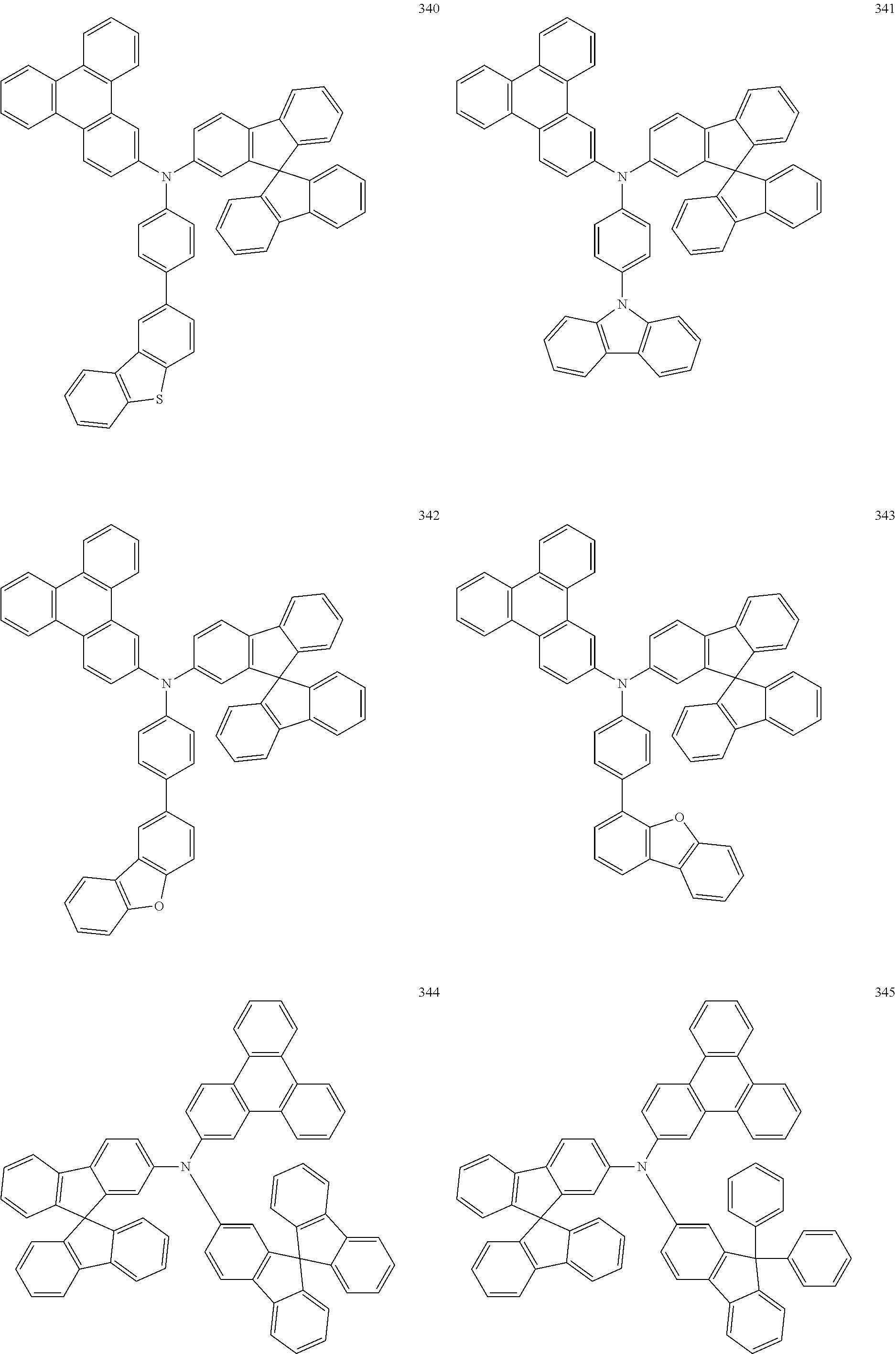

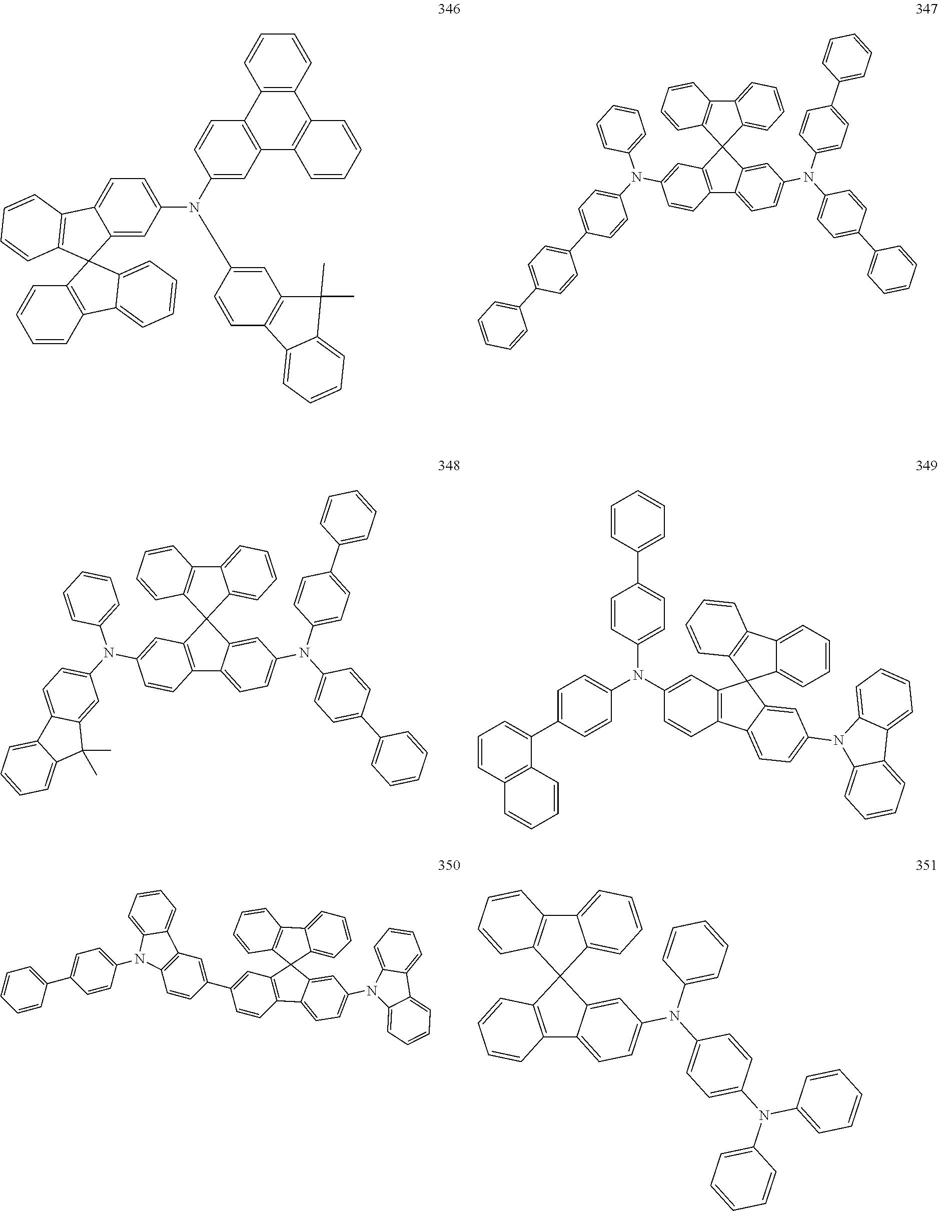

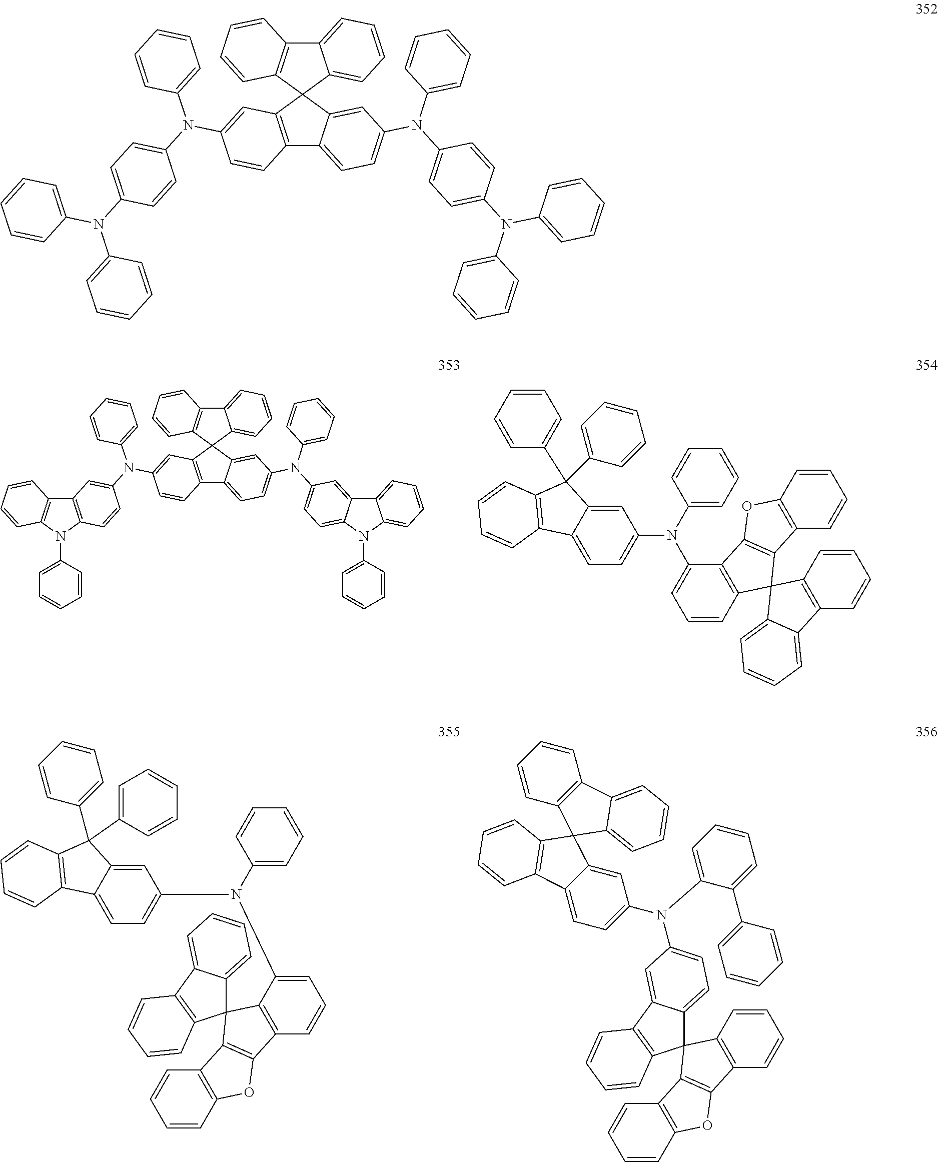

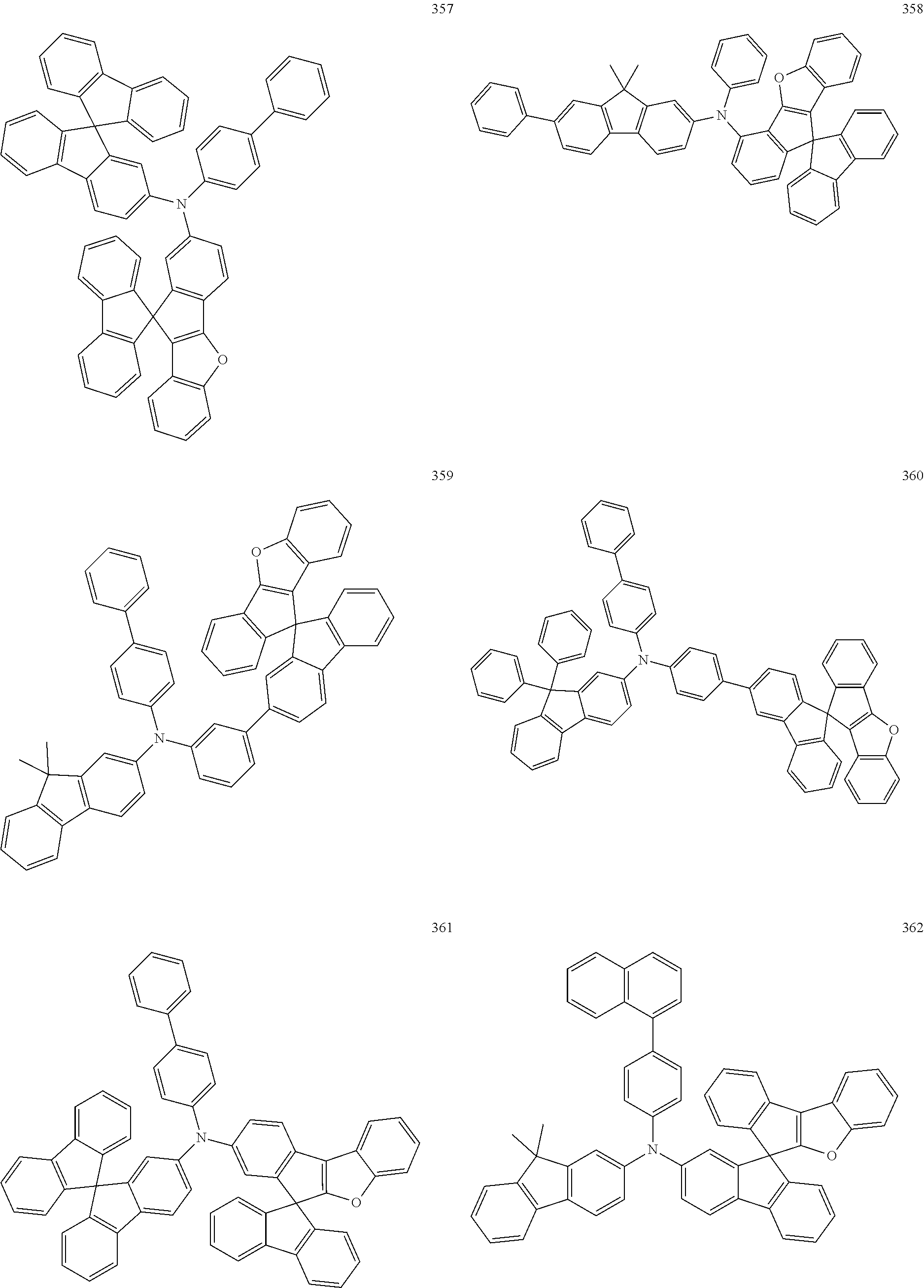

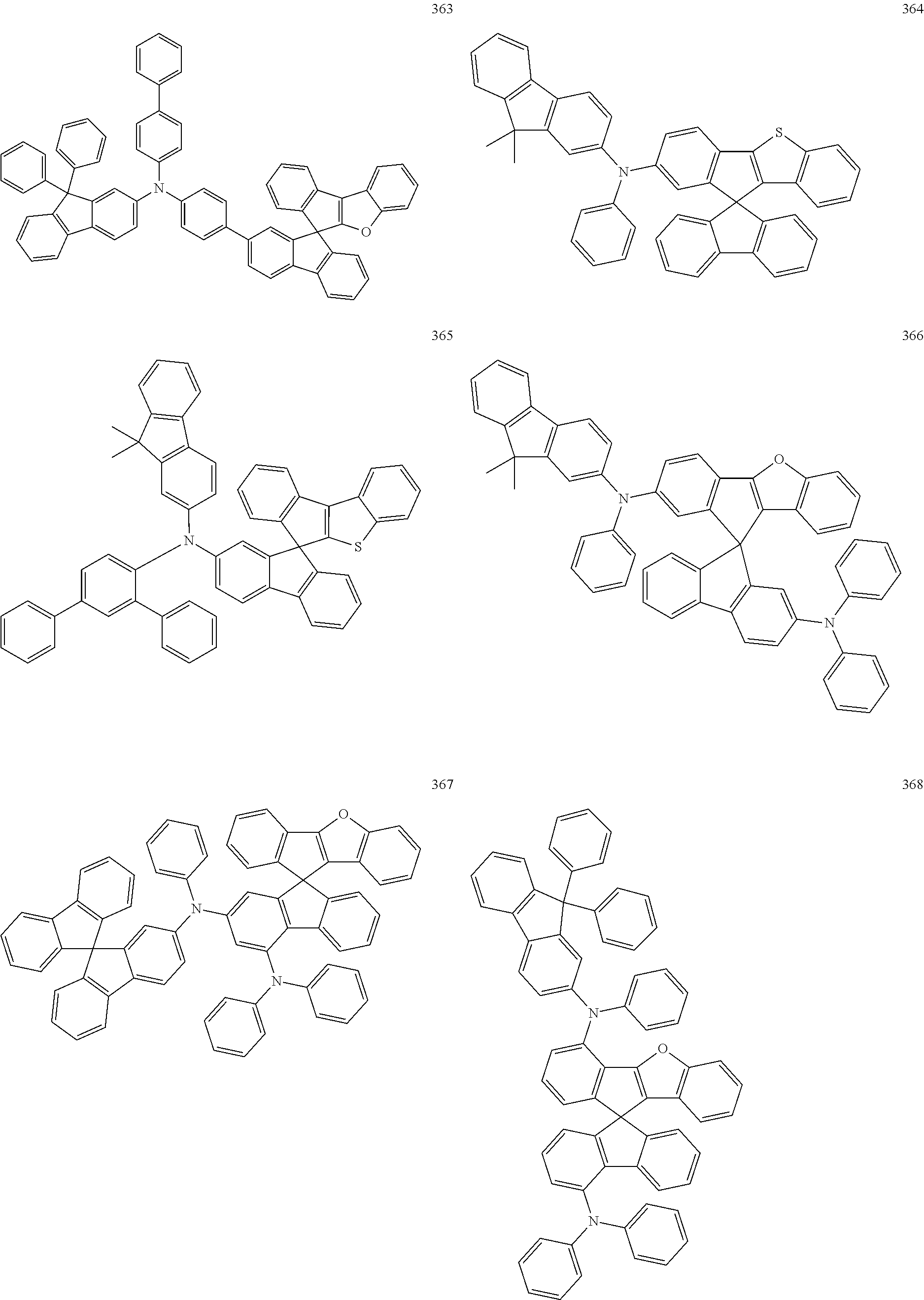

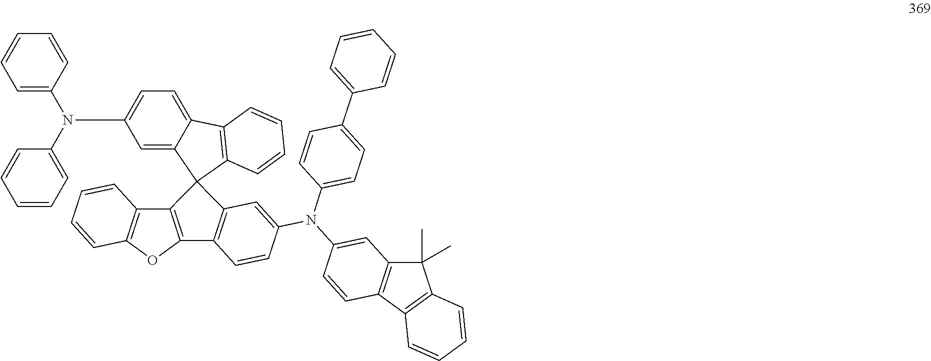 [SMILES: CC1(C)c2ccccc2-c2ccc(N(c3ccc(-c4ccccc4)cc3)c3ccc4c(c3)C3(c5ccccc5-c5ccc(N(c6ccccc6)c6ccccc6)cc53)c3c-4oc4ccccc34)cc21]

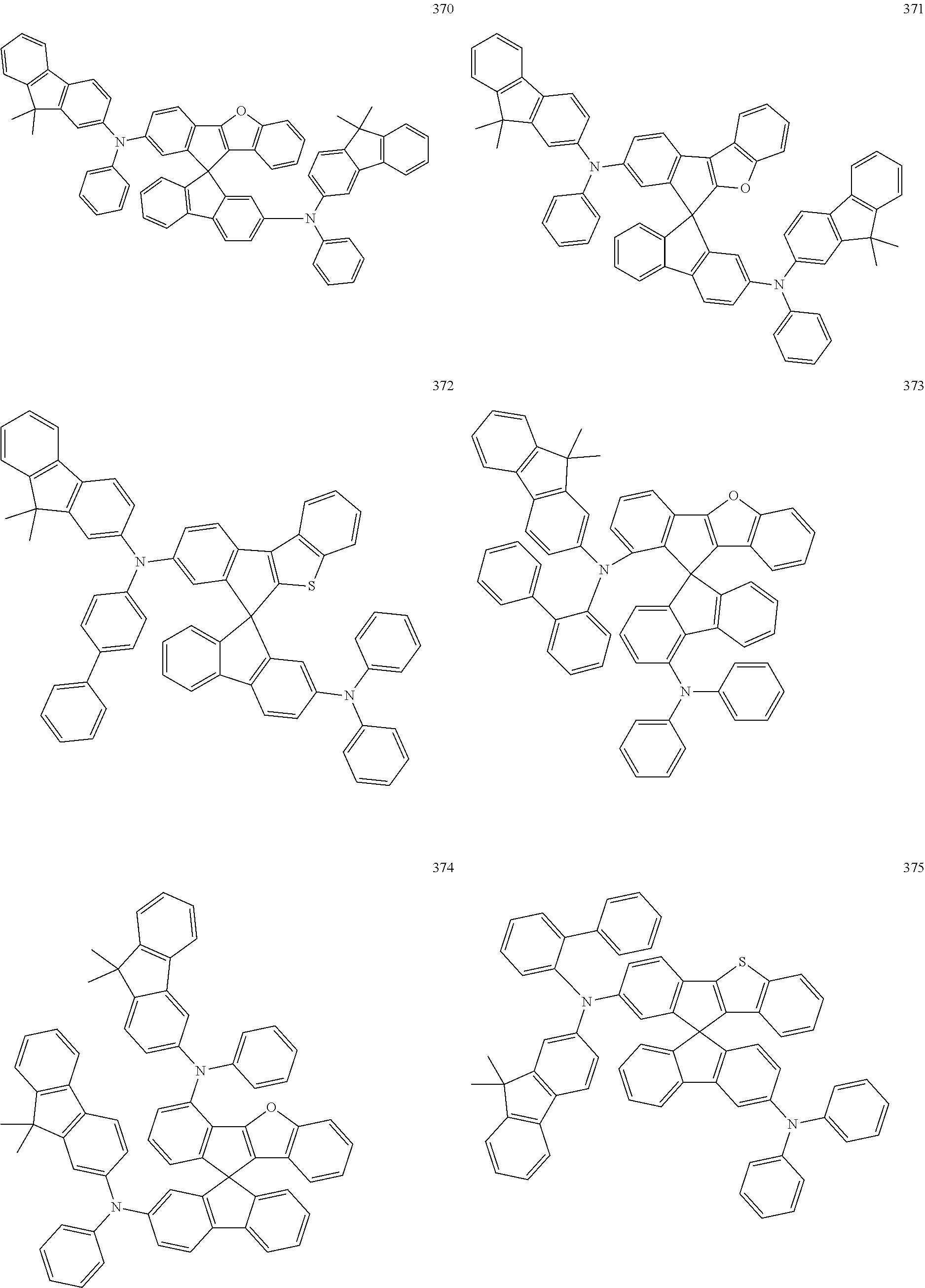

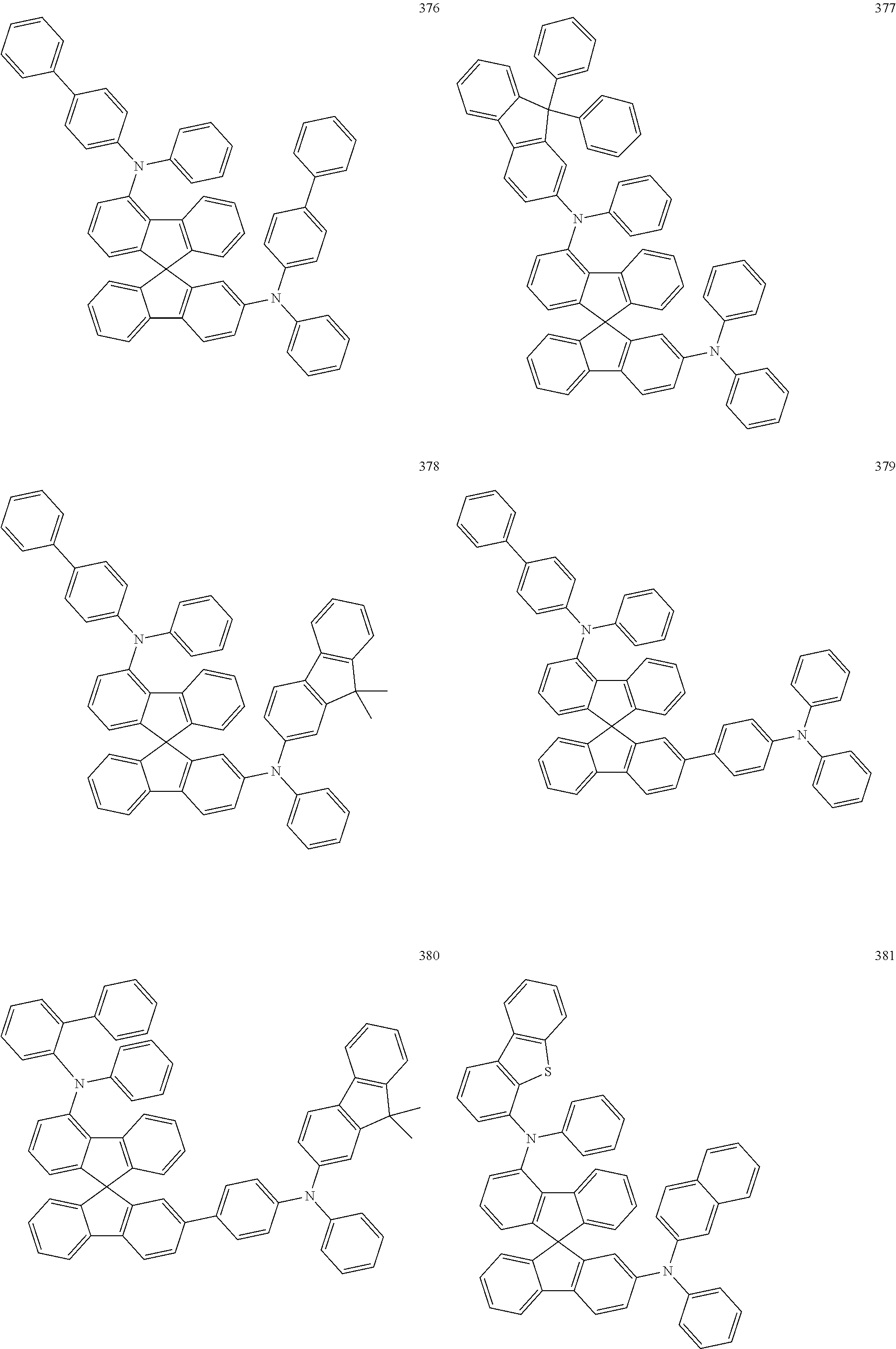

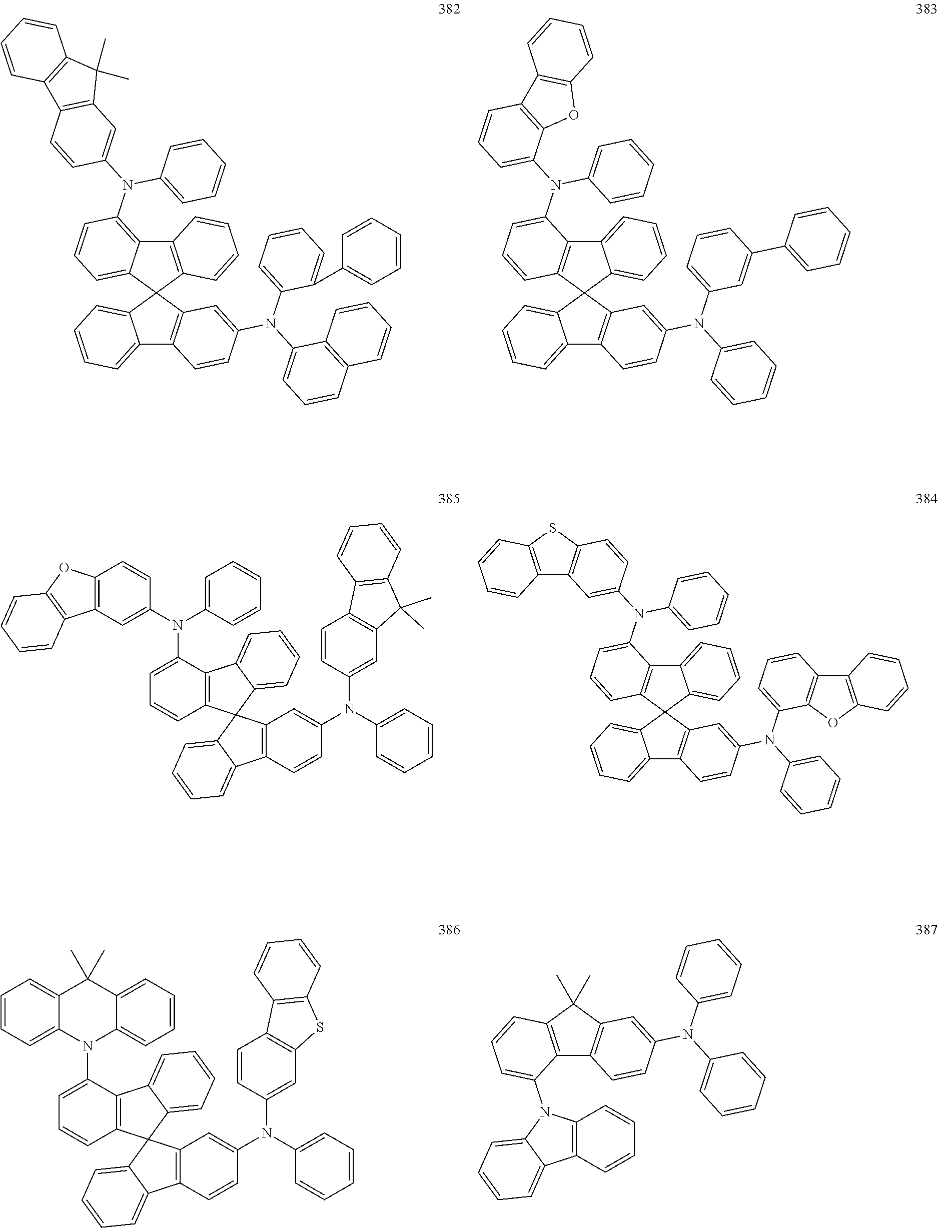

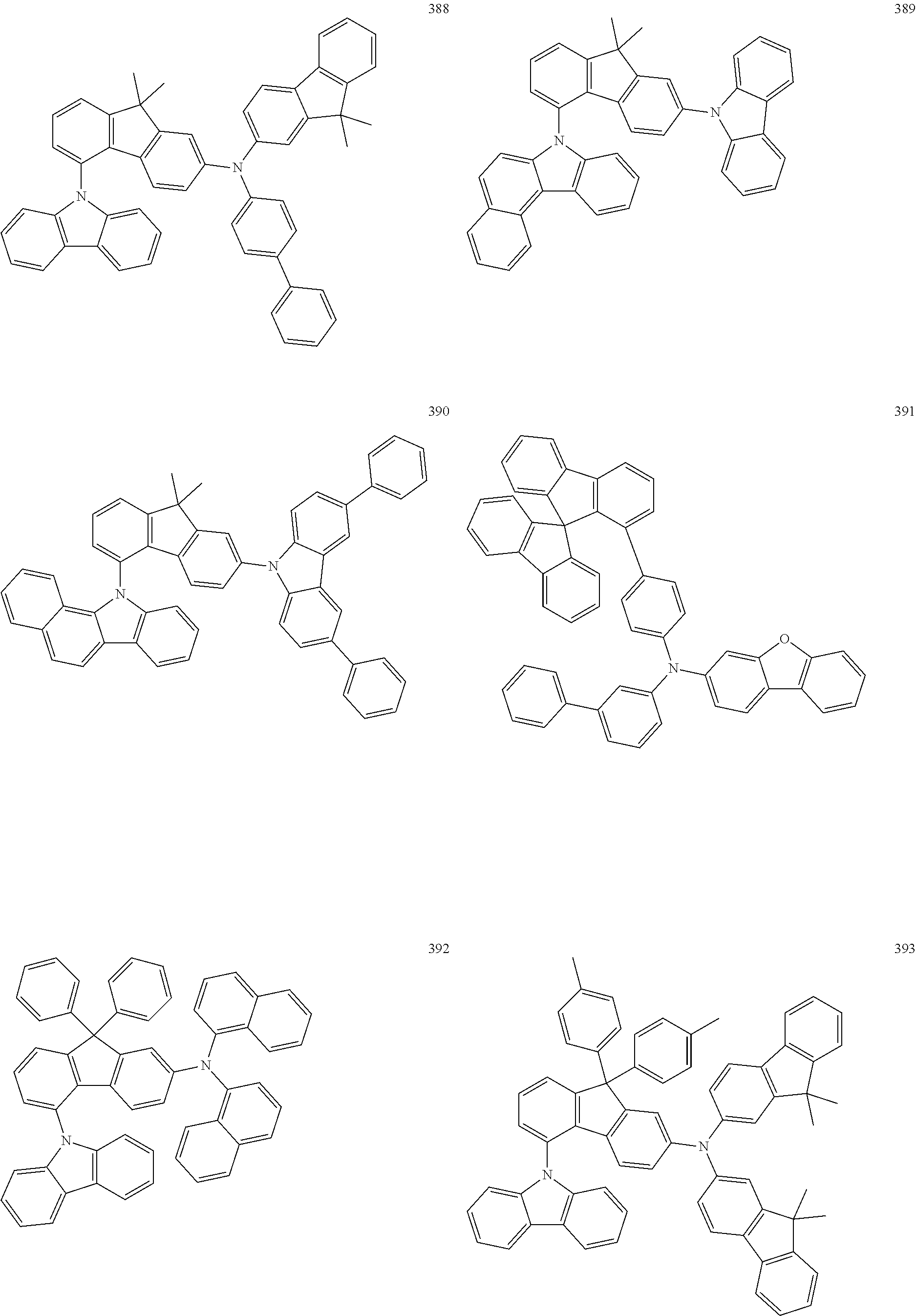

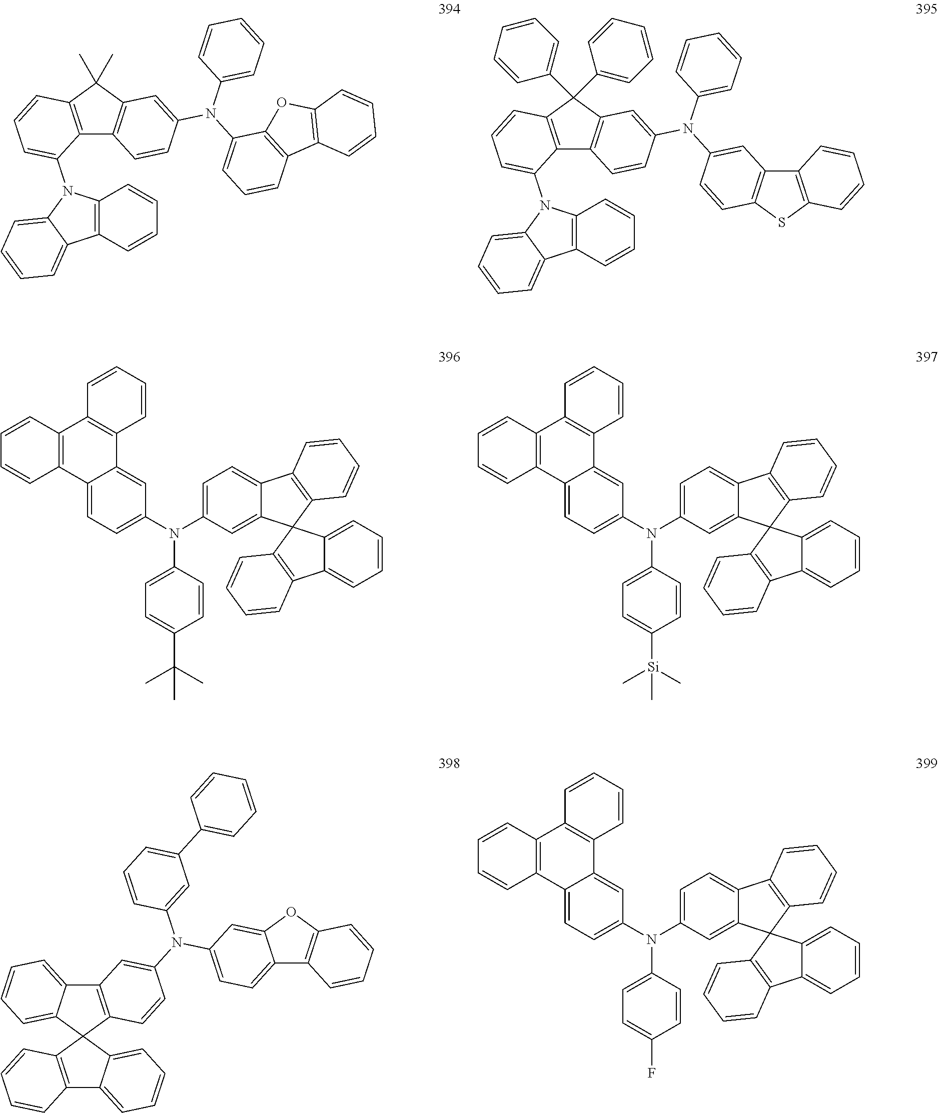

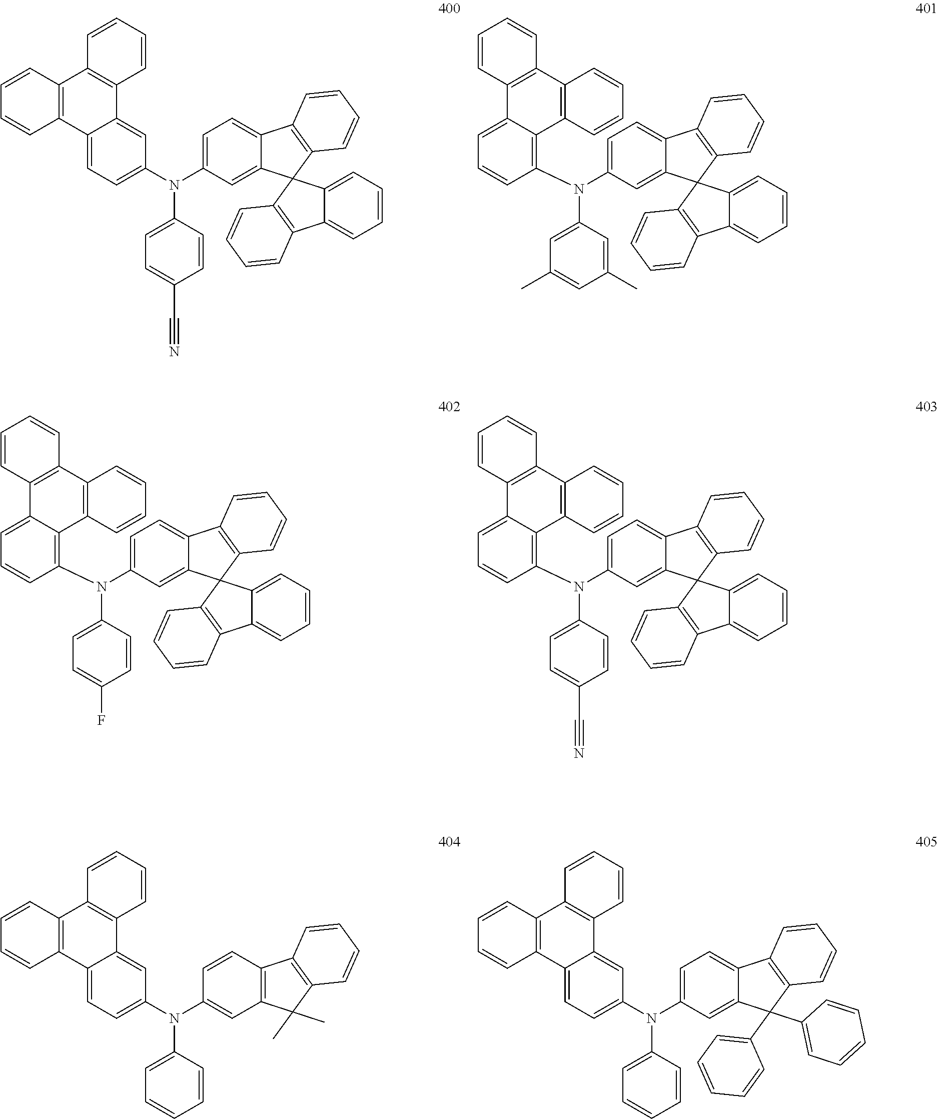 [SMILES: N#Cc1ccc(N(c2ccc3c(c2)C2(c4ccccc4-c4ccccc42)c2ccccc2-3)c2ccc3c4ccccc4c4ccccc4c3c2)cc1 ; Cc1cc(C)cc(N(c2ccc3c(c2)C2(c4ccccc4-c4ccccc42)c2ccccc2-3)c2cccc3c4ccccc4c4ccccc4c23)c1 ; Fc1ccc(N(c2ccc3c(c2)C2(c4ccccc4-c4ccccc42)c2ccccc2-3)c2cccc3c4ccccc4c4ccccc4c23)cc1 ; N#Cc1ccc(N(c2ccc3c(c2)C2(c4ccccc4-c4ccccc42)c2ccccc2-3)c2cccc3c4ccccc4c4ccccc4c23)cc1 ; CC1(C)c2ccccc2-c2ccc(N(c3ccccc3)c3ccc4c5ccccc5c5ccccc5c4c3)cc21 ; c1ccc(N(c2ccc3c(c2)C(c2ccccc2)(c2ccccc2)c2ccccc2-3)c2ccc3c4ccccc4c4ccccc4c3c2)cc1]

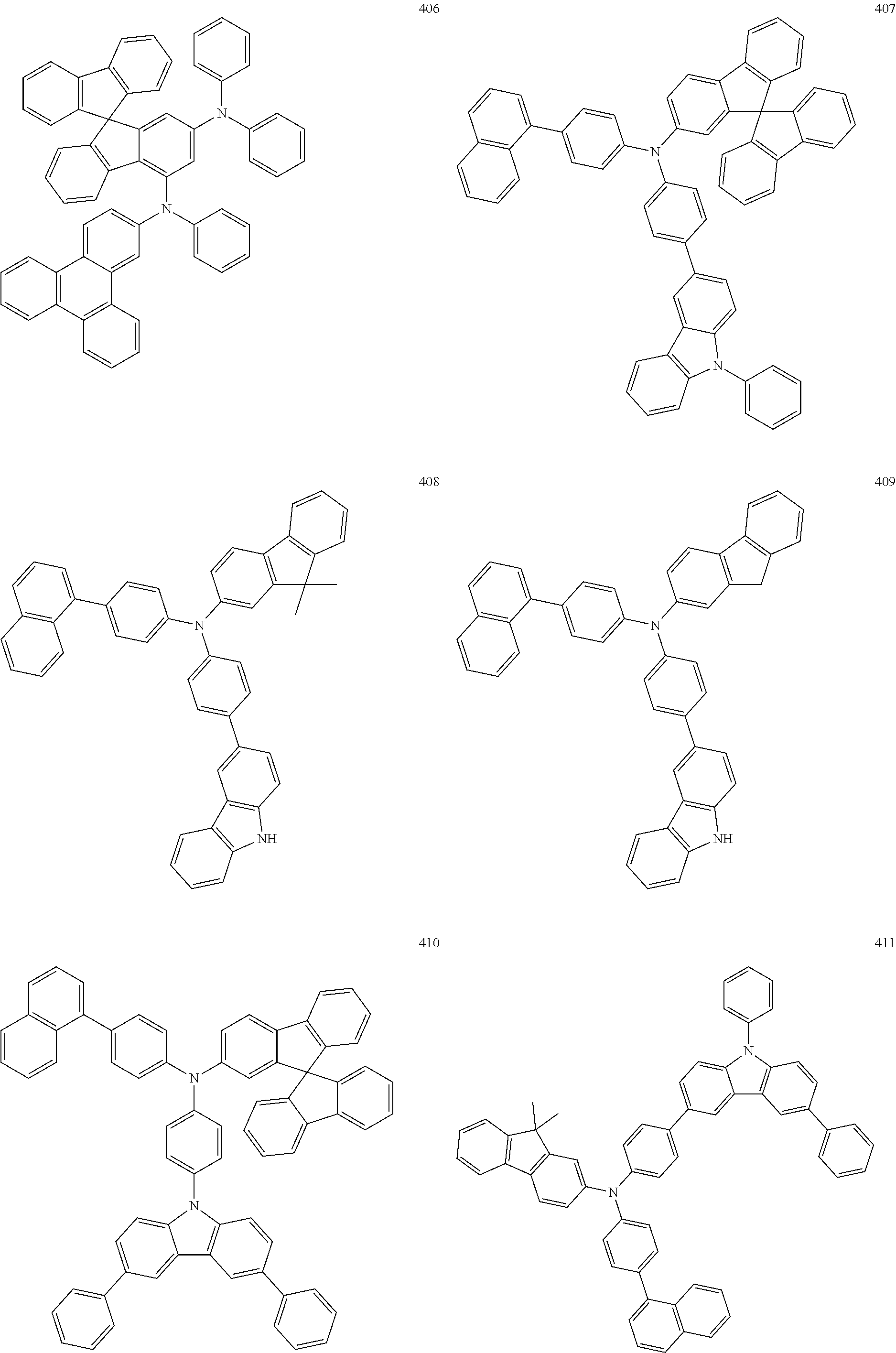

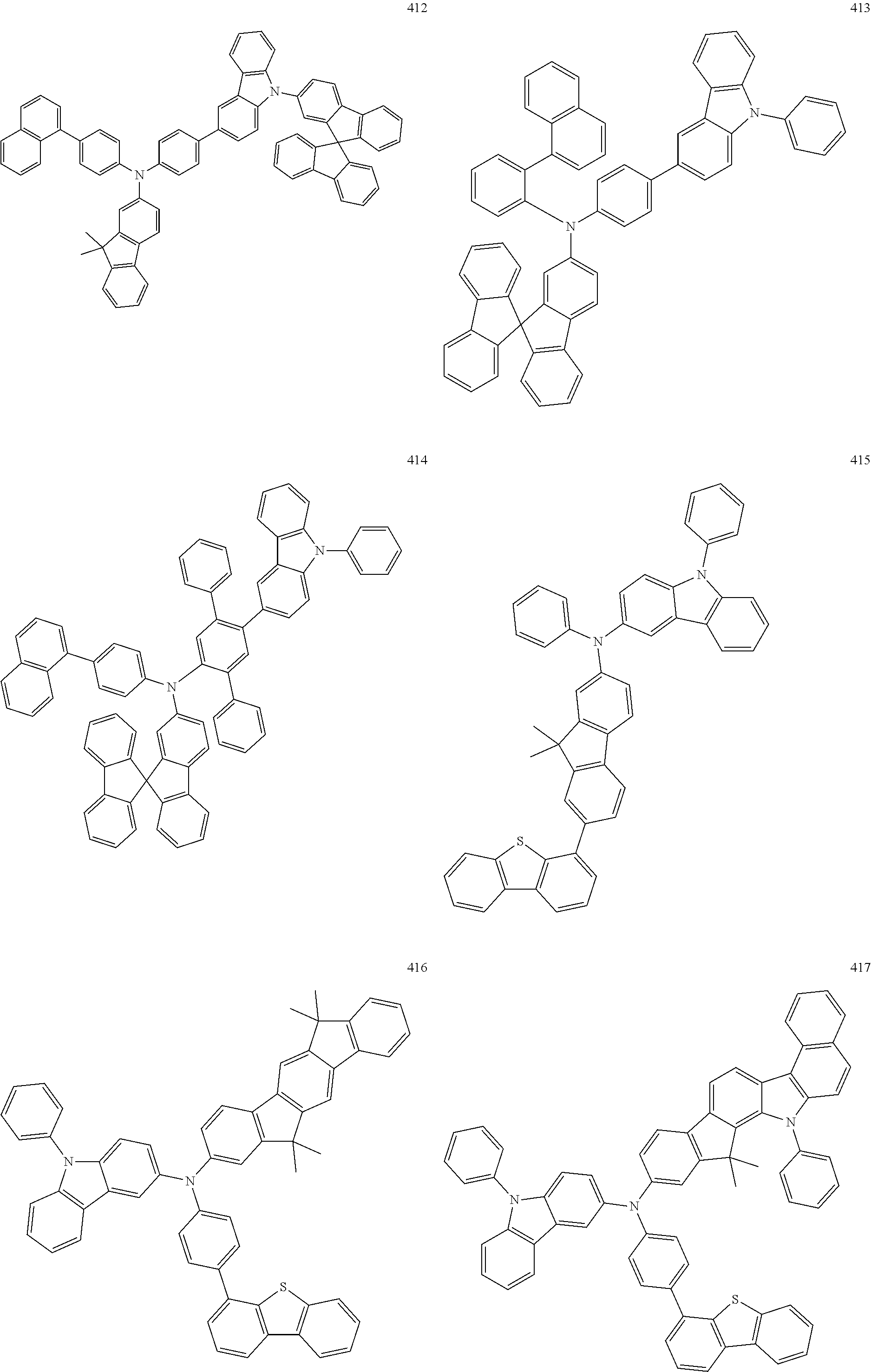

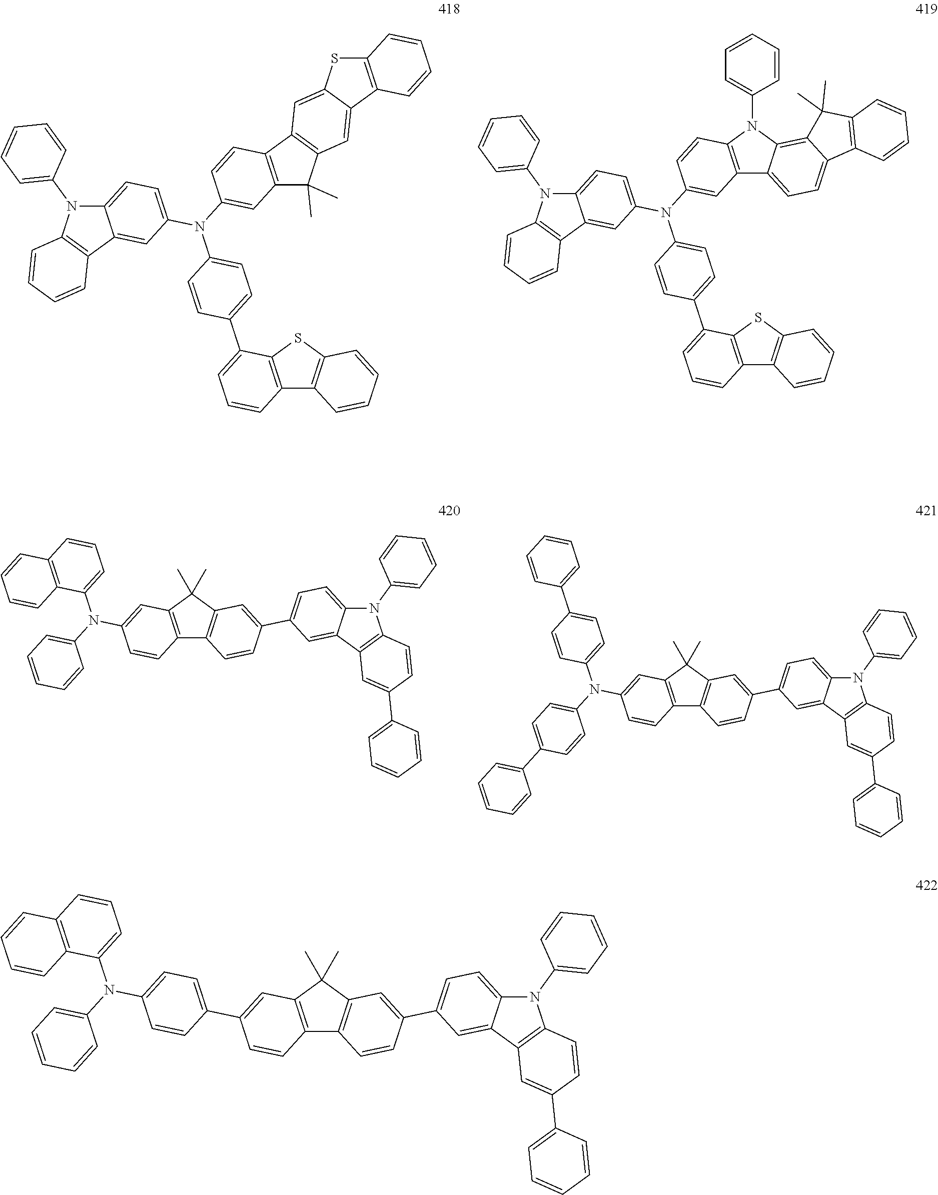

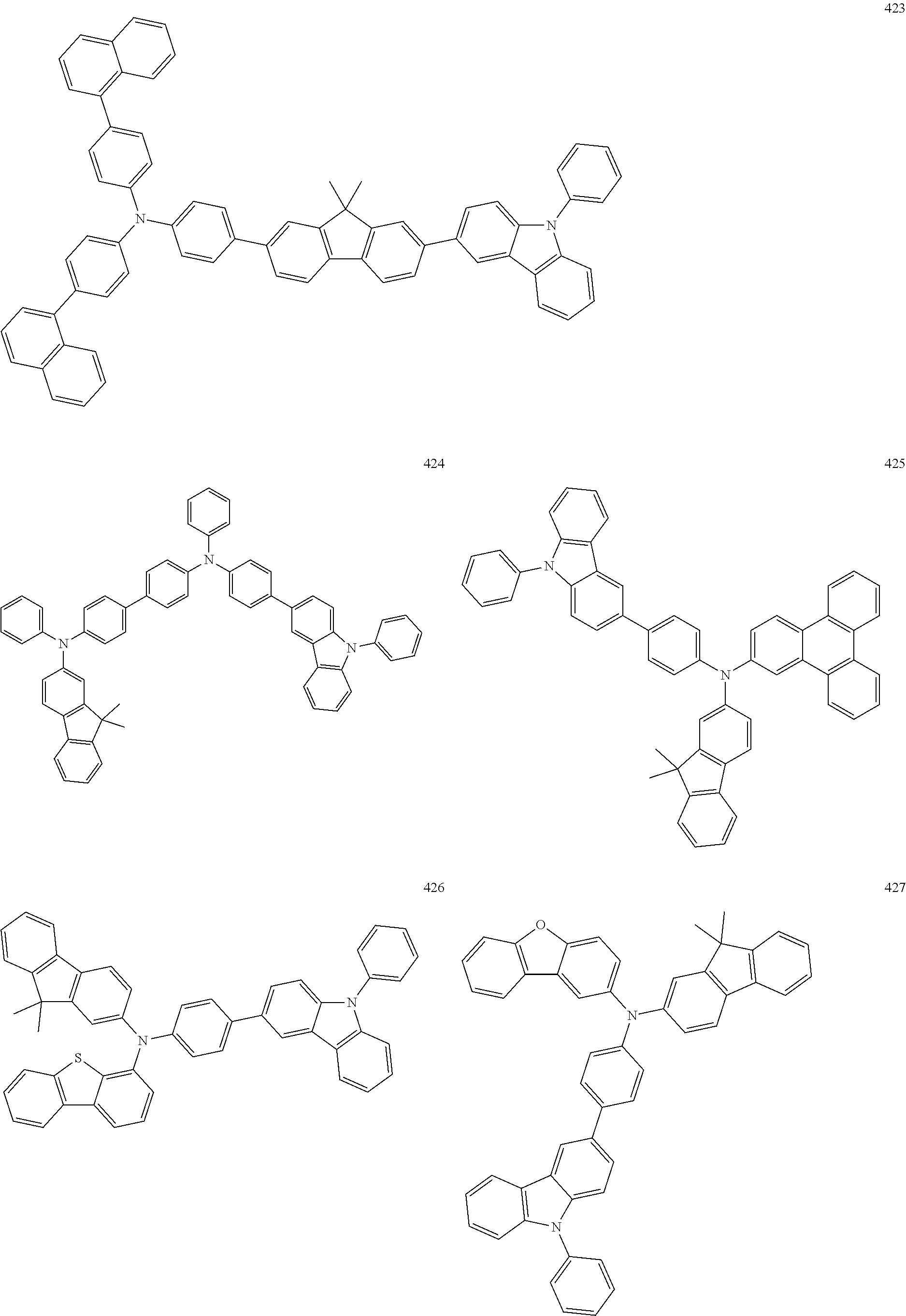

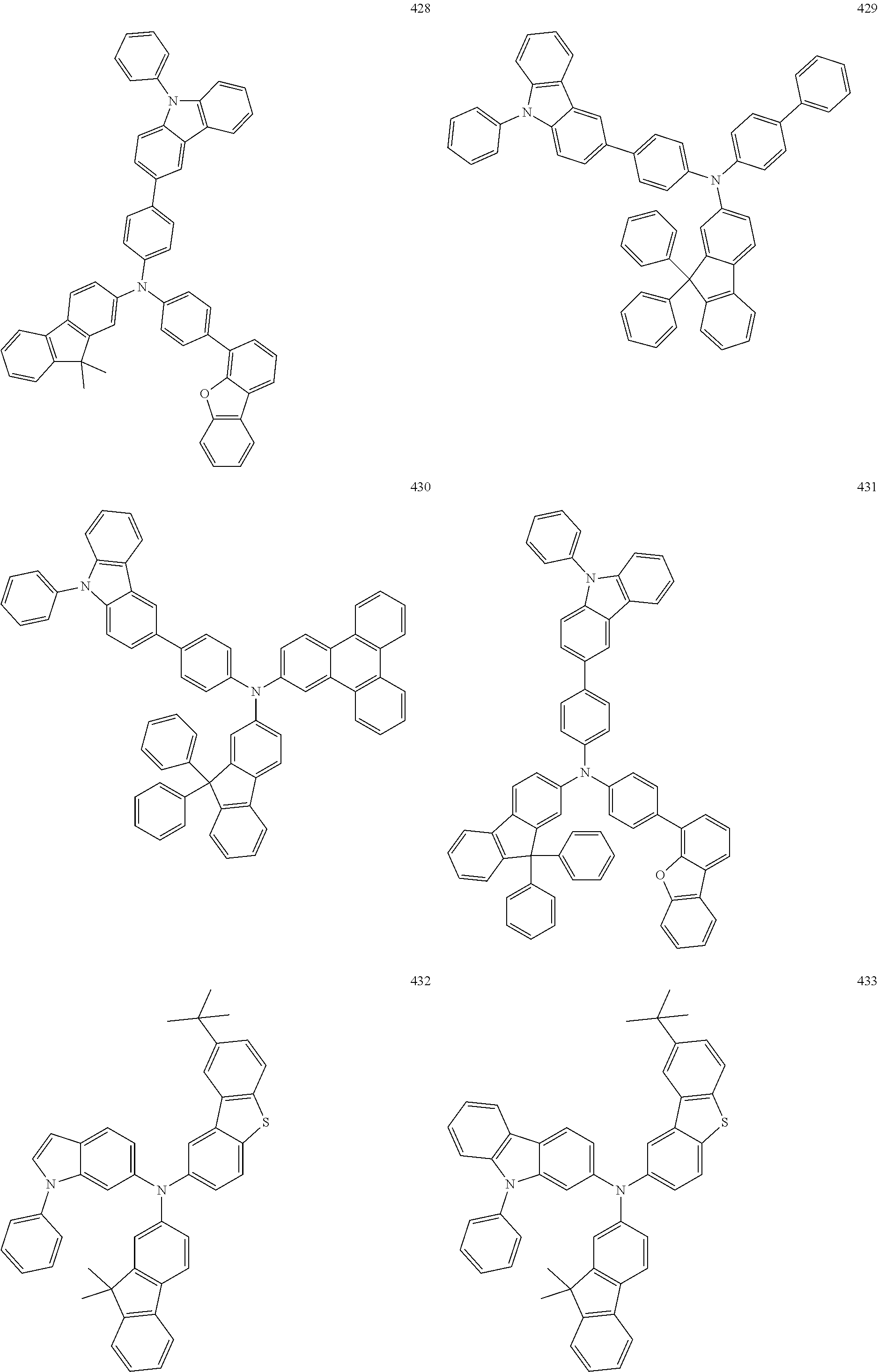

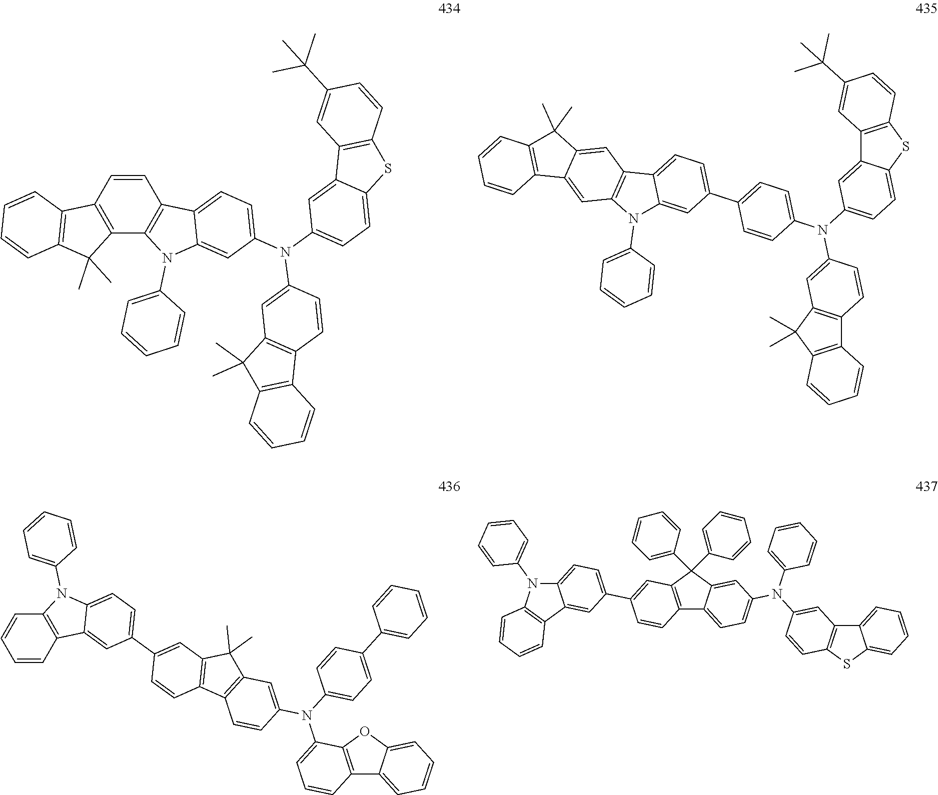 [SMILES: CC(C)(C)c1ccc2sc3ccc(N(c4ccc5c(c4)C(C)(C)c4ccccc4-5)c4ccc5c6ccc7c(c6n(-c6ccccc6)c5c4)C(C)(C)c4ccccc4-7)cc3c2c1 ; CC(C)(C)c1ccc2sc3ccc(N(c4ccc(-c5ccc6c7cc8c(cc7n(-c7ccccc7)c6c5)-c5ccccc5C8(C)C)cc4)c4ccc5c(c4)C(C)(C)c4ccccc4-5)cc3c2c1 ; CC1(C)c2cc(-c3ccc4c(c3)c3ccccc3n4-c3ccccc3)ccc2-c2ccc(N(c3ccc(-c4ccccc4)cc3)c3cccc4c3oc3ccccc34)cc21 ; c1ccc(N(c2ccc3c(c2)C(c2ccccc2)(c2ccccc2)c2cc(-c4ccc5c(c4)c4ccccc4n5-c4ccccc4)ccc2-3)c2ccc3sc4ccccc4c3c2)cc1]

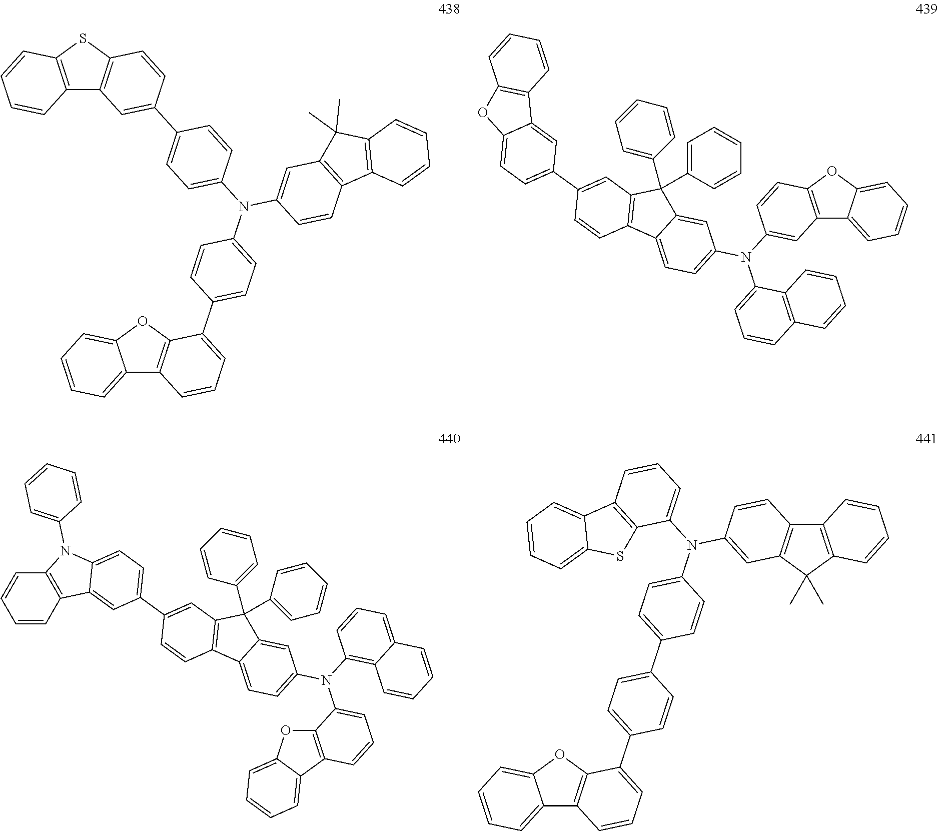 [SMILES: CC1(C)c2ccccc2-c2ccc(N(c3ccc(-c4ccc5sc6ccccc6c5c4)cc3)c3ccc(-c4cccc5c4oc4ccccc45)cc3)cc21 ; c1ccc(C2(c3ccccc3)c3cc(-c4ccc5oc6ccccc6c5c4)ccc3-c3ccc(N(c4ccc5oc6ccccc6c5c4)c4cccc5ccccc45)cc32)cc1 ; c1ccc(-n2c3ccccc3c3cc(-c4ccc5c(c4)C(c4ccccc4)(c4ccccc4)c4cc(N(c6cccc7ccccc67)c6cccc7c6oc6ccccc67)ccc4-5)ccc32)cc1 ; CC1(C)c2ccccc2-c2ccc(N(c3ccc(-c4ccc(-c5cccc6c5oc5ccccc56)cc4)cc3)c3cccc4c3sc3ccccc34)cc21]

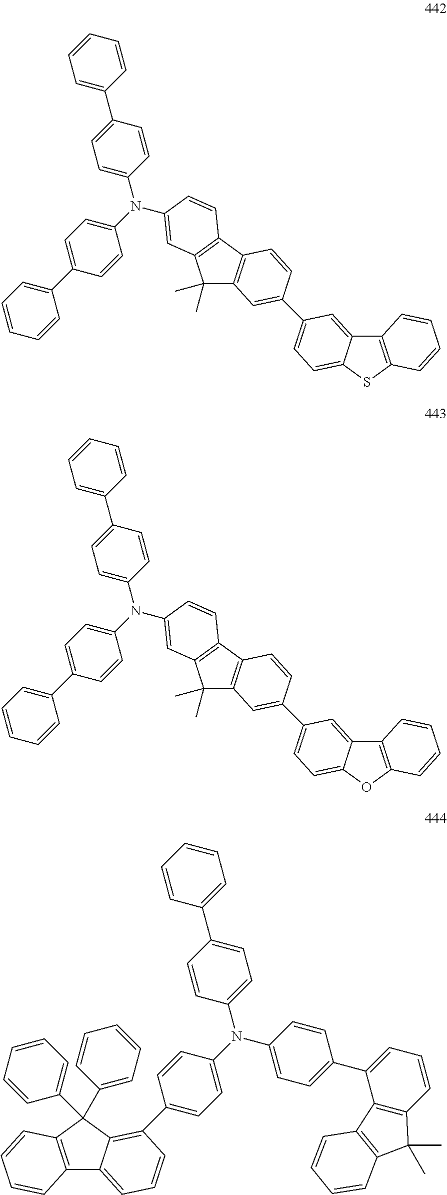 [SMILES: CC1(C)c2cc(-c3ccc4sc5ccccc5c4c3)ccc2-c2ccc(N(c3ccc(-c4ccccc4)cc3)c3ccc(-c4ccccc4)cc3)cc21 ; CC1(C)c2cc(-c3ccc4oc5ccccc5c4c3)ccc2-c2ccc(N(c3ccc(-c4ccccc4)cc3)c3ccc(-c4ccccc4)cc3)cc21 ; CC1(C)c2ccccc2-c2c(-c3ccc(N(c4ccc(-c5ccccc5)cc4)c4ccc(-c5cccc6c5C(c5ccccc5)(c5ccccc5)c5ccccc5-6)cc4)cc3)cccc21]

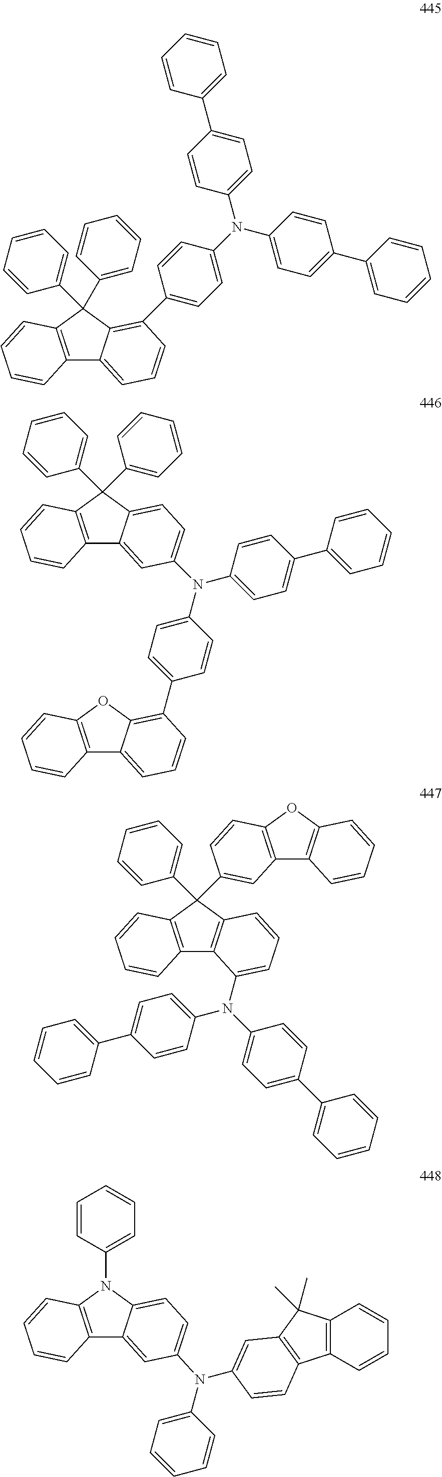

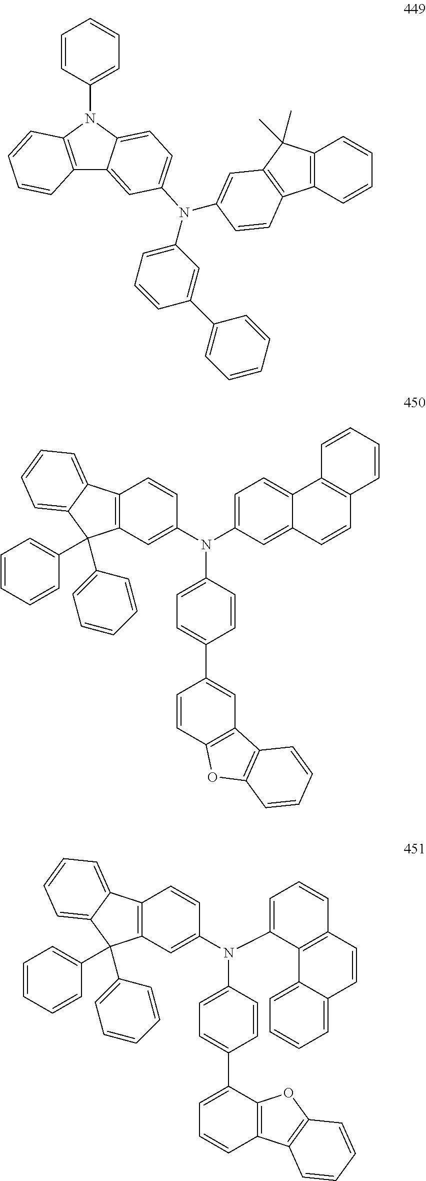 [SMILES: CC1(C)c2ccccc2-c2ccc(N(c3cccc(-c4ccccc4)c3)c3ccc4c(c3)c3ccccc3n4-c3ccccc3)cc21 ; c1ccc(C2(c3ccccc3)c3ccccc3-c3ccc(N(c4ccc(-c5ccc6oc7ccccc7c6c5)cc4)c4ccc5c(ccc6ccccc65)c4)cc32)cc1 ; c1ccc(C2(c3ccccc3)c3ccccc3-c3ccc(N(c4ccc(-c5cccc6c5oc5ccccc56)cc4)c4cccc5ccc6ccccc6c45)cc32)cc1]

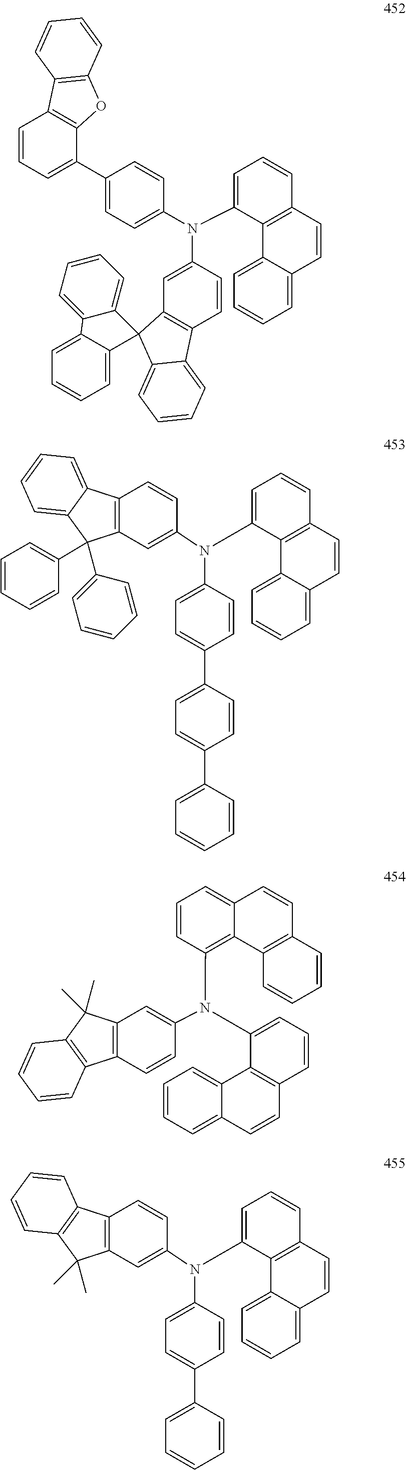

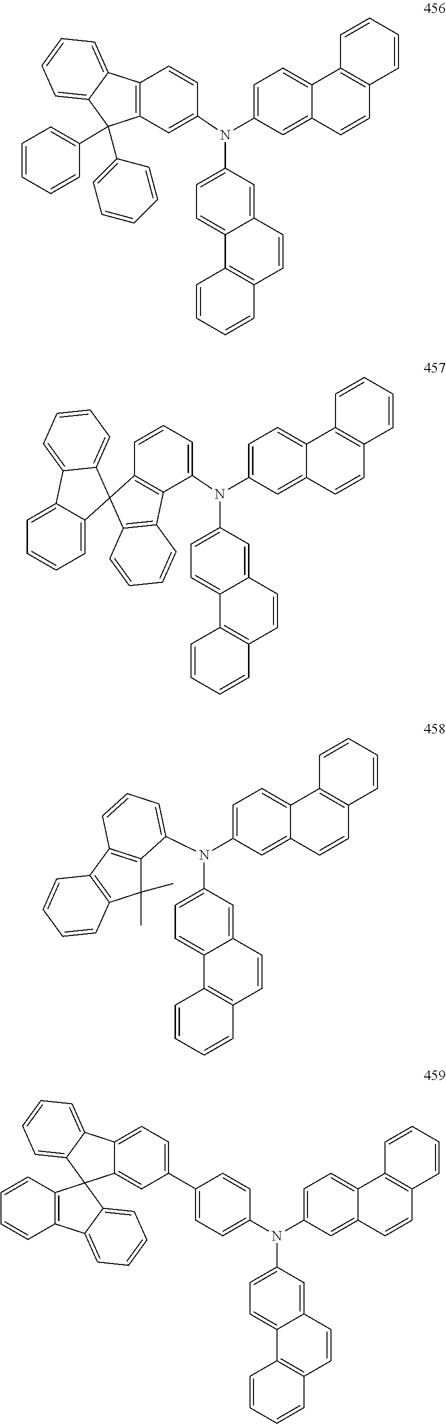 [SMILES: c1ccc(C2(c3ccccc3)c3ccccc3-c3ccc(N(c4ccc5c(ccc6ccccc65)c4)c4ccc5c(ccc6ccccc65)c4)cc32)cc1 ; c1ccc2c(c1)-c1ccccc1C21c2ccccc2-c2c(N(c3ccc4c(ccc5ccccc54)c3)c3ccc4c(ccc5ccccc54)c3)cccc21 ; CC1(C)c2ccccc2-c2cccc(N(c3ccc4c(ccc5ccccc54)c3)c3ccc4c(ccc5ccccc54)c3)c21 ; c1ccc2c(c1)-c1ccccc1C21c2ccccc2-c2ccc(-c3ccc(N(c4ccc5c(ccc6ccccc65)c4)c4ccc5c(ccc6ccccc65)c4)cc3)cc21]

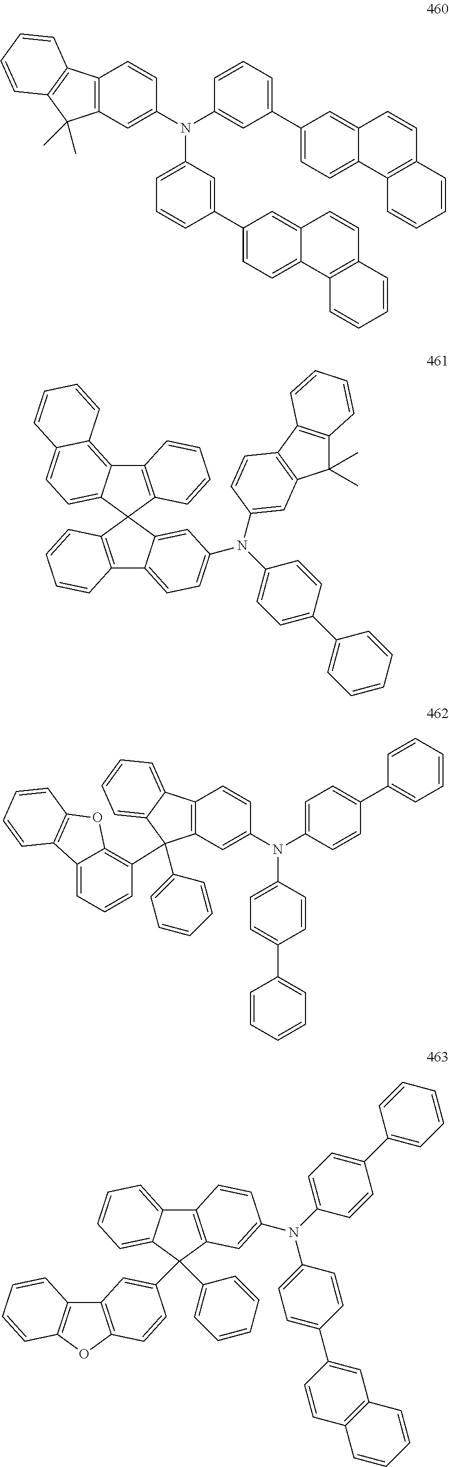 [SMILES: CC1(C)c2ccccc2-c2ccc(N(c3cccc(-c4ccc5c(ccc6ccccc65)c4)c3)c3cccc(-c4ccc5c(ccc6ccccc65)c4)c3)cc21 ; CC1(C)c2ccccc2-c2ccc(N(c3ccc(-c4ccccc4)cc3)c3ccc4c(c3)C3(c5ccccc5-4)c4ccccc4-c4c3ccc3ccccc43)cc21 ; c1ccc(-c2ccc(N(c3ccc(-c4ccccc4)cc3)c3ccc4c(c3)C(c3ccccc3)(c3cccc5c3oc3ccccc35)c3ccccc3-4)cc2)cc1 ; c1ccc(-c2ccc(N(c3ccc(-c4ccc5ccccc5c4)cc3)c3ccc4c(c3)C(c3ccccc3)(c3ccc5oc6ccccc6c5c3)c3ccccc3-4)cc2)cc1]

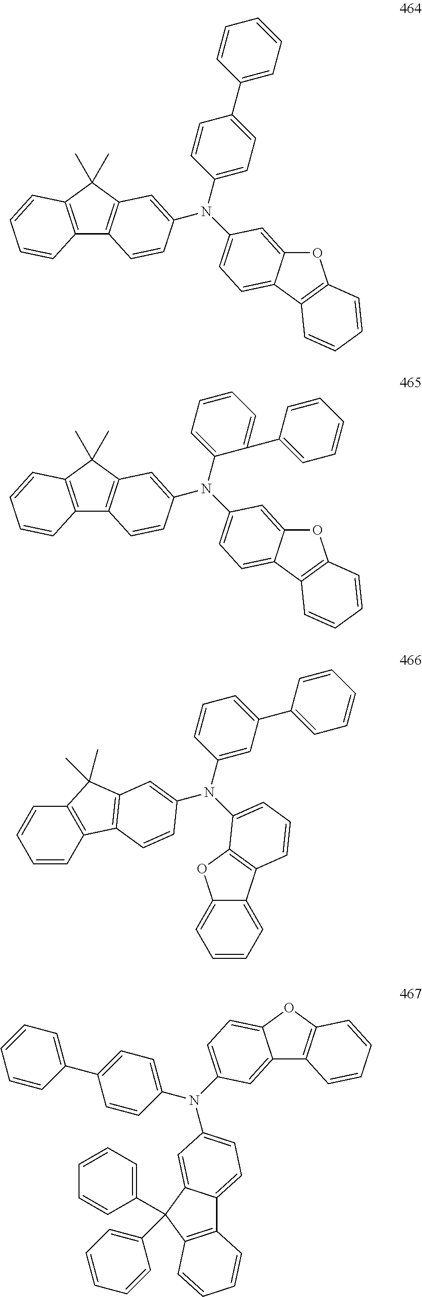

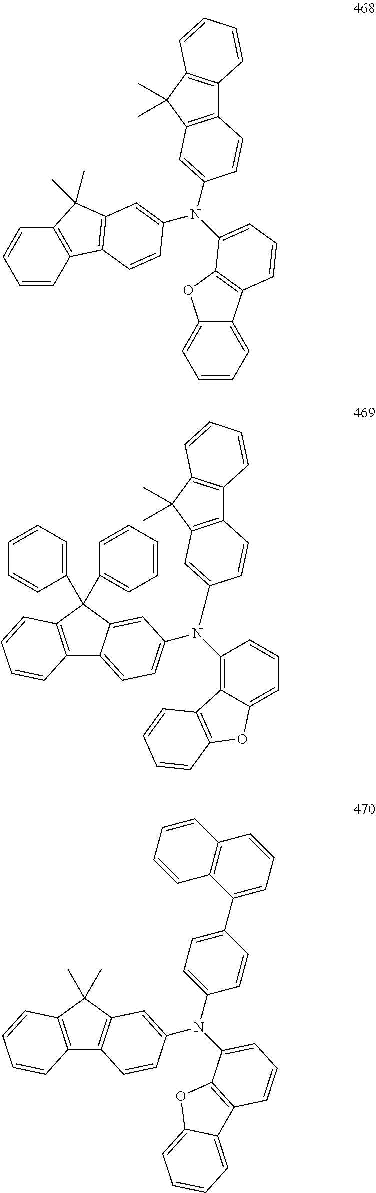

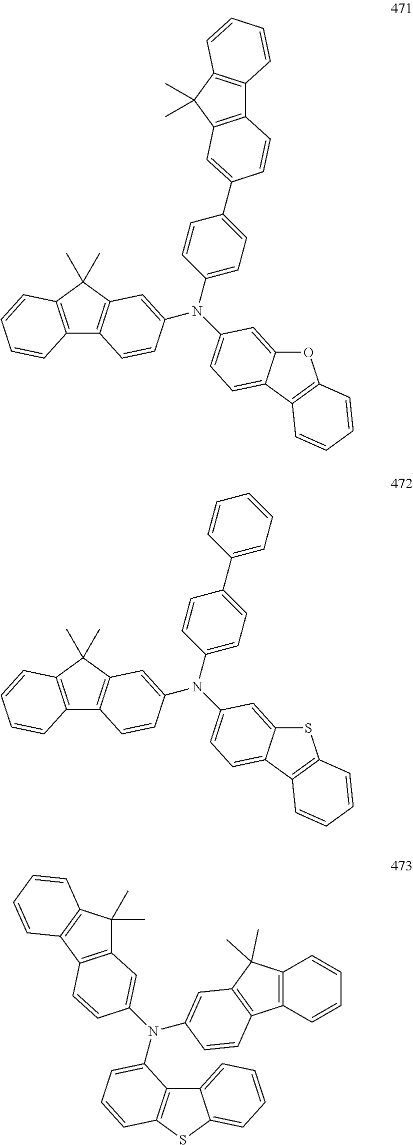 [SMILES: CC1(C)c2ccccc2-c2ccc(-c3ccc(N(c4ccc5c(c4)C(C)(C)c4ccccc4-5)c4ccc5c(c4)oc4ccccc45)cc3)cc21 ; CC1(C)c2ccccc2-c2ccc(N(c3ccc(-c4ccccc4)cc3)c3ccc4c(c3)sc3ccccc34)cc21 ; CC1(C)c2ccccc2-c2ccc(N(c3ccc4c(c3)C(C)(C)c3ccccc3-4)c3cccc4sc5ccccc5c34)cc21]

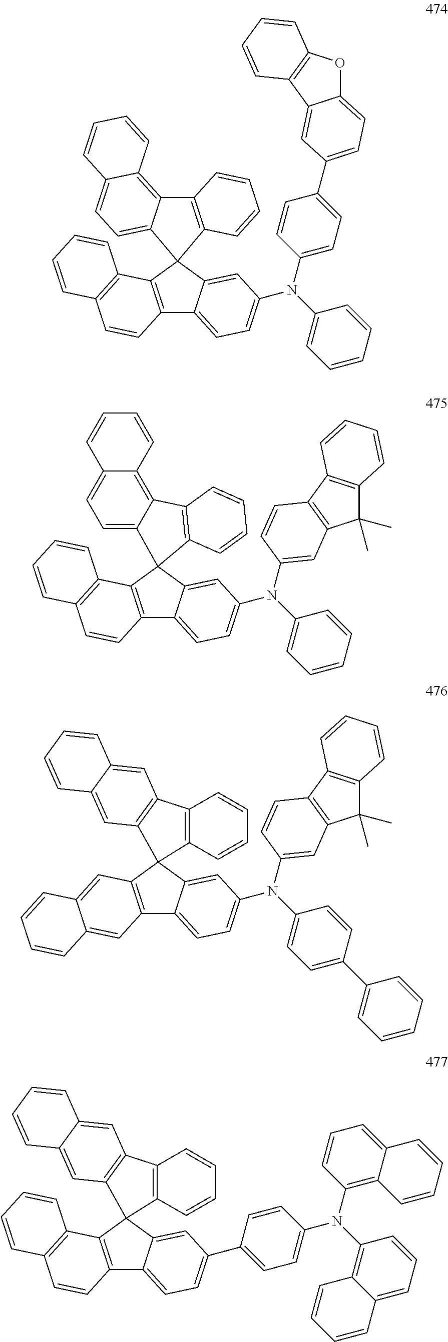 [SMILES: c1ccc(N(c2ccc(-c3ccc4oc5ccccc5c4c3)cc2)c2ccc3c(c2)C2(c4ccccc4-c4c2ccc2ccccc42)c2c-3ccc3ccccc23)cc1 ; CC1(C)c2ccccc2-c2ccc(N(c3ccccc3)c3ccc4c(c3)C3(c5ccccc5-c5c3ccc3ccccc53)c3c-4ccc4ccccc34)cc21 ; CC1(C)c2ccccc2-c2ccc(N(c3ccc(-c4ccccc4)cc3)c3ccc4c(c3)C3(c5ccccc5-c5cc6ccccc6cc53)c3cc5ccccc5cc3-4)cc21 ; c1ccc2c(c1)-c1cc3ccccc3cc1C21c2cc(-c3ccc(N(c4cccc5ccccc45)c4cccc5ccccc45)cc3)ccc2-c2ccc3ccccc3c21]

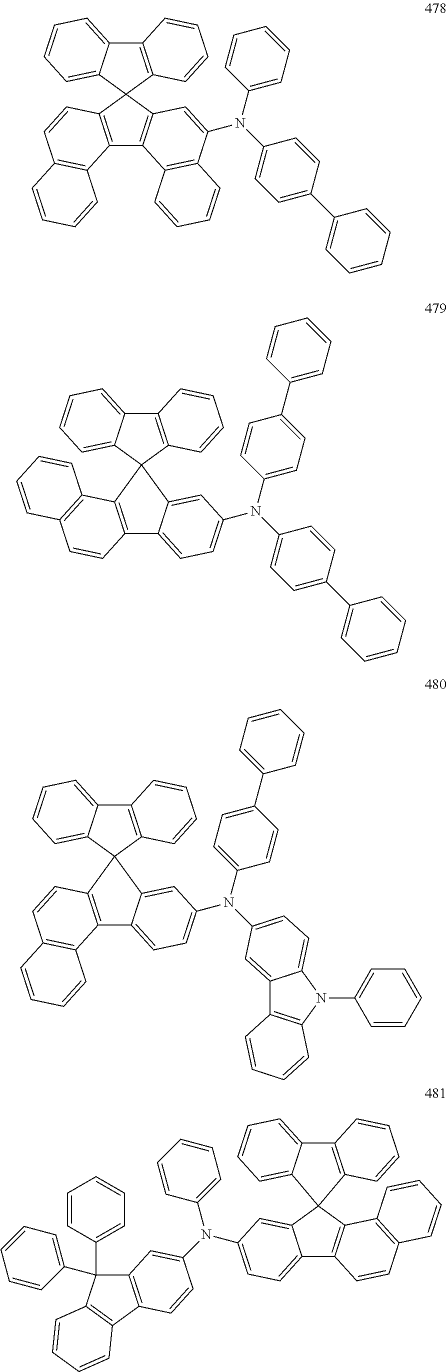

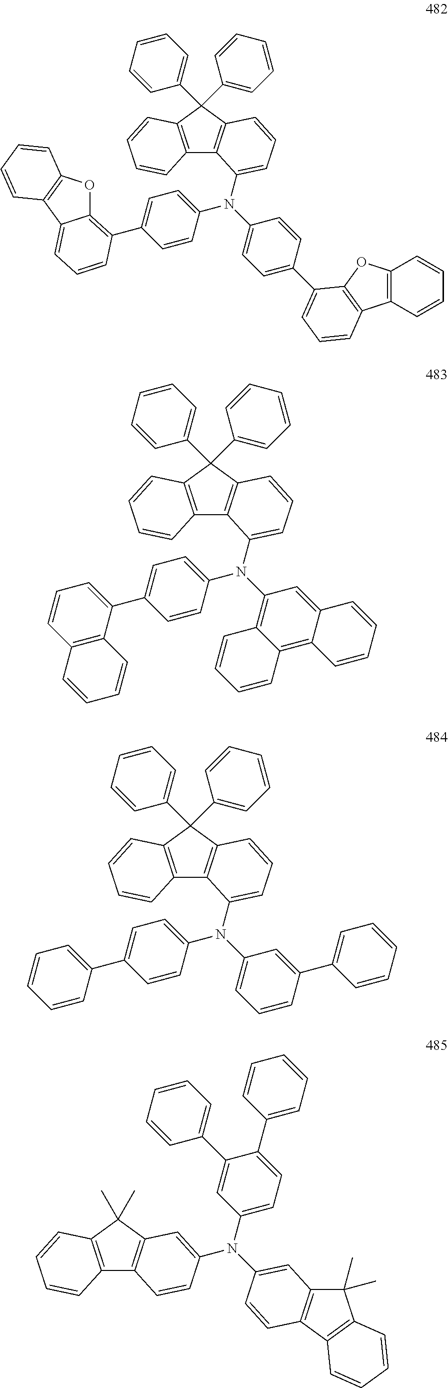 [SMILES: c1ccc(C2(c3ccccc3)c3ccccc3-c3c(N(c4ccc(-c5cccc6c5oc5ccccc56)cc4)c4ccc(-c5cccc6c5oc5ccccc56)cc4)cccc32)cc1 ; c1ccc(C2(c3ccccc3)c3ccccc3-c3c(N(c4ccc(-c5cccc6ccccc56)cc4)c4cc5ccccc5c5ccccc45)cccc32)cc1 ; c1ccc(-c2ccc(N(c3cccc(-c4ccccc4)c3)c3cccc4c3-c3ccccc3C4(c3ccccc3)c3ccccc3)cc2)cc1 ; CC1(C)c2ccccc2-c2ccc(N(c3ccc(-c4ccccc4)c(-c4ccccc4)c3)c3ccc4c(c3)C(C)(C)c3ccccc3-4)cc21]

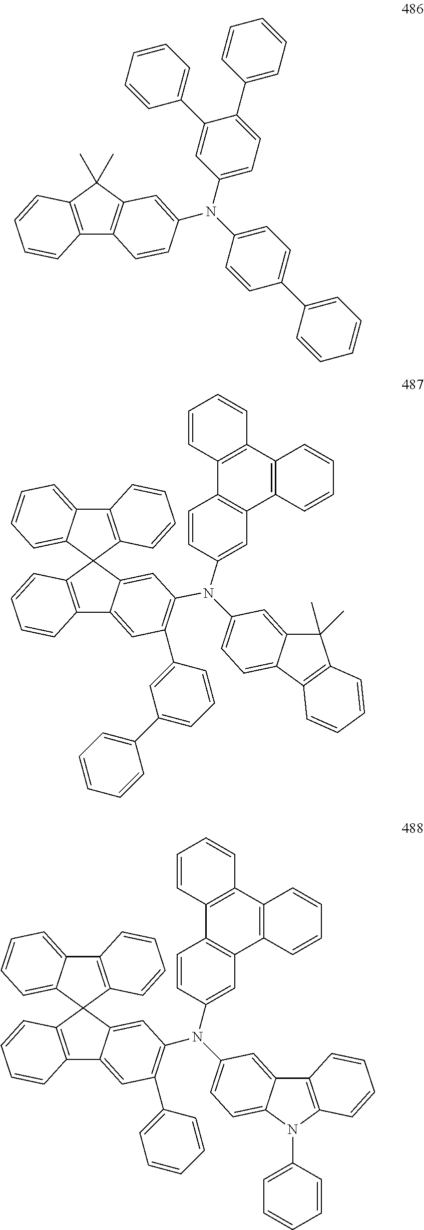 [SMILES: CC1(C)c2ccccc2-c2ccc(N(c3ccc(-c4ccccc4)cc3)c3ccc(-c4ccccc4)c(-c4ccccc4)c3)cc21 ; CC1(C)c2ccccc2-c2ccc(N(c3ccc4c5ccccc5c5ccccc5c4c3)c3cc4c(cc3-c3cccc(-c5ccccc5)c3)-c3ccccc3C43c4ccccc4-c4ccccc43)cc21 ; c1ccc(-c2cc3c(cc2N(c2ccc4c5ccccc5c5ccccc5c4c2)c2ccc4c(c2)c2ccccc2n4-c2ccccc2)C2(c4ccccc4-c4ccccc42)c2ccccc2-3)cc1]

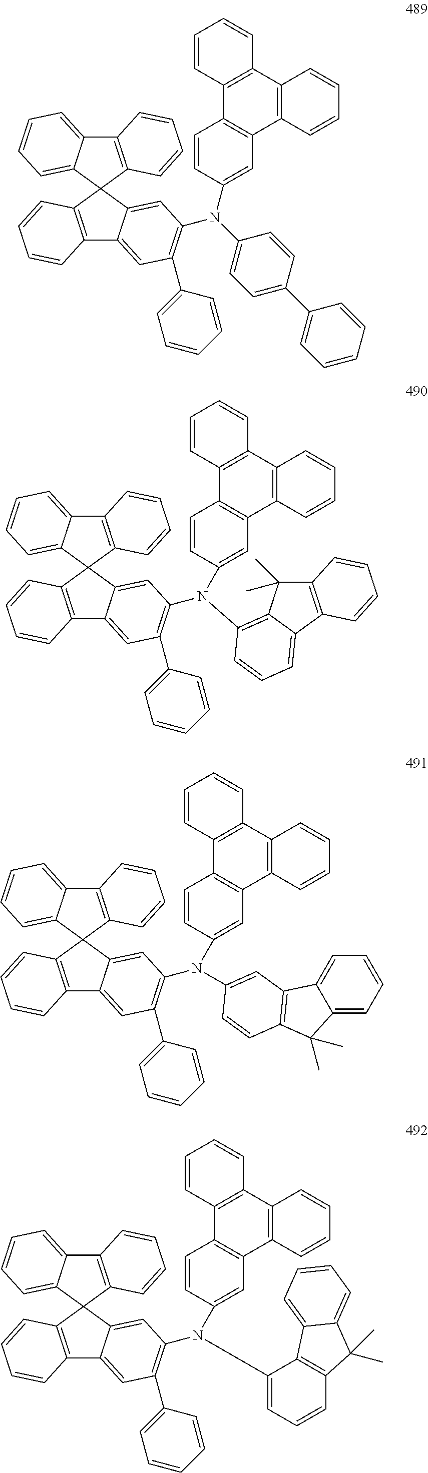 [SMILES: c1ccc(-c2ccc(N(c3ccc4c5ccccc5c5ccccc5c4c3)c3cc4c(cc3-c3ccccc3)-c3ccccc3C43c4ccccc4-c4ccccc43)cc2)cc1 ; CC1(C)c2ccccc2-c2cccc(N(c3ccc4c5ccccc5c5ccccc5c4c3)c3cc4c(cc3-c3ccccc3)-c3ccccc3C43c4ccccc4-c4ccccc43)c21 ; CC1(C)c2ccccc2-c2cc(N(c3ccc4c5ccccc5c5ccccc5c4c3)c3cc4c(cc3-c3ccccc3)-c3ccccc3C43c4ccccc4-c4ccccc43)ccc21 ; CC1(C)c2ccccc2-c2c(N(c3ccc4c5ccccc5c5ccccc5c4c3)c3cc4c(cc3-c3ccccc3)-c3ccccc3C43c4ccccc4-c4ccccc43)cccc21]

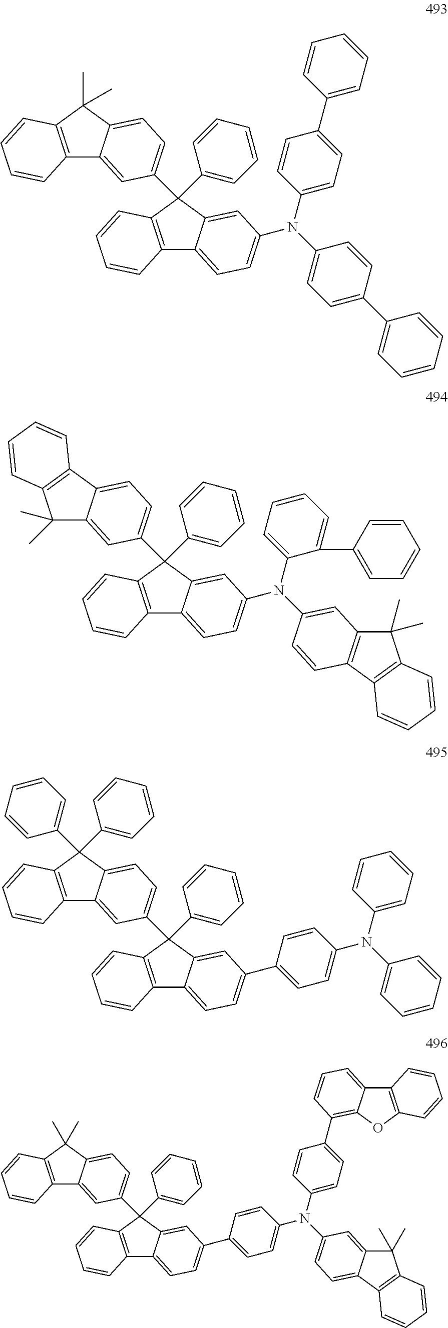 [SMILES: CC1(C)c2ccccc2-c2cc(C3(c4ccccc4)c4ccccc4-c4ccc(N(c5ccc(-c6ccccc6)cc5)c5ccc(-c6ccccc6)cc5)cc43)ccc21 ; CC1(C)c2ccccc2-c2ccc(N(c3ccc4c(c3)C(c3ccccc3)(c3ccc5c(c3)C(C)(C)c3ccccc3-5)c3ccccc3-4)c3ccccc3-c3ccccc3)cc21 ; c1ccc(N(c2ccccc2)c2ccc(-c3ccc4c(c3)C(c3ccccc3)(c3ccc5c(c3)-c3ccccc3C5(c3ccccc3)c3ccccc3)c3ccccc3-4)cc2)cc1 ; CC1(C)c2ccccc2-c2cc(C3(c4ccccc4)c4ccccc4-c4ccc(-c5ccc(N(c6ccc(-c7cccc8c7oc7ccccc78)cc6)c6ccc7c(c6)C(C)(C)c6ccccc6-7)cc5)cc43)ccc21]

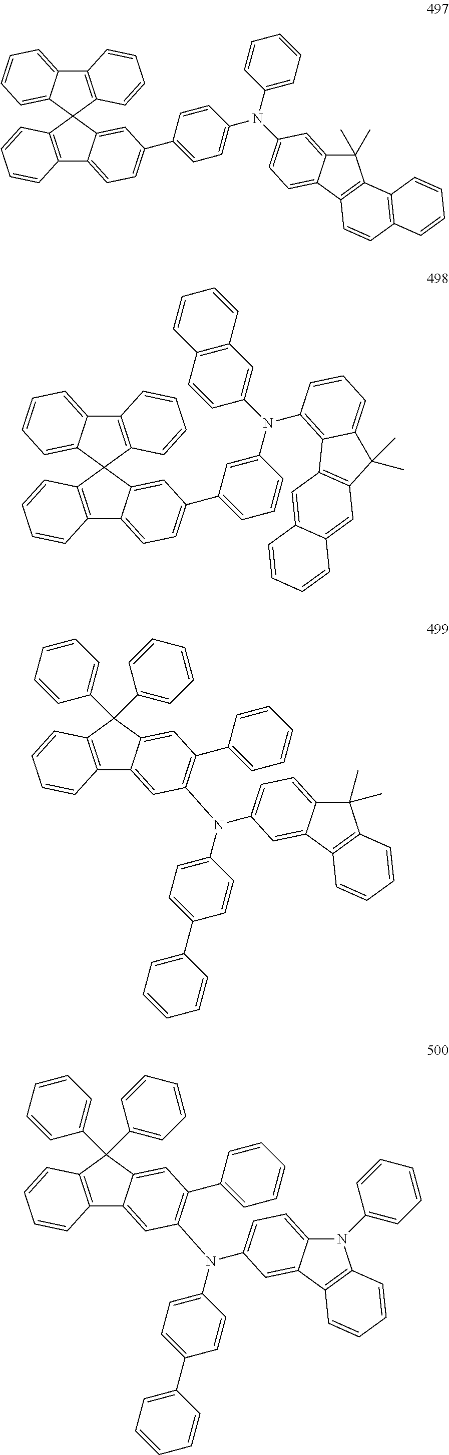 [SMILES: CC1(C)c2cc(N(c3ccccc3)c3ccc(-c4ccc5c(c4)C4(c6ccccc6-c6ccccc64)c4ccccc4-5)cc3)ccc2-c2ccc3ccccc3c21 ; CC1(C)c2cc3ccccc3cc2-c2c(N(c3cccc(-c4ccc5c(c4)C4(c6ccccc6-c6ccccc64)c4ccccc4-5)c3)c3ccc4ccccc4c3)cccc21 ; CC1(C)c2ccccc2-c2cc(N(c3ccc(-c4ccccc4)cc3)c3cc4c(cc3-c3ccccc3)C(c3ccccc3)(c3ccccc3)c3ccccc3-4)ccc21 ; c1ccc(-c2ccc(N(c3ccc4c(c3)c3ccccc3n4-c3ccccc3)c3cc4c(cc3-c3ccccc3)C(c3ccccc3)(c3ccccc3)c3ccccc3-4)cc2)cc1]

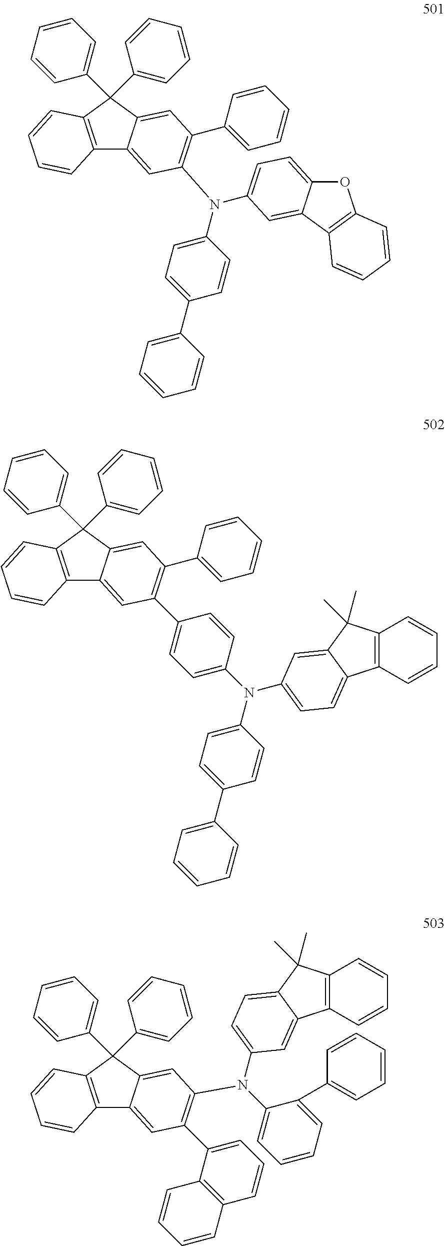 [SMILES: c1ccc(-c2ccc(N(c3ccc4oc5ccccc5c4c3)c3cc4c(cc3-c3ccccc3)C(c3ccccc3)(c3ccccc3)c3ccccc3-4)cc2)cc1 ; CC1(C)c2ccccc2-c2ccc(N(c3ccc(-c4ccccc4)cc3)c3ccc(-c4cc5c(cc4-c4ccccc4)C(c4ccccc4)(c4ccccc4)c4ccccc4-5)cc3)cc21 ; CC1(C)c2ccccc2-c2cc(N(c3ccccc3-c3ccccc3)c3cc4c(cc3-c3cccc5ccccc35)-c3ccccc3C4(c3ccccc3)c3ccccc3)ccc21]

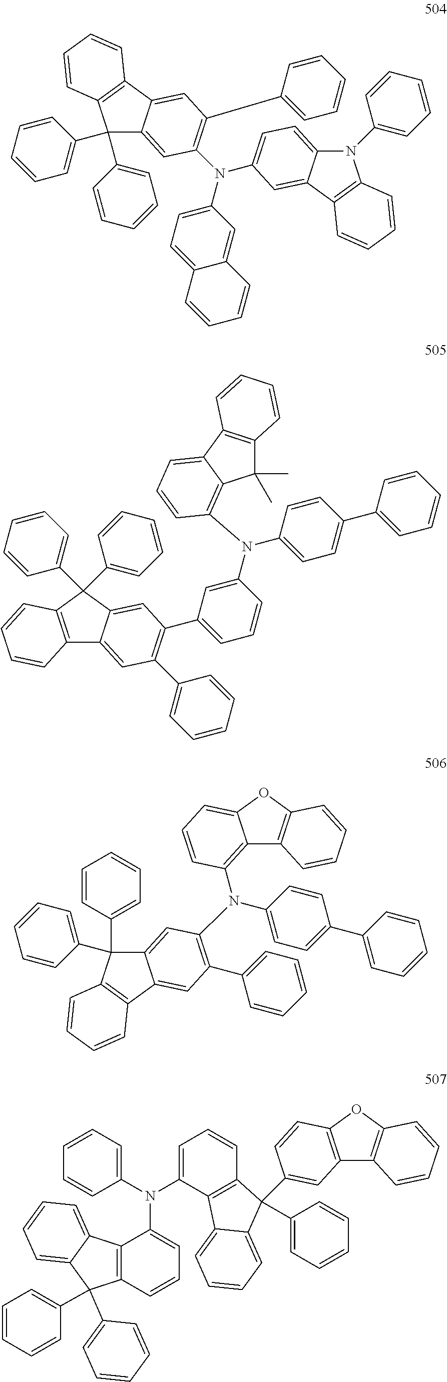 [SMILES: c1ccc(-c2cc3c(cc2N(c2ccc4ccccc4c2)c2ccc4c(c2)c2ccccc2n4-c2ccccc2)C(c2ccccc2)(c2ccccc2)c2ccccc2-3)cc1 ; CC1(C)c2ccccc2-c2cccc(N(c3ccc(-c4ccccc4)cc3)c3cccc(-c4cc5c(cc4-c4ccccc4)-c4ccccc4C5(c4ccccc4)c4ccccc4)c3)c21 ; c1ccc(-c2ccc(N(c3cc4c(cc3-c3ccccc3)-c3ccccc3C4(c3ccccc3)c3ccccc3)c3cccc4oc5ccccc5c34)cc2)cc1 ; c1ccc(N(c2cccc3c2-c2ccccc2C3(c2ccccc2)c2ccccc2)c2cccc3c2-c2ccccc2C3(c2ccccc2)c2ccc3oc4ccccc4c3c2)cc1]

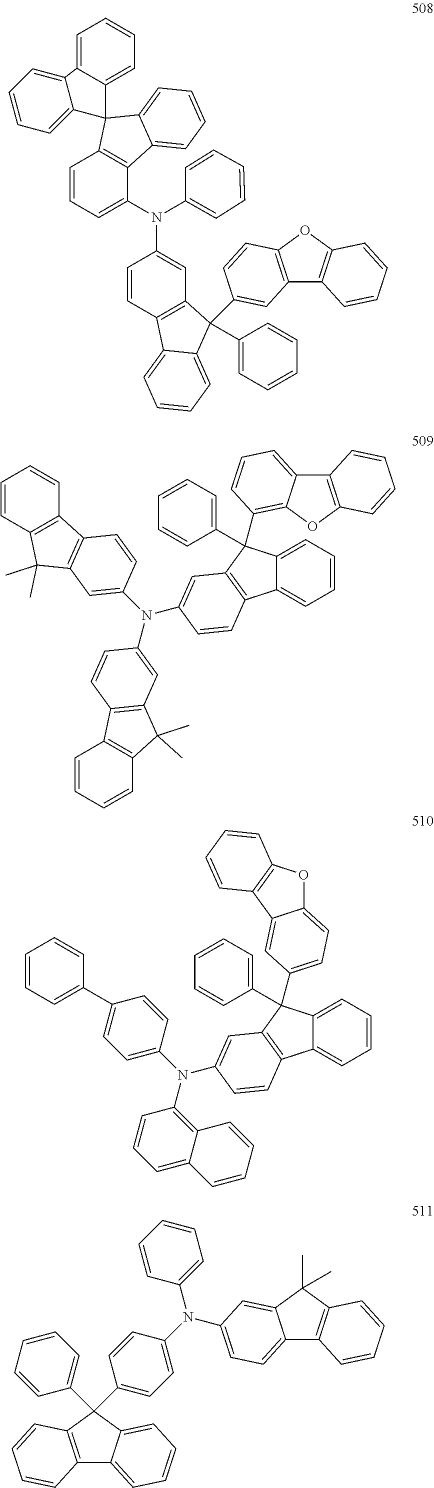

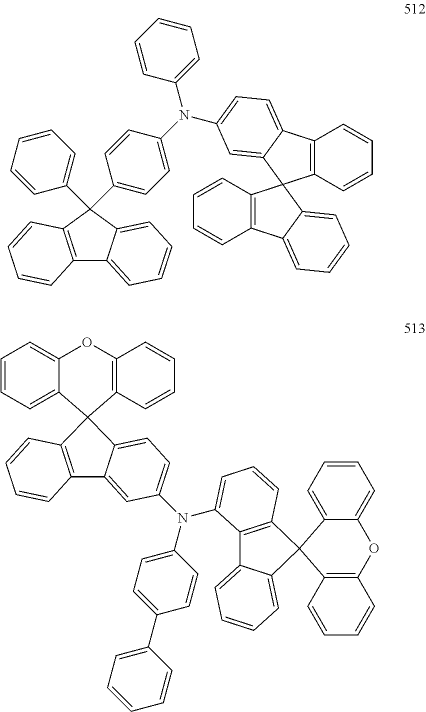 [SMILES: c1ccc(N(c2ccc(C3(c4ccccc4)c4ccccc4-c4ccccc43)cc2)c2ccc3c(c2)C2(c4ccccc4-c4ccccc42)c2ccccc2-3)cc1 ; c1ccc(-c2ccc(N(c3ccc4c(c3)-c3ccccc3C43c4ccccc4Oc4ccccc43)c3cccc4c3-c3ccccc3C43c4ccccc4Oc4ccccc43)cc2)cc1]

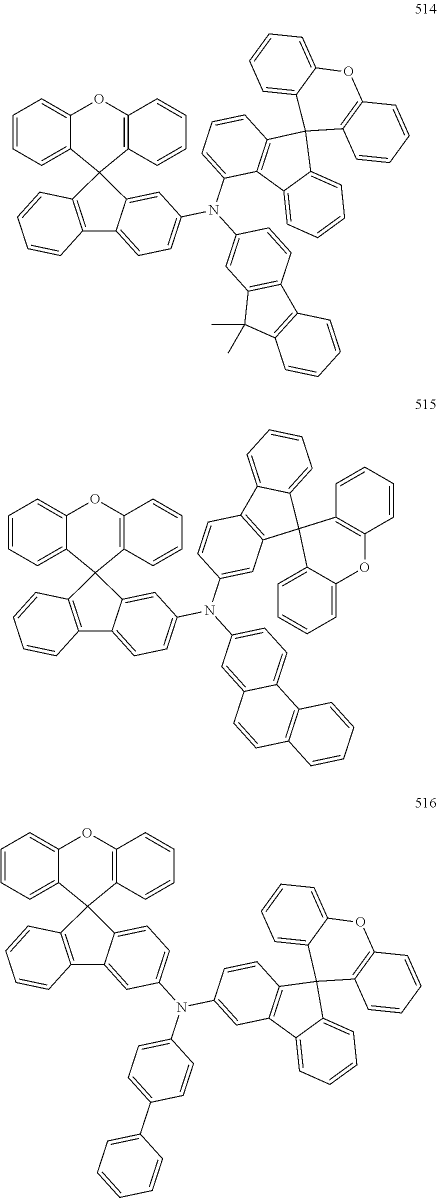 [SMILES: CC1(C)c2ccccc2-c2ccc(N(c3ccc4c(c3)C3(c5ccccc5Oc5ccccc53)c3ccccc3-4)c3cccc4c3-c3ccccc3C43c4ccccc4Oc4ccccc43)cc21 ; c1ccc2c(c1)Oc1ccccc1C21c2ccccc2-c2ccc(N(c3ccc4c(c3)C3(c5ccccc5Oc5ccccc53)c3ccccc3-4)c3ccc4c(ccc5ccccc54)c3)cc21 ; c1ccc(-c2ccc(N(c3ccc4c(c3)-c3ccccc3C43c4ccccc4Oc4ccccc43)c3ccc4c(c3)-c3ccccc3C43c4ccccc4Oc4ccccc43)cc2)cc1]

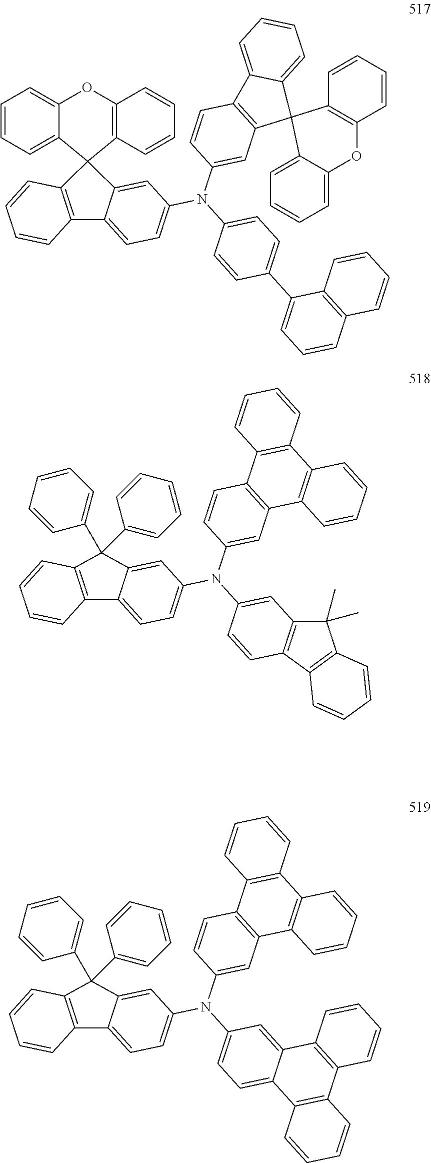

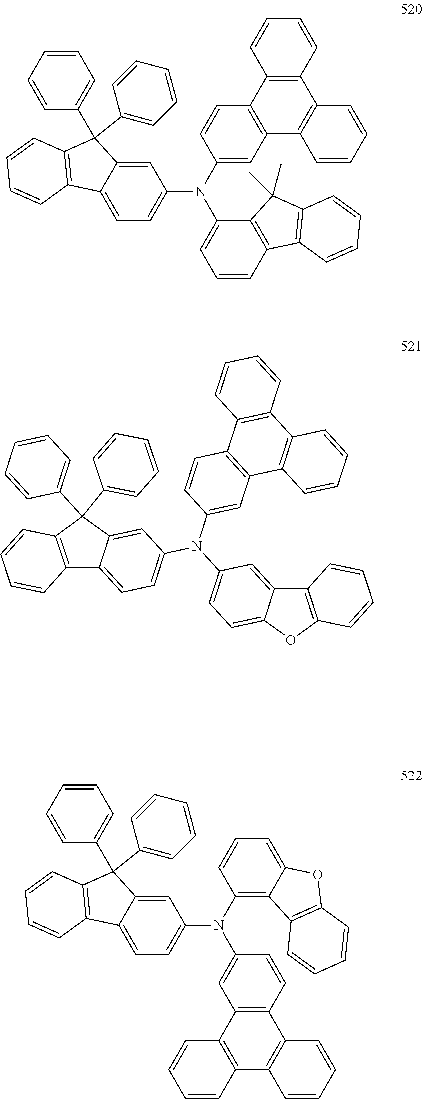 [SMILES: CC1(C)c2ccccc2-c2cccc(N(c3ccc4c(c3)C(c3ccccc3)(c3ccccc3)c3ccccc3-4)c3ccc4c5ccccc5c5ccccc5c4c3)c21 ; c1ccc(C2(c3ccccc3)c3ccccc3-c3ccc(N(c4ccc5oc6ccccc6c5c4)c4ccc5c6ccccc6c6ccccc6c5c4)cc32)cc1 ; c1ccc(C2(c3ccccc3)c3ccccc3-c3ccc(N(c4ccc5c6ccccc6c6ccccc6c5c4)c4cccc5oc6ccccc6c45)cc32)cc1]

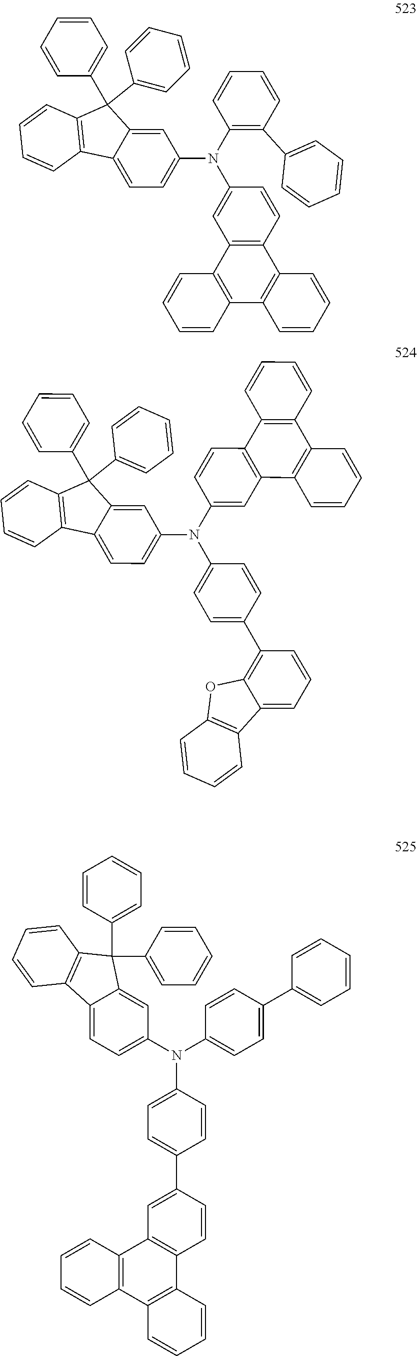

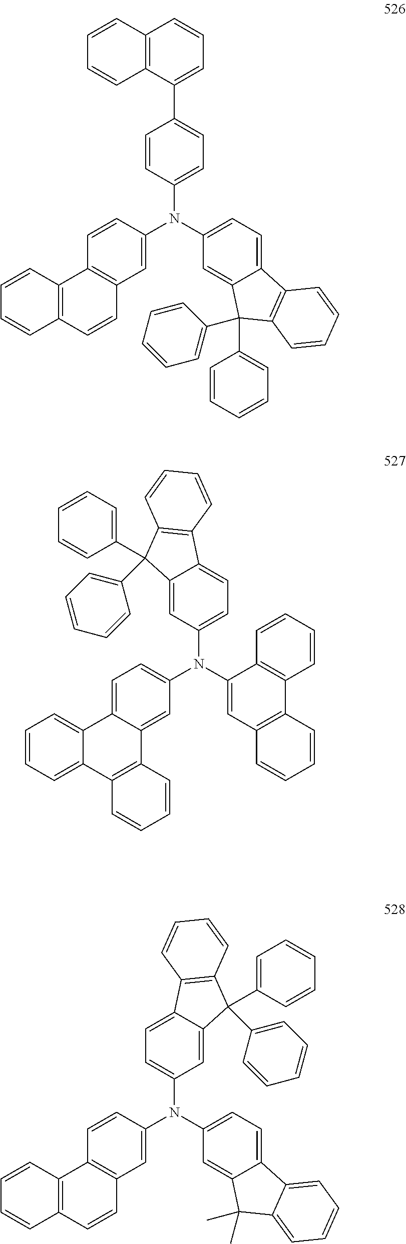 [SMILES: c1ccc(C2(c3ccccc3)c3ccccc3-c3ccc(N(c4ccc(-c5cccc6ccccc56)cc4)c4ccc5c(ccc6ccccc65)c4)cc32)cc1 ; c1ccc(C2(c3ccccc3)c3ccccc3-c3ccc(N(c4ccc5c6ccccc6c6ccccc6c5c4)c4cc5ccccc5c5ccccc45)cc32)cc1 ; CC1(C)c2ccccc2-c2ccc(N(c3ccc4c(c3)C(c3ccccc3)(c3ccccc3)c3ccccc3-4)c3ccc4c(ccc5ccccc54)c3)cc21]

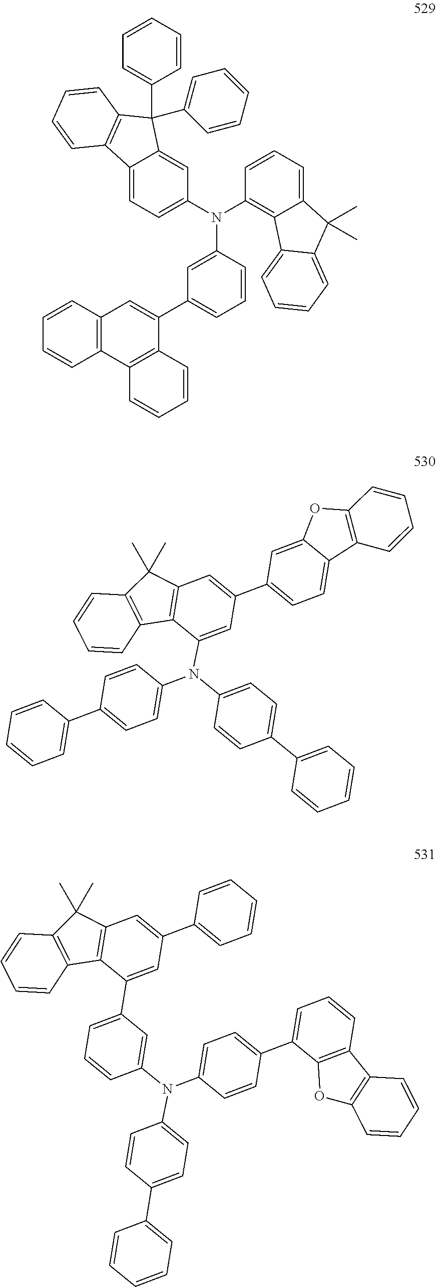 [SMILES: CC1(C)c2ccccc2-c2c(N(c3cccc(-c4cc5ccccc5c5ccccc45)c3)c3ccc4c(c3)C(c3ccccc3)(c3ccccc3)c3ccccc3-4)cccc21 ; CC1(C)c2ccccc2-c2c(N(c3ccc(-c4ccccc4)cc3)c3ccc(-c4ccccc4)cc3)cc(-c3ccc4c(c3)oc3ccccc34)cc21 ; CC1(C)c2ccccc2-c2c(-c3cccc(N(c4ccc(-c5ccccc5)cc4)c4ccc(-c5cccc6c5oc5ccccc56)cc4)c3)cc(-c3ccccc3)cc21]

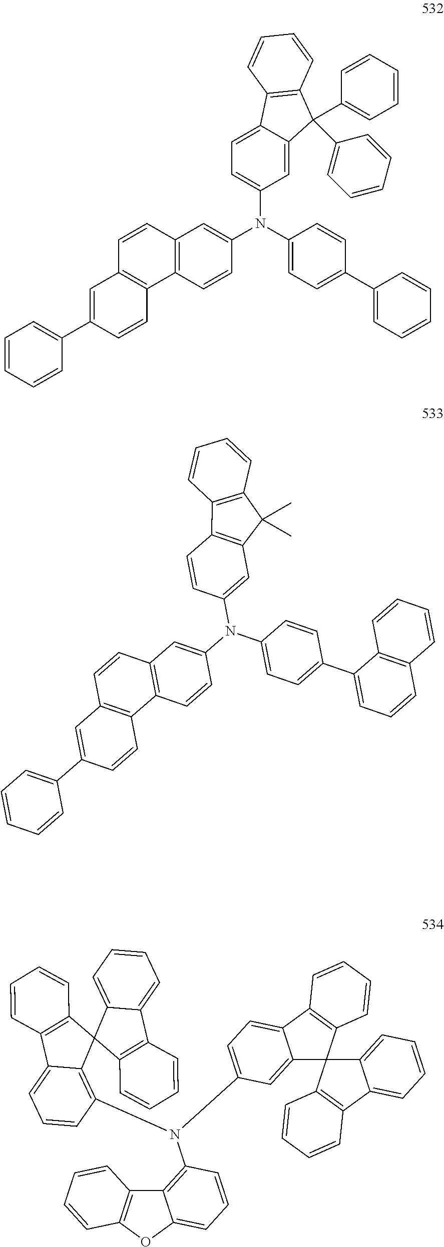 [SMILES: c1ccc(-c2ccc(N(c3ccc4c(c3)C(c3ccccc3)(c3ccccc3)c3ccccc3-4)c3ccc4c(ccc5cc(-c6ccccc6)ccc54)c3)cc2)cc1 ; CC1(C)c2ccccc2-c2ccc(N(c3ccc(-c4cccc5ccccc45)cc3)c3ccc4c(ccc5cc(-c6ccccc6)ccc54)c3)cc21 ; c1ccc2c(c1)-c1ccccc1C21c2ccccc2-c2ccc(N(c3cccc4c3C3(c5ccccc5-c5ccccc53)c3ccccc3-4)c3cccc4oc5ccccc5c34)cc21]

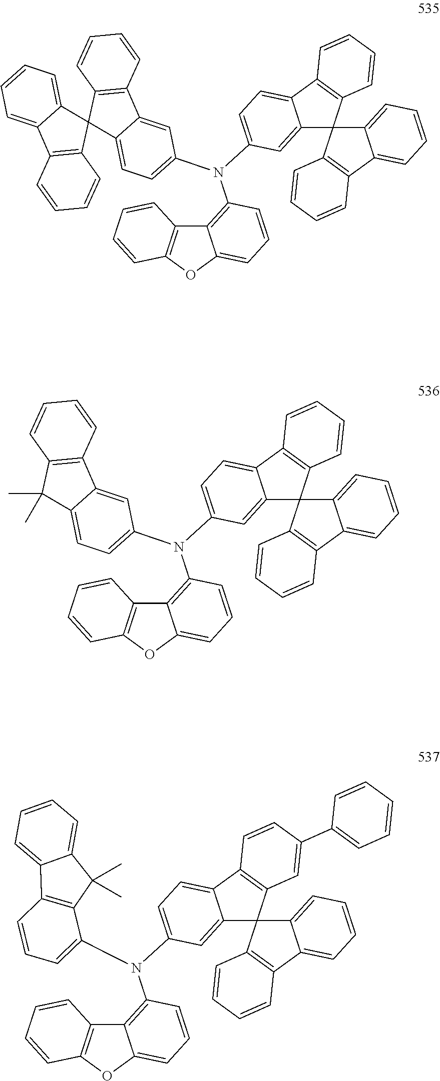 [SMILES: c1ccc2c(c1)-c1ccccc1C21c2ccccc2-c2cc(N(c3ccc4c(c3)C3(c5ccccc5-c5ccccc53)c3ccccc3-4)c3cccc4oc5ccccc5c34)ccc21 ; CC1(C)c2ccccc2-c2cc(N(c3ccc4c(c3)C3(c5ccccc5-c5ccccc53)c3ccccc3-4)c3cccc4oc5ccccc5c34)ccc21 ; CC1(C)c2ccccc2-c2cccc(N(c3ccc4c(c3)C3(c5ccccc5-c5ccccc53)c3cc(-c5ccccc5)ccc3-4)c3cccc4oc5ccccc5c34)c21]

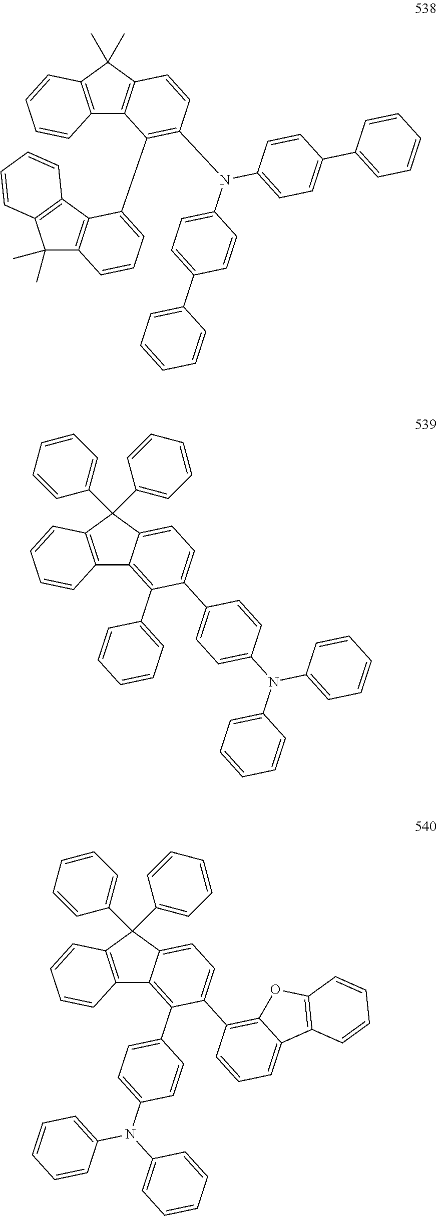 [SMILES: CC1(C)c2ccccc2-c2c(-c3c(N(c4ccc(-c5ccccc5)cc4)c4ccc(-c5ccccc5)cc4)ccc4c3-c3ccccc3C4(C)C)cccc21 ; c1ccc(-c2c(-c3ccc(N(c4ccccc4)c4ccccc4)cc3)ccc3c2-c2ccccc2C3(c2ccccc2)c2ccccc2)cc1 ; c1ccc(N(c2ccccc2)c2ccc(-c3c(-c4cccc5c4oc4ccccc45)ccc4c3-c3ccccc3C4(c3ccccc3)c3ccccc3)cc2)cc1]

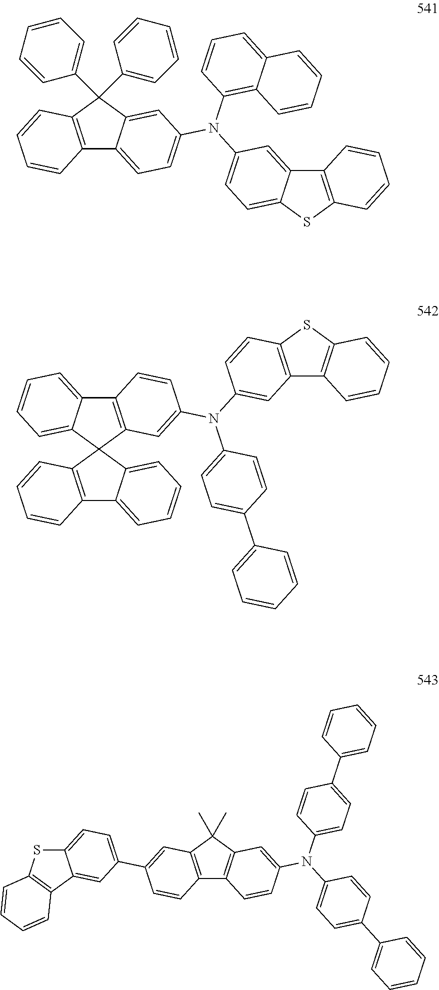 [SMILES: c1ccc(C2(c3ccccc3)c3ccccc3-c3ccc(N(c4ccc5sc6ccccc6c5c4)c4cccc5ccccc45)cc32)cc1 ; c1ccc(-c2ccc(N(c3ccc4c(c3)C3(c5ccccc5-c5ccccc53)c3ccccc3-4)c3ccc4sc5ccccc5c4c3)cc2)cc1 ; CC1(C)c2cc(-c3ccc4sc5ccccc5c4c3)ccc2-c2ccc(N(c3ccc(-c4ccccc4)cc3)c3ccc(-c4ccccc4)cc3)cc21]

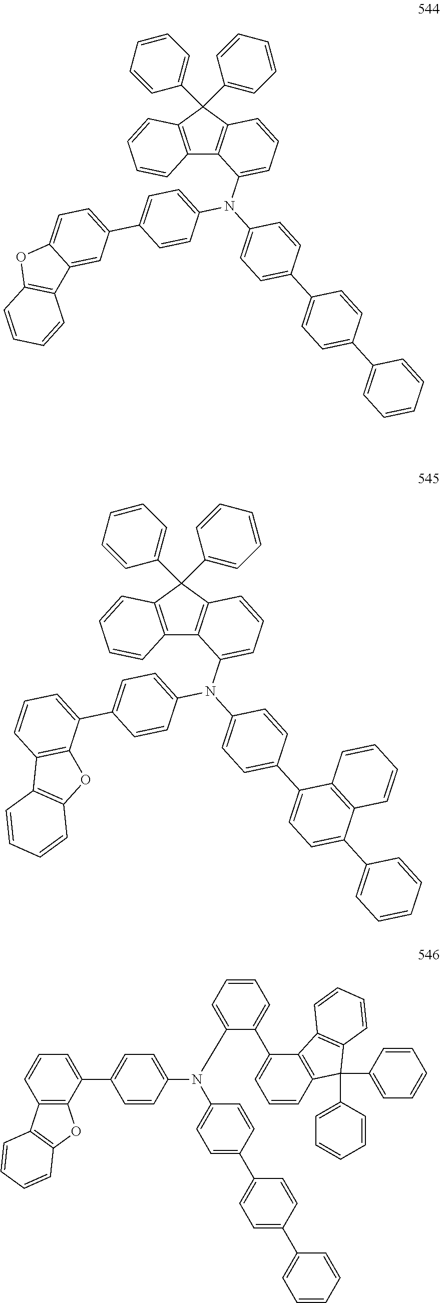 [SMILES: c1ccc(-c2ccc(-c3ccc(N(c4ccc(-c5ccc6oc7ccccc7c6c5)cc4)c4cccc5c4-c4ccccc4C5(c4ccccc4)c4ccccc4)cc3)cc2)cc1 ; c1ccc(-c2ccc(-c3ccc(N(c4ccc(-c5cccc6c5oc5ccccc56)cc4)c4cccc5c4-c4ccccc4C5(c4ccccc4)c4ccccc4)cc3)c3ccccc23)cc1 ; c1ccc(-c2ccc(-c3ccc(N(c4ccc(-c5cccc6c5oc5ccccc56)cc4)c4ccccc4-c4cccc5c4-c4ccccc4C5(c4ccccc4)c4ccccc4)cc3)cc2)cc1]

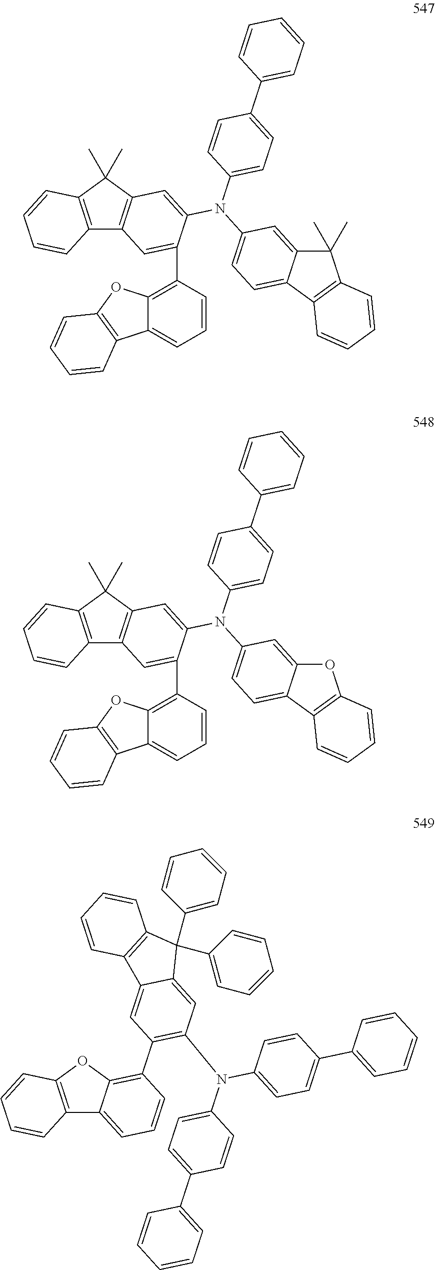 [SMILES: CC1(C)c2ccccc2-c2ccc(N(c3ccc(-c4ccccc4)cc3)c3cc4c(cc3-c3cccc5c3oc3ccccc35)-c3ccccc3C4(C)C)cc21 ; CC1(C)c2ccccc2-c2cc(-c3cccc4c3oc3ccccc34)c(N(c3ccc(-c4ccccc4)cc3)c3ccc4c(c3)oc3ccccc34)cc21 ; c1ccc(-c2ccc(N(c3ccc(-c4ccccc4)cc3)c3cc4c(cc3-c3cccc5c3oc3ccccc35)-c3ccccc3C4(c3ccccc3)c3ccccc3)cc2)cc1]

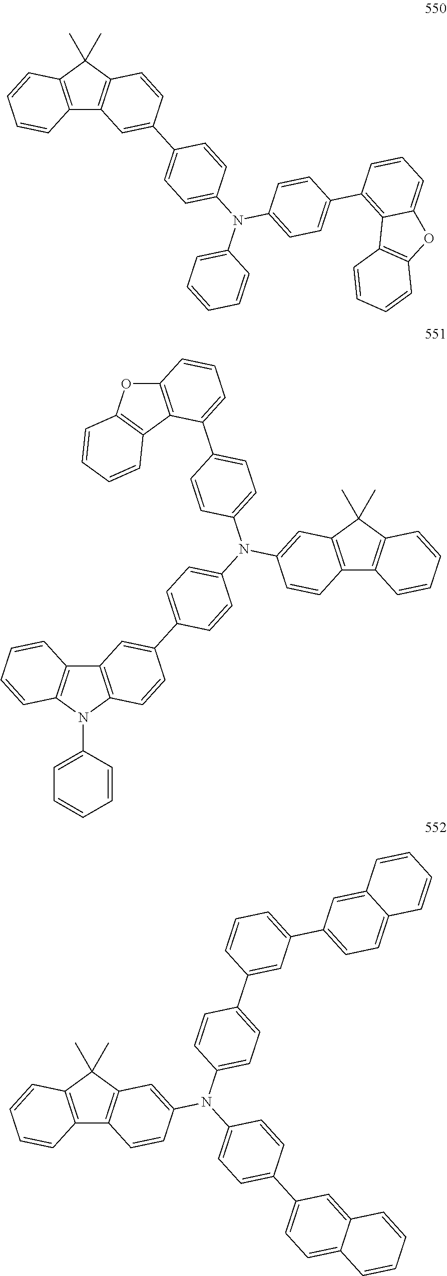 [SMILES: CC1(C)c2ccccc2-c2cc(-c3ccc(N(c4ccccc4)c4ccc(-c5cccc6oc7ccccc7c56)cc4)cc3)ccc21 ; CC1(C)c2ccccc2-c2ccc(N(c3ccc(-c4ccc5c(c4)c4ccccc4n5-c4ccccc4)cc3)c3ccc(-c4cccc5oc6ccccc6c45)cc3)cc21 ; CC1(C)c2ccccc2-c2ccc(N(c3ccc(-c4cccc(-c5ccc6ccccc6c5)c4)cc3)c3ccc(-c4ccc5ccccc5c4)cc3)cc21]

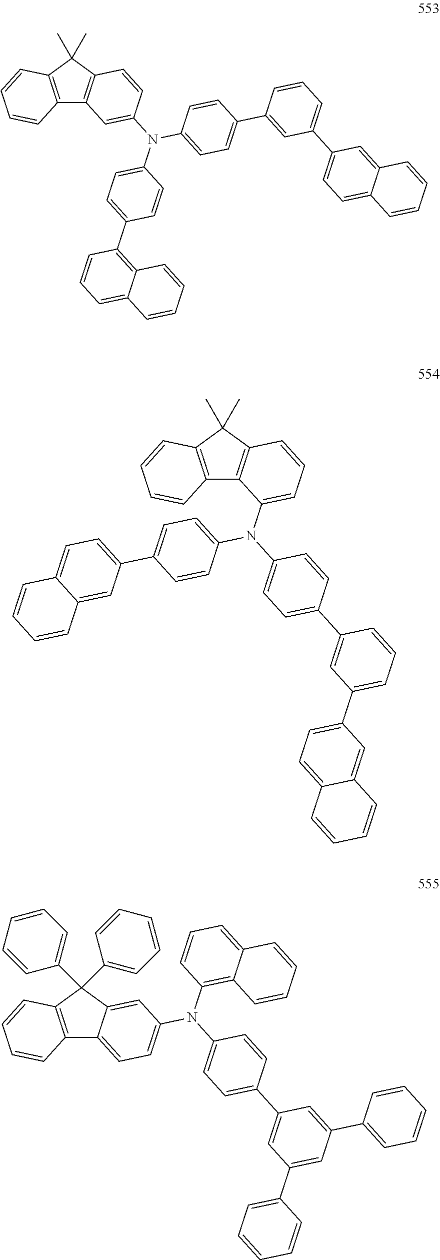 [SMILES: CC1(C)c2ccccc2-c2cc(N(c3ccc(-c4cccc(-c5ccc6ccccc6c5)c4)cc3)c3ccc(-c4cccc5ccccc45)cc3)ccc21 ; CC1(C)c2ccccc2-c2c(N(c3ccc(-c4cccc(-c5ccc6ccccc6c5)c4)cc3)c3ccc(-c4ccc5ccccc5c4)cc3)cccc21 ; c1ccc(-c2cc(-c3ccccc3)cc(-c3ccc(N(c4ccc5c(c4)C(c4ccccc4)(c4ccccc4)c4ccccc4-5)c4cccc5ccccc45)cc3)c2)cc1]

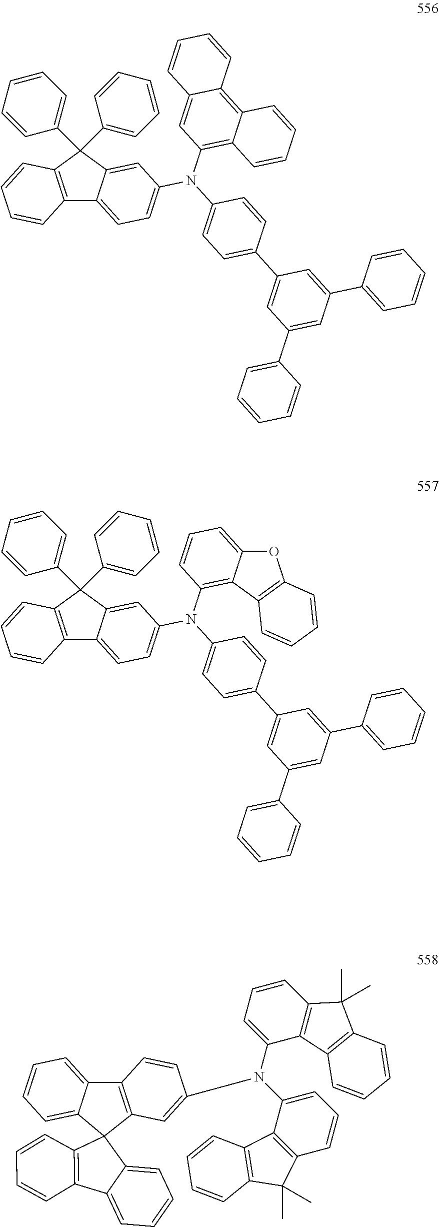 [SMILES: c1ccc(-c2cc(-c3ccccc3)cc(-c3ccc(N(c4ccc5c(c4)C(c4ccccc4)(c4ccccc4)c4ccccc4-5)c4cc5ccccc5c5ccccc45)cc3)c2)cc1 ; c1ccc(-c2cc(-c3ccccc3)cc(-c3ccc(N(c4ccc5c(c4)C(c4ccccc4)(c4ccccc4)c4ccccc4-5)c4cccc5oc6ccccc6c45)cc3)c2)cc1 ; CC1(C)c2ccccc2-c2c(N(c3ccc4c(c3)C3(c5ccccc5-c5ccccc53)c3ccccc3-4)c3cccc4c3-c3ccccc3C4(C)C)cccc21]

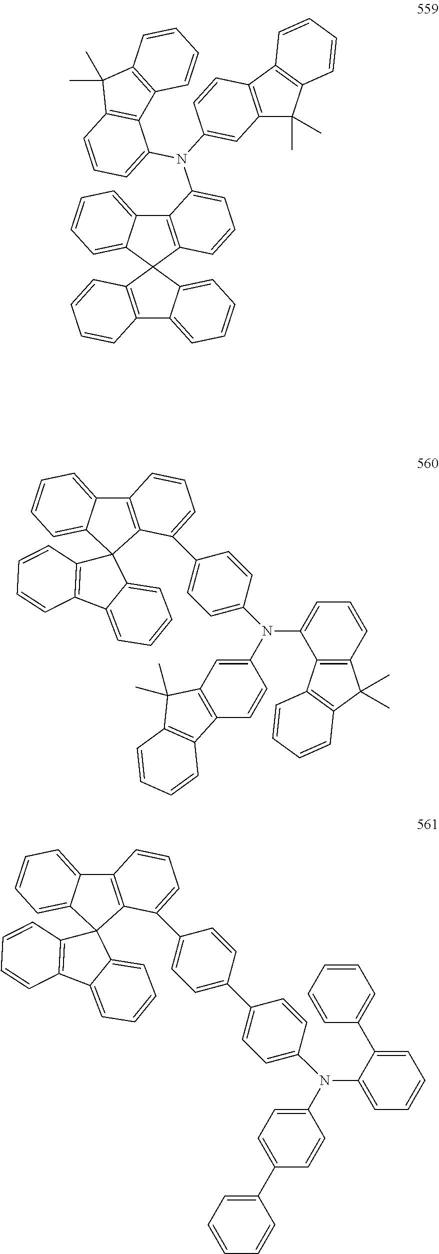 [SMILES: CC1(C)c2ccccc2-c2ccc(N(c3cccc4c3-c3ccccc3C4(C)C)c3cccc4c3-c3ccccc3C43c4ccccc4-c4ccccc43)cc21 ; CC1(C)c2ccccc2-c2ccc(N(c3ccc(-c4cccc5c4C4(c6ccccc6-c6ccccc64)c4ccccc4-5)cc3)c3cccc4c3-c3ccccc3C4(C)C)cc21 ; c1ccc(-c2ccc(N(c3ccc(-c4ccc(-c5cccc6c5C5(c7ccccc7-c7ccccc75)c5ccccc5-6)cc4)cc3)c3ccccc3-c3ccccc3)cc2)cc1]

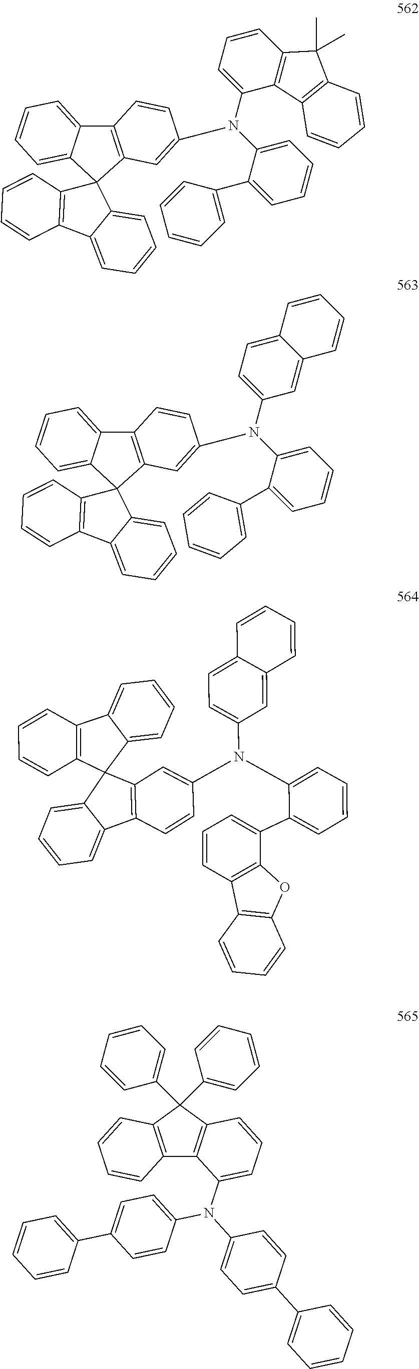 [SMILES: CC1(C)c2ccccc2-c2c(N(c3ccc4c(c3)C3(c5ccccc5-c5ccccc53)c3ccccc3-4)c3ccccc3-c3ccccc3)cccc21 ; c1ccc(-c2ccccc2N(c2ccc3c(c2)C2(c4ccccc4-c4ccccc42)c2ccccc2-3)c2ccc3ccccc3c2)cc1 ; c1ccc(N(c2ccc3c(c2)C2(c4ccccc4-c4ccccc42)c2ccccc2-3)c2ccc3ccccc3c2)c(-c2cccc3c2oc2ccccc23)c1 ; c1ccc(-c2ccc(N(c3ccc(-c4ccccc4)cc3)c3cccc4c3-c3ccccc3C4(c3ccccc3)c3ccccc3)cc2)cc1]

Processes for synthesis of hole-transport materials for the common hole-transport layer and the electron blocking layers are known in the prior art, especially in the publications cited in the table below:

| Structure type | Publication |
|---|---|
| Fluorenylamines | WO2007/072952, WO2013/118846, |
| | WO2016/006710, WO2019/168320, |
| | WO2019/216411, US2020/106017 |
| Spirobifluorenylamines | KR20140045154A, WO2012/034627, |
| | WO2013/120577, WO2016/199784, |
| | WO2016/078738, WO2017/016632, |
| | WO2017/102063, WO2017/102064, |
| | WO2017/061779, WO2017/133829, |
| | WO2017/144150, WO2019/168320 |
| | WO2019/002190 |
| Aminocarbazoles | WO2013/017192, WO2012/043531 |
| Phenanthreneamines | WO2017/022729 |

The electronic device is preferably selected from the group consisting of organic integrated circuits (OICs), organic field-effect transistors (OFETs), organic thin-film transistors (OTFTs), organic light-emitting transistors (OLETs), organic solar cells (OSCs), organic optical detectors, organic photoreceptors, organic field-quench devices (OFQDs), organic light-emitting electrochemical cells (OLECs), organic laser diodes (O-lasers) and organic electroluminescent devices (OLEDs). More preferably, the electronic device is an organic electroluminescent device.

Preferably, the common hole-transport layer c-HTL comprises at least one hole-transport material, preferably selected from compounds of formula (A), where the at least one hole-transport material in the c-HTL has a LUMO of from −1.40 eV to −1.80 eV, preferably of from −1.45 eV to −1.75 eV, more preferably of from −1.50 eV to −1.65 eV, even more preferbaly of from −1.55 eV to −1.65 eV and the hole-transport material has a HOMO of from −5.0 eV to −5.35 eV, preferably of from −5.05 eV to −5.25 eV, more preferably of from −5.10 eV to −5.20 eV, even more preferably of from −5.15 eV to −5.20 eV.

Preferably, the electron-blocking layers EBL₁, EBL₂ and/or EBL₃ comprise at least one hole-transport material, preferably selected from compounds of formula (A), where the at least one hole-transport material in EBL₁, EBL₂ and/or EBL₃ has a LUMO of from from −1.40 eV to −1.80 eV, preferably of from −1.45 eV to −1.75 eV, more preferably of from −1.50 eV to −1.65 eV, even more preferbaly of from −1.55 eV to −1.65 eV and the hole-transport material has a HOMO of from −5.0 eV to −5.35 eV, preferably of from −5.05 eV to −5.25 eV, more preferably of from −5.15 eV to −5.25 eV, even more preferably of from −5.15 eV to −5.20 eV.

In a preferred embodiment of the invention, the HOMO levels of the common hole-transport layer (c-HTL) and the adjacent electron-blocking layer (EBL) meet the following condition:

HOMO(c-HTL)≥HOMO(EBL), preferably HOMO(c-HTL)>HOMO(EBL),
which means that the HOMO of the c-HTL should be higher or equal, preferably higher than the HOMO of the EBL. What is meant by the expression “higher” HOMO in the context of the present application is that the value is less negative; for example, a HOMO of −5.2 eV is higher than a HOMO of −5.3 eV. In this way, it is possible to avoid a hole barrier and hence a voltage drop between the hole transport layer and the emitting layer. This is advantageously possible, for example, through the use of the same material in the hole transport layer and the further layer between the hole transport layer and emitting layer.

The HOMO and LUMO energies are determined by cyclic voltammetry as described in the experimental part below.

Hole-injection layers, hole-transport layers (like c-HTL), and electron-blocking layers (like EBL₁, EBL₂, EBL₃) are actually all hole-transporting layers. Hole-transporting layers are understood here to mean all layers disposed between the anode and the emitting laye like hole-injection layers, hole-transport layers, and electron-blocking layers. Preferably, a hole-injection layer is a layer that directly adjoins the anode. Preferably, a hole-transport layer is a layer which is between the anode and emitting layer but does not directly adjoin the anode, and preferably does not directly adjoin the emitting layer either. Preferably, the electron-blocking layer is a layer which is between the anode and emitting layer and directly adjoins the emitting layer. An electron-blocking layer preferably has a high-energy LUMO and hence prevents electrons from exiting from the emitting layer.

The common hole-transport layer c-HTL is a hole-transport layer, which preferably has a thickness of 50 to 150 nm, more preferably of 70 to 120 nm.

The electron-blocking layers EBL₁, EBL₂ and EBL₃ preferably have a thickness of 5 to 50 nm, more preferably of 15 to 35 nm. If the electron-blocking layer is a layer directly adjoining a green-phosphorescing emitting layer, it preferably has a thickness of 10 to 50 nm. If the electron-blocking layer is a layer directly adjoining a blue-fluorescing emitting layer, it preferably has a thickness of 5 to 30 nm.

Preferred cathodes of the electronic device are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

The emitting layers EML₁, EML₃, EML₃ are preferably selected from phosphorescent emitting layers and fluorescent emitting layers. A phosphorescent emitting layer preferably contains at least one matrix material and at least one phosphorescent emitter. A fluorescent emitting layer preferably contains at least one matrix material and at least one fluorescent emitter.

The emitting layer EML₁ has an emission maximum wavelength wavelength λ₁ and the emitting layer EML₂ has an emission maximum wavelength wavelength λ₂, where it is preferrer that:

$${1}_{} > {2}_{}$$

Preferably, the emitting layer EML₁ has an emission maximum wavelength λ₁ of from 430 to 500 nm. Preferably, the emitting layer EML₂ has an emission maximum wavelength λ₂ of from 500 to 660 nm, more preferably of from 500 to 580 nm. Preferably, the emitting layer EML₃ has an emission maximum wavelength λ₃ of from 580 to 660 nm.

More preferably, the emitting layer EML₁ is a blue-fluorescent emitting layer, the emitting layer EML₂ is a green-, orange- or red-phosphorescent emitting layer, preferably a green-emitting layer and the emitting layer EML₃ is an orange- or red-phosphorescent emitting layer.

In accordance with a preferred embodiment, the subpixels in the electroluminescent device according to the invention are placed in a side-by-side geometry, where it is preferred that one subpixel comprises a blue-emitting layer (B), one subpixel comprises a green-emitting layer (G) and one subpixel comprises a red-emitting layer (R). This is also called an RGB side-by-side arrangement.

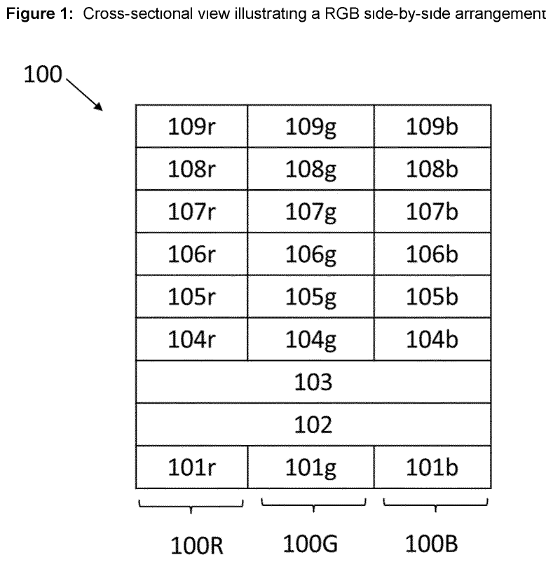

### FIG. 1: RGB Side-by-Side Arrangement

A particularly preferred example of such an arrangement 100 containing three subpixels is shown in FIG. 1. In this figure, the subpixels 100R, 100G and 100B are placed in a side-by-side arrangement. Layer 101r is the anode of the subpixel 100R, layer 101g is the anode of the subpixel 100G and layer 101b is the anode of the subpixel 100B. Layer 102 is a hole-injection layer, designed as a common layer and layer 103 is a hole-transport layer designed as a common layer. Layer 103 preferably corresponds to the common hole-transport layer c-HTL as described above. Layer 104r is the electron-blocking layer of the subpixel 100R, preferably corresponding to EBL₃ as defined above. Layer 104g is the electron-blocking layer of the subpixel 100G, preferably corresponding to EBL₂ as defined above. Layer 104b is the electron-blocking layer of the subpixel 100B, preferably corresponding to EBL₁ as defined above. Layer 105r is the emitting layer of the subpixel 100R, layer 105r is preferably a red-emitting layer. Layer 105g is the emitting layer of the subpixel 100G, layer 105g is preferably a green-emitting layer. Layer 105b is the emitting layer of the subpixel 100B, layer 105b is preferably a blue-emitting layer. Layer 106r is a hole-blocking layer of the subpixel 100R, layer 106g is a hole-blockingr layer of the subpixel 100G and layer 106b is a hole-blocking layer of the subpixel 100B. Layer 107r is an electron-transport layer of the subpixel 100R, layer 107g is an electron-transport layer of the subpixel 100G and layer 107b is an electron-transport layer of the subpixel 100B. Layer 108r is an electron-injection layer of the subpixel 100R, layer 108g is an electron-injection layer of the subpixel 100G and layer 108b is an electron-injection layer of the subpixel 100B. Layer 109r is the cathode of the subpixel 100R, layer 109g is the cathode of the subpixel 100G and 109 is the cathode of the subpixel 100B.

What is meant by a “common layer” here is that the layer contains the same material in all three layers of the arrangement. This preferably means that the layer is identical in all three subpixel in the arrangement, i.e. extends as one layer across all three subpixel in the arrangement.

The electronic devices of the arrangement shown in FIG. 1 may contain additional layers not shown in the figure.

More particularly, it is preferred that each subpixel comprises an anode, and that the anodes of the subpixels are laterally separated in a side-by-side geometry by an insulating layer.

An emitting layer of the electronic device may contain systems comprising one or more emitting compound(s) as dopant(s) and one or more of matrix material(s) (mixed matrix systems). When the emitting layer is a phosphorescent emitting layer, it is preferable that this layer contains two or more, preferably exactly two, different matrix materials.

Mixed matrix systems preferably comprise two or three different matrix materials, more preferably two different matrix materials. Preferably, in this case, one of the two materials is a material having hole-transporting properties and the other material is a material having electron-transporting properties. It is further preferable when one of the materials is selected from compounds having a large energy differential between HOMO and LUMO (wide-bandgap materials). The two different matrix materials may be present in a ratio of 1:50 to 1:1, preferably 1:20 to 1:1, more preferably 1:10 to 1:1 and most preferably 1:4 to 1:1. The desired electron-transporting and hole-transporting properties of the mixed matrix components may, however, also be combined mainly or entirely in a single mixed matrix component, in which case the further mixed matrix component(s) fulfil(s) other functions.

Preference is given to using the following material classes in emitting layers of the subpixels:

### Phosphorescent Emitters:

The term “phosphorescent emitters” typically encompasses compounds where the emission of light is effected through a spin-forbidden transition, for example a transition from an excited triplet state or a state having a higher spin quantum number, for example a quintet state.

Suitable phosphorescent emitters are especially compounds which, when suitably excited, emit light, preferably in the visible region, and also contain at least one atom of atomic number greater than 20, preferably greater than 38, and less than 84, more preferably greater than 56 and less than 80. Preference is given to using, as phosphorescent emitters, compounds containing copper, molybdenum, tungsten, rhenium, ruthenium, osmium, rhodium, iridium, palladium, platinum, silver, gold or europium, especially compounds containing iridium, platinum or copper.

In the context of the present invention, all luminescent iridium, platinum or copper complexes are considered to be phosphorescent compounds.

In general, all phosphorescent complexes as used for phosphorescent OLEDs according to the prior art and as known to those skilled in the art in the field of organic electroluminescent devices are suitable for use in the devices according to the application.

### Fluorescent Emitters:

Preferred fluorescent emitting compounds are selected from the class of the arylamines. An arylamine or an aromatic amine in the context of this invention is understood to mean a compound containing three substituted or unsubstituted aromatic or heteroaromatic ring systems bonded directly to the nitrogen. Preferably, at least one of these aromatic or heteroaromatic ring systems is a fused ring system, more preferably having at least 14 aromatic ring atoms. Preferred examples of these are aromatic anthraceneamines, aromatic anthracenediamines, aromatic pyreneamines, aromatic pyrenediamines, aromatic chryseneamines or aromatic chrysenediamines. An aromatic anthraceneamine is understood to mean a compound in which a diarylamino group is bonded directly to an anthracene group, preferably in the 9 position. An aromatic anthracenediamine is understood to mean a compound in which two diarylamino groups are bonded directly to an anthracene group, preferably in the 9,10 positions. Aromatic pyreneamines, pyrenediamines, chryseneamines and chrysenediamines are defined analogously, where the diarylamino groups are bonded to the pyrene preferably in the 1 position or 1,6 positions. Further preferred emitting compounds are indenofluoreneamines or -diamines, benzoindenofluoreneamines or -diamines, and dibenzoindenofluoreneamines or -diamines, and indenofluorene derivatives having fused aryl groups. Likewise preferred are pyrenearylamines. Likewise preferred are benzoindenofluoreneamines, benzofluoreneamines, extended benzoindenofluorenes, phenoxazines, and fluorene derivatives joined to furan units or to thiophene units.

### Matrix Materials for Fluorescent Emitters:

Preferred matrix materials for fluorescent emitters are selected from the classes of the oligoarylenes (e.g. 2,2′,7,7′-tetraphenylspirobifluorene), especially the oligoarylenes containing fused aromatic groups, the oligoarylenevinylenes, the polypodal metal complexes, the hole-conducting compounds, the electron-conducting compounds, especially ketones, phosphine oxides and sulfoxides; the atropisomers, the boronic acid derivatives or the benzanthracenes. Particularly preferred matrix materials are selected from the classes of the oligoarylenes comprising naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes comprising anthracene, benzanthracene, benzophenanthrene and/or pyrene or atropisomers of these compounds. An oligoarylene in the context of this invention shall be understood to mean a compound in which at least three aryl or arylene groups are bonded to one another.

### Matrix Materials for Phosphorescent Emitters:

Preferred matrix materials for phosphorescent emitters are aromatic ketones, aromatic phosphine oxides or aromatic sulfoxides or sulfones, triarylamines, carbazole derivatives, e.g. CBP (N,N-biscarbazolylbiphenyl), indolocarbazole derivatives, indenocarbazole derivatives, azacarbazole derivatives, bipolar matrix materials, silanes, azaboroles or boronic esters, triazine derivatives, zinc complexes, diazasilole or tetraazasilole derivatives, diazaphosphole derivatives, bridged carbazole derivatives, triphenylene derivatives, or lactams.

Apart from cathode, anode, emitting layer, layer HTL1 and layer HTL2, the electronic device may comprise further layers. These are selected, for example, from in each case one or more hole injection layers, hole transport layers, hole blocker layers, electron transport layers, electron injection layers, electron blocker layers, exciton blocker layers, interlayers, charge generation layers and/or organic or inorganic p/n junctions. However, it should be pointed out that not every one of these layers need necessarily be present and the choice of layers always depends on the compounds used and especially also on whether the device is a fluorescent or phosphorescent electroluminescent device.

The sequence of layers in the first subpixel is preferably as follows:
substrate,
anode,
optionally a hole-injection layer, preferably p-doped,
common hole-transport layer c-HTL
electron blocking layer EBL₁
emitting layer EML₁
optionally a hole-blocking layer,
an electron-transport layer,
optionally an electron-injection layer, and
a cathode.

The sequence of layers in the second subpixel is preferably as follows:
substrate,
anode,
optionally a hole-injection layer, preferably p-doped,
common hole-transport layer c-HTL
electron blocking layer EBL₂
emitting layer EML₂
optionally a hole-blocking layer,
an electron-transport layer,
optionally an electron-injection layer, and
a cathode.

The sequence of layers in the third subpixel is preferably as follows:
substrate,
anode,
optionally a hole-injection layer, preferably p-doped,
common hole-transport layer c-HTL
electron blocking layer EBL₃
emitting layer EML₃
optionally a hole-blocking layer,
an electron-transport layer,
optionally an electron-injection layer, and
a cathode.

However, further layers may additionally be present in the first, second and third subpixels.

In a preferred embodiment, the subpixels of the electronic device contain a common hole-injection layer disposed between the anode and the common hole-transport layer c-HTL, which is preferably directly adjoining the anode, and more preferably additionally directly adjoining layer c-HTL. The common hole-injection layer preferably conforms to one of the following embodiments: a) it contains a triarylamine and at least one p-dopant; or b) it contains a single electron-deficient material (electron acceptor). In a preferred embodiment of embodiment b), the electron-deficient material is a hexaazatriphenylene derivative as described in US 2007/0092755. It is further preferable that the layer contains, as the main component or sole component, a compound having a 4-substituted spirobifluorene group and an amino group, especially a compound having a spirobifluorene group 4-substituted by an amino group or an amino group bonded via an aromatic system. In a preferred embodiment, the main component is doped by a p-dopant. It is further preferable that the common hole-inection layer disposed between the anode and layer c-HTL contains a compound of formula (A) as defined above. Especially preferably, this common hole-injection layer directly adjoins the anode and layer c-HTL.

p-Dopants according to the present application are organic electron acceptor compounds. p-Dopants used are preferably those organic electron acceptor compounds capable of oxidizing one or more of the other compounds in the p-doped layer.

Particularly preferred as p-dopants are quinodimethane compounds, azaindenofluorenediones, azaphenalenes, azatriphenylenes, I₂, metal halides, preferably transition metal halides, metal oxides, preferably metal oxides comprising at least one transition metal or a metal from main group 3, and transition metal complexes, preferably complexes of Cu, Co, Ni, Pd and Pt with ligands containing at least one oxygen atom as binding site. Preference is further given to transition metal oxides as dopants, preferably oxides of rhenium, molybdenum and tungsten, more preferably Re₂O₇, MoO₃, WO₃ and ReO₃. Still further preference is given to complexes of bismuth in the (III) oxidation state, more particularly bismuth(III) complexes with electron-deficient ligands, more particularly carboxylate ligands.

The p-dopants are preferably in substantially homogeneous distribution in the p-doped layers. This can be achieved, for example, by co-evaporation of the p-dopant and the hole transport material matrix. The p-dopant is preferably present in a proportion of 1% to 10% in the p-doped layer.

Preferred p-dopants are especially the compounds shown in WO2021/104749 on pages 99-100 as (D-1) to (D-14).

In a preferred embodiment, each subpixel may have one or more further hole transport layers in addition to layer c-HTL. These may be present between the anode and layer c-HTL.

Compounds that are preferably used in further hole-transporting layers of the subpixels are indenofluoreneamine derivatives, amine derivatives, hexaazatriphenylene derivatives, amine derivatives with fused aromatic systems, monobenzoindenofluoreneamines, dibenzoindenofluoreneamines, spirobifluoreneamines, fluoreneamines, spirodibenzopyranamines, dihydroacridine derivatives, spirodibenzofurans and spirodibenzothiophenes, phenanthrenediarylamines, spirotribenzotropolones, spirobifluorenes having meta-phenyldiamine groups, spirobisacridines, xanthenediarylamines, and 9,10-dihydroanthracene spiro compounds having diarylamino groups.

Preferably, a subpixel present in the electronic device contains at least one electron transport layer. In addition, a subpixel here preferably contains at least one electron injection layer. The electron injection layer preferably directly adjoins the cathode. In a preferred embodiment, the electron transport layer contains a triazine derivative and lithium quinolinate. In a preferred embodiment, the electron injection layer contains a triazine derivative and lithium quinolinate. In a particularly preferred embodiment, the electron transport layer and/or the electron injection layer, most preferably the electron transport layer and the electron injection layer, contain a triazine derivative and lithium quinolinate (LiQ).

In a preferred embodiment, a subpixel here contains at least one hole blocker layer. This preferably has hole-blocking and electron-transporting properties, and directly adjoins this emitting layer on the cathode side in a device containing a single emitting layer. In a device comprising multiple emitting layers that are arranged in succession, the hole blocker layer directly adjoins those of the multiple emitting layers that are closest to the cathode on the cathode side.

Suitable electron-transporting materials are, for example, the compounds disclosed in Y. Shirota et al., Chem. Rev. 2007, 107(4), 953-1010, or other materials used in these layers according to the prior art.

Materials used for the electron transport layer may be any materials that are used as electron transport materials in the electron transport layer according to the prior art. Especially suitable are aluminium complexes, for example Alq₃, zirconium complexes, for example Zrq₄, lithium complexes, for example Liq, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives.

In a preferred embodiment, the electronic device is characterized in that one or more layers are applied by a sublimation process. In this case, the materials are applied by vapour deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

Preference is likewise given to an electronic device, characterized in that one or more layers are coated by the OVPD (organic vapour phase deposition) method or with the aid of a carrier gas sublimation. In this case, the materials are applied at a pressure between 10⁻⁵ mbar and 1 bar. A special case of this method is the OVJP (organic vapour jet printing) method, in which the materials are applied directly by a nozzle and thus structured (for example M. S. Arnold et al., Appl. Phys. Lett. 2008, 92, 053301).

Preference is additionally given to an electronic device, characterized in that one or more layers are produced from solution, for example by spin-coating, or by any printing method, for example screen printing, flexographic printing, nozzle printing or offset printing, but more preferably LITI (light-induced thermal imaging, thermal transfer printing) or inkjet printing.

It is further preferable that an electronic device according to the application is produced by applying one or more layers from solution and one or more layers by a sublimation method.

A preferred process for the production of an electronic device according to the invention is a process comprising the following steps:
a) Application of a common hole-transport layer c-HTL by a sublimation method;
b) Deposition of the electron-blocking layers EBL₁ and EBL₂, preferably of the electron-blocking layers EBL₁, EBL₂ and EBL₃, on the common hole-transport layer c-HTL by a sublimation method using a metal shadow mask technology.

After application of the layers, according to the use, the device is structured, contact-connected and finally sealed, in order to rule out damaging effects of water and air.

The electronic device may be used in displays, as light source in lighting applications, and as light source in medical and/or cosmetic applications.

### EXAMPLES

### 1. Method for Determining the Surface Charge Density (SCD)

### 1.1. Preparation of the Test Devices for SCD Measurements:

Glass plates with structured ITO (50 nm, indium tin oxide) form the substrates on which the OLEDs are processed. Before evaporation of the materials, the substrates are cleaned in a wet process (using filtered deionized water and the detergent “Extran” of Merck KGaA). Glass substrates are then dried for 15 minutes at 170° C. Subsequently the clean and dry substrates are exposed to an oxygen and subsequently to an argon plasma.

The structure of the test devices used for the SCD measurements is represented in Table 1. The anode is an ITO electrode, the HIL (Hole Injection Layer) has a thickness of 10 nm and consists in a mixture of HTM-7 and P-1 (95%:5%) (meaning HTM-7 is present in the layer in a proportion by weight of 95% and P-1 is present in the layer in a proportion by volume of 5%), the HTL (Hole Transport Layer) has a thickness of 100 nm and consists of HTM-7, the test layer has a thickness of 40 nm and consists of the investigated material and TMM-1 (x %:(100−x) %) and the cathode is a 100 nm thick aluminium electrode. The symbol x represents the concentration of the investigated material in the corresponding layer.

All materials are applied by thermal vapour deposition in a vacuum chamber. The structure of the materials used in these experiments are depicted in Table 2 below:

TABLE 1
Cross-sectional view illustrating a device used
for determination of surface charge density

Cathode
Test Layer
HTL
HIL
Anode

TABLE 2
Materials for SCD measurements

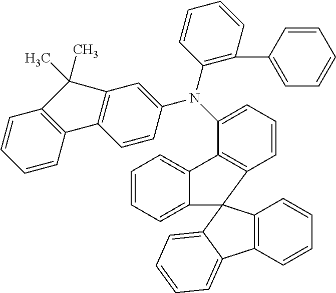 [SMILES: CC1(C)c2ccccc2-c2ccc(N(c3ccccc3-c3ccccc3)c3cccc4c3-c3ccccc3C43c4ccccc4-c4ccccc43)cc21]

HTM-7
(CAS 1450933-44-4)

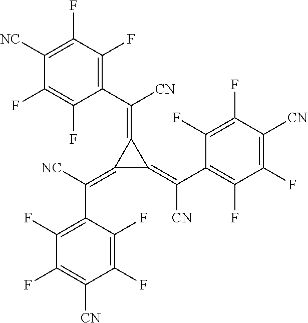 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

P-1
(CAS 1224447-88-4)

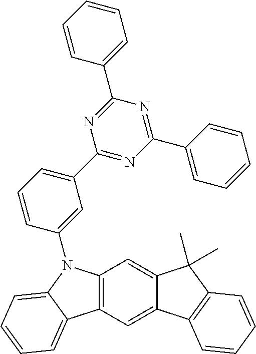 [SMILES: CC1(C)c2ccccc2-c2cc3c4ccccc4n(-c4cccc(-c5nc(-c6ccccc6)nc(-c6ccccc6)n5)c4)c3cc21]

TMM-1
(CAS 1257248-13-7)

### 1.2. Determination of the Build-In Voltage U_{bi}

All test devices for SCD measurements are characterized by standard current/voltage/luminance measurements (IUL measurements) assuming a Lambertian emission profile. For the analysis of SCDs, the build-in voltage U_{bi} is taken from the current/voltage characteristics.

### 1.3. Dielectric Spectroscopy Measurements

The Surface Charge Density of the investigated material in determined via dielectric spectroscopy measurements using an Alpha-NB Single-Unit Dielectric Analyzer (Novocontrol technologies) combined with a dielectric interface (Novocontrol ZGS). This setup allows frequency sweeps covering a range from f=10⁻² to f=10⁷ Hz. The AC rms voltage UAC is set to 100 mV for all measurements and the superimposed DC bias U_{DC} is varied between −7 and 7 V. The experimental capacity C-f-U_{DC} curves were analyzed according to the theoretical description in J. Appl. Phys. 107, 1-9 (2010) for Uₜᵣₐₙₛ and C_{SCD} with a fixed frequency f=10⁴ Hz in order to observe all necessary quantities for the final surface charge density SCD of the material under test:

$$SCD = \frac{{C}_{SCD}}{A} ( {U}_{trans} - {U}_{bi} )$$

As mentioned above, the build-in voltage Ubi is taken from the IUL measurements. “A” depicts the active electrode area of the OLED device. Final surface charge density for a material is calculated/extrapolated from a set of experiments where the concentration of the investigated material is x=0%, 10%, 20%, 30%.

### 2. Determination of the HOMO and LUMO Energies of the Materials by Cyclic Voltammetry

For Cyclic Voltammetry measurements, a potentiostat from Metronon μAUTOLAB type III in a three electrode setup is used including working-electrode (Au), counter electrode (Pt) and reference-electrode (Ag/AgCl, KCl 3M). Oxydation is measured in Methylenchloride (DCM) and reduction in Tetrahydrofuran (THF) and tetrabutylammonium hexafluorophosphate (0.11 M) is added as electrolyte. Ferrocene or decamethylferrocene are used as internal standard.

3. Results with Regard to Surface Charge Density, HOMO, LUMO of Selected Materials

The surface charge densities and electronic properties of some tested materials are shown in Table 3 below.

TABLE 3
SCD, HOMO

| Material | SCD (mC/m²) | HOMO CV (eV) |
|---|---|---|
| HTM-1 | 0 | −5.13 |
| HTM-2 | −0.38 | −5.18 |
| HTM-3 | 0.77 | −5.29 |
| HTM-4 | −0.35 | −5.20 |
| HTM-5 | −1.15 | −5.28 |
| HTM-6 | −0.46 | −5.23 |

### 4. Fabrication of OLEDs

Glass plates with structured ITO (50 nm, indium tin oxide) form the substrates on which the OLEDs are processed. Before evaporation of the materials, the substrates are cleaned in a wet process (using filtered deionized water and the detergent “Extran” of Merck KGaA). Glass substrates are then dried for 15 minutes at 170° C. Subsequently the clean and dry substrates are exposed to an oxygen and subsequently to an argon plasma.

Fully emitting side-by-side OLEDs were built, comprising two subpixels comprising two structured anodes and a common cathode as shown in Table 4. The hole injection layer (HIL) and then the hole transport layer (HTL) are successively deposited between the electrodes. Separated by fine metal masks, the electron block layers (EBL1 and EBL2), the emission layers (EML1 and EML2), the hole block layers (HBL1 and HBL2) and the electron transport layers (ETL1 and ETL2) are deposited. Finally, the cathode (aluminium) is vapour-deposited onto both OLEDs without fine metal masks.

### 5. Lateral Conductivity

Table 4 shows the general structure of side-by-side subpixels tested for lateral conductivity. The compounds used in HIL, HTL, EBL1 and EBL2 are varied as shown in Table 6. The layer EML1 consists of (TMM-1 (46%), TMM-3 (36%), TEG-1 (8%)). The layer EML2 consists of (TMM-2 (48.3%), HTM-8 (48.2%), TER-1 (3.5%)). The layer ETL1 and ETL2 consist of ETM-1 (50%) and LiQ (50%). EIL1 and EIL2 consist of LiQ (100%).

The structures of the materials used in EML1, EML2, ETL1 and ETL2 are shown in Table 7.

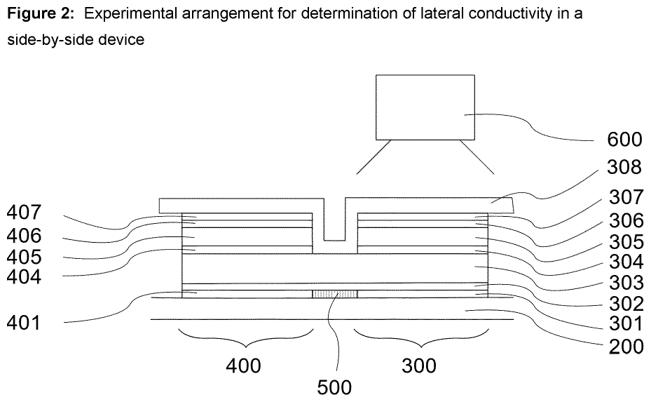

Lateral conductivity behavior is detected by optical signals. When the second subpixel of the side-by-side OLED is turned on, the emitted intensity of the first subpixel is measured as illustrated by the schematic experiment in FIG. 2. In FIG. 2, patterned ITO (301, 401) on a substrate (300) forms the anode for a first and a second subpixel (300, 400). An insulating layer (500) is present between the anodes. A common hole-injection layer is deposited (302), followed by the deposition on a common hole-transport layer (303). An electron blocking layer (304) is deposited on the first subpixel (300) and a electron blocking layer (404) is deposited on the second subpixel (400). An emissive layer (305) is deposited on the first subpixel (300) and an emissive layer (405) is deposited on the second subpixel (400). An electron transport layer (306) is deposited on the first subpixel (300) and an electron transport layer (406) is deposited on the second subpixel (400). An electron injection layer (307) is deposited on the first subpixel (300) and an electron injection layer (407) is deposited on the second subpixel (400). Finally, a cathode (308) is deposited on both subpixels. A detection unit (600) as described below is used to detect the optical signal due to lateral conductivity.

The optical signal of the first subpixel is detected using a photosensor module (Hamamatsu H7844), whose amplified signal (Femto HCA-200M-20K-C) is measured using an oscilloscope. The voltage read out on the oscilloscope is corrected with the voltage measured with the second subpixel switched-off. The corrected voltage is called the intensity level. A constant current density for operating the second subpixel of 50 mA/cm² is used for the measurement. Table 5 shows examples E1-E8, in which two different HTLs are combined with different HTMs in EBL1 and EBL2. The EBL2 materials varied in the second subpixel show different ICDs combined with the common HTL. With fixed optical detection settings for all measurements, the relative intensity level of 100% denotes the measured values of E1 (reference).

A measured intensity in the first subpixel is in general not acceptable for driving of a side-by-side OLED, since it leads to unwanted light emission in switched-off subpixels leading in turn to colorshifts. As Table 5 shows, the difference in ICDs between HTL1/EBL1 and HTL2/EBL2 clearly shows the advantage of a more positive ICD between HTL2 and EBL2 compared to HTL1/EBL1, which reduces the lateral conductivity and thus the emission of the first subpixel.

TABLE 4
General layout side-by-side OLED arrangement
for determination of lateral conductivity

| Cathode (Alu) | | | 100 | nm |
|---|---|---|---|---|
| | ETL1 | ETL2 | 30 | nm |
| | HBL1 | HBL2 | 5 | nm |
| | EML1 | EML2 | 40 | nm |
| | EBL1 | EBL2 | 20 | nm |
| HTL | | | 100 | nm |
| HIL | | | 20 | nm |
| | Anode1 (ITO) | Anode2 (ITO) | 50 | nm |

TABLE 5
Device properties in terms of lateral conductivities

| | | | | | Relative | |
|---|---|---|---|---|---|---|
| | | | | | emission | |
| | | | | | due to | |
| | | | | | side-by- | |
| | | | | | side lateral | ICD₂ − |
| | | | | | conduc- | ICD₁/ |
| | HIL | HTL | EBL1 | EBL2 | tivity | mC/m² |
| E1 | HTM-1:p1 (3%) | HTM-1 | HTM-4 | HTM-5 | 100% | −0.8 |
| E2 | HTM-1:p1 (3%) | HTM-1 | HTM-4 | HTM-6 | 40%-60% | −0.1 |
| E3 | HTM-1:p1 (3%) | HTM-1 | HTM-4 | HTM-2 | 40%-60% | −0.1 |
| E4 | HTM-1:p1 (3%) | HTM-1 | HTM-4 | HTM-4 | 10%-20% | 0 |
| E5 | HTM-2:p1 (3%) | HTM-2 | HTM-4 | HTM-3 | 0%-5% | +1.1 |
| E6 | HTM-2:p1 (3%) | HTM-2 | HTM-4 | HTM-1 | 5%-10% | +0.4 |
| E7 | HTM-2:p1 (3%) | HTM-2 | HTM-4 | HTM-4 | 10%-20% | 0 |
| E8 | HTM-2:p1 (3%) | HTM-2 | HTM-4 | HTM-5 | 100% | −0.8 |

TABLE 6
Molecular structures of the materials used HIL, HTL, EBL1
and EBL2

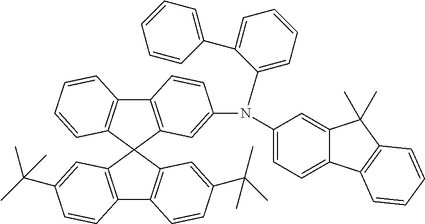 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

HTM-1
(WO2012/034627 A1)

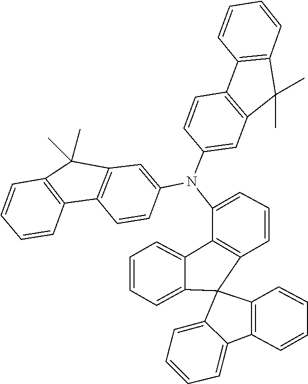 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21]

HTM-2
(WO2013/120577 A1)

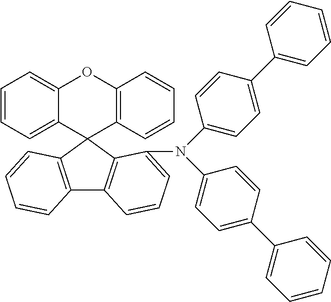 [SMILES: c1ccc(-c2ccc(N(c3ccc(-c4ccccc4)cc3)c3cccc4c3C3(c5ccccc5Oc5ccccc53)c3ccccc3-4)cc2)cc1]

HTM-3
(WO2014/072017 A1)

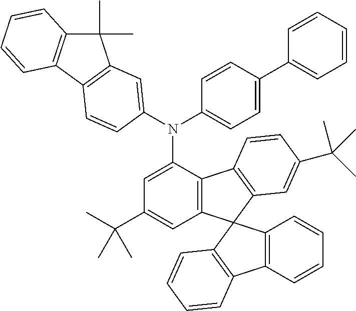 [SMILES: CC(C)(C)c1ccc2c(c1)C1(c3ccccc3-c3ccccc31)c1cc(C(C)(C)C)cc(N(c3ccc(-c4ccccc4)cc3)c3ccc4c(c3)C(C)(C)c3ccccc3-4)c1-2]

HTM-4
(WO2013/120577 A1)

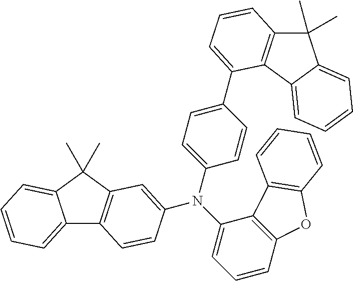 [SMILES: CC1(C)c2ccccc2-c2ccc(N(c3ccc(-c4cccc5c4-c4ccccc4C5(C)C)cc3)c3cccc4oc5ccccc5c34)cc21]

HTM-5
(WO2015/082056 A1)

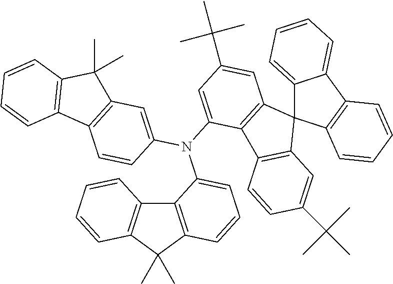 [SMILES: CC(C)(C)c1ccc2c(c1)C1(c3ccccc3-c3ccccc31)c1cc(C(C)(C)C)cc(N(c3ccc4c(c3)C(C)(C)c3ccccc3-4)c3cccc4c3-c3ccccc3C4(C)C)c1-2]

HTM-6
(WO2022/096172)

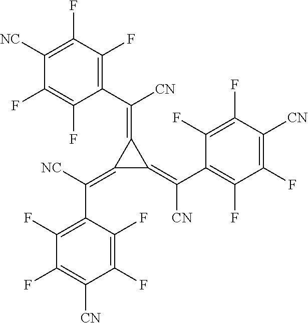 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

p-1
(CAS 1224447-88-4)

TABLE 7
Molecular structures of the materials used EML1, EML2, ETL1
and ETL2

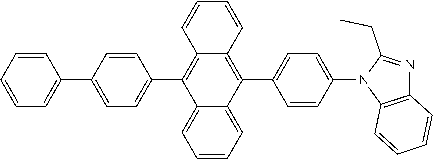 [SMILES: CCc1nc2ccccc2n1-c1ccc(-c2c3ccccc3c(-c3ccc(-c4ccccc4)cc3)c3ccccc23)cc1]

ETM-1
(CAS 1254961-38-0)

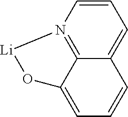

LiQ
(CAS 25387-93-3)

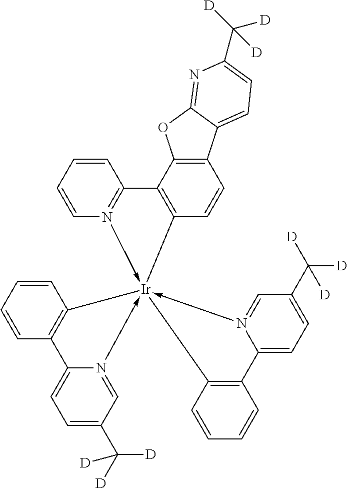

TEG-1
(CAS 1609368-32-2)

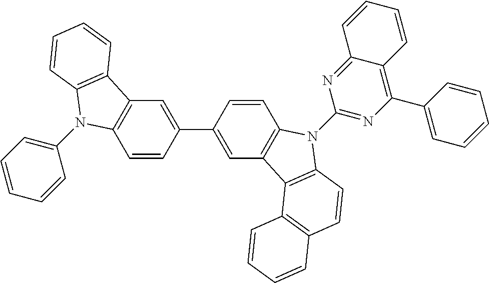 [SMILES: c1ccc(-c2nc(-n3c4ccc(-c5ccc6c(c5)c5ccccc5n6-c5ccccc5)cc4c4c5ccccc5ccc43)nc3ccccc23)cc1]

TMM-2
(CAS 1365548-87-3)

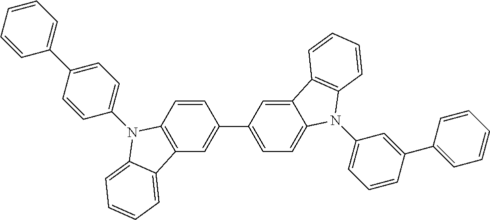 [SMILES: c1ccc(-c2ccc(-n3c4ccccc4c4cc(-c5ccc6c(c5)c5ccccc5n6-c5cccc(-c6ccccc6)c5)ccc43)cc2)cc1]

TMM-3
(CAS 1643479-47-3)

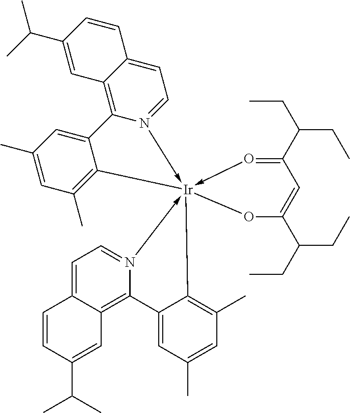

TER-1
(CAS 1643580-54-4)

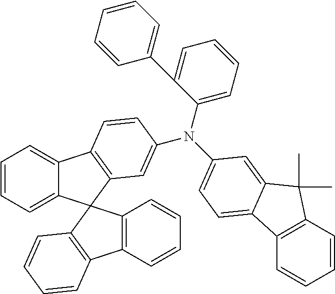 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

HTM-8
(CAS 1364603-07-5)

1. An electronic device comprising at least one pixel comprising:
a first subpixel comprising in the following sequence: an anode, at least one hole transport layer and an electron-blocking layer EBL₁,
a second subpixel comprising in the following sequence: an anode, at least one hole transport layer and an electron-blocking layer EBL₂,
where the at least one hole-transport layer in the first and second subpixel is a common hole-transport layer c-HTL, and the electron-blocking layer EBL₁ and layer EBL₂ adjoin the layer c-HTL, and
where the interface charge densities ICD₁ and ICD₂ fulfill the following conditions (1) and (2):
$$0 < {ICD}_{1} < 1. mC \cdot {m}^{- 2} \qquad ( 1 )$$
$$0 < {ICD}_{2} < 1. mC \cdot {m}^{- 2} \qquad ( 2 )$$
where
ICD₁ is the difference between the surface charge density of layer EBL₁ and the surface charge density of layer c-HTL;
ICD₂ is the difference between the surface charge density of the electron-blocking layer EBL₂ and the surface charge density of layer c-HTL; and
where the surface charge density of a layer is determined by dielectric spectroscopy measurements.

2. An electronic device according to claim 1, characterized in that the following condition (3) is fulfilled:
$${ICD}_{2} \geq {ICD}_{1} . \qquad ( 3 )$$

3. An electronic device according to claim 2, characterized in that the following condition (4) is fulfilled:
$$0 \leq {ICD}_{2} - {IDC}_{1} < 1. . \qquad ( 4 )$$

4. An electronic device according to claim 1, characterized in that the first subpixel comprising an electron-blocking layer EBL₁ also comprises an emitting layer EML₁ and the second subpixel comprising an electron-blocking layer EBL₂ also comprises an emitting layer EML₂.

5. An electronic device according to claim 4, characterized in that the first emitting layer EML₁ has an emission maximum wavelength λ₁ of from 430 to 500 nm.

6. An electronic device according to claim 5, characterized in that the emitting layer EML₂ has an emission maximum wavelength λ₂ of from 500 to 660 nm.

7. An electronic device according to claim 1, characterized in that the common hole-transport layer c-HTL comprises a hole-transport material selected from compounds of formula (A) 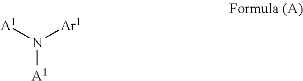
where:
A¹ is the same or different at each instance and is H, an alkyl group which has 1 to 20 carbon atoms and may be substituted by one or more R¹ radicals, or Ar¹;
Ar¹ is the same or different at each instance and is an aromatic ring system which has 6 to 60 aromatic ring atoms and may be substituted by one or more R¹ radicals, or a heteroaromatic ring system which has 5 to 60 aromatic ring atoms and may be substituted by one or more R¹ radicals; Ar¹ and/or A¹ groups here may be bonded to one another via R¹ radicals;
R¹ is the same or different at each instance and is selected from H, D, F, C(═O)R², CN, Si(R²)₃, P(═O)(R²)₂, OR², S(═O)R², S(═O)₂R², straight-chain alkyl or alkoxy groups having 1 to 20 carbon atoms, branched or cyclic alkyl or alkoxy groups having 3 to 20 carbon atoms, alkenyl or alkynyl groups having 2 to 20 carbon atoms, aromatic ring systems having 6 to 40 aromatic ring atoms, and heteroaromatic ring systems having 5 to 40 aromatic ring atoms; where two or more R¹ radicals may be joined to one another and may form a ring; where the alkyl, alkoxy, alkenyl and alkynyl groups mentioned and the aromatic ring systems and heteroaromatic ring systems mentioned may each be substituted by one or more R² radicals; and where one or more CH₂ groups in the alkyl, alkoxy, alkenyl and alkynyl groups mentioned may be replaced by —R²C═CR²—, —C≡C—, Si(R²)₂, C═O, C═NR², —C(═O)O—, —C(═O)NR²—, P(═O)(R²), —O—, —S—, SO or SO₂;
R² is the same or different at each instance and is selected from H, D, F, CN, alkyl groups having 1 to 20 carbon atoms, aromatic ring systems having 6 to 40 aromatic ring atoms and heteroaromatic ring systems having 5 to 40 aromatic ring atoms; where two or more R² radicals may be joined to one another and may form a ring; and where the alkyl groups, aromatic ring systems and heteroaromatic ring systems mentioned may be substituted by F or CN.

8. An electronic device according to claim 7, characterized in that the common hole-transport layer c-HTL comprises a hole-transport material selected from compounds of formula (A-I) to (A-IX): 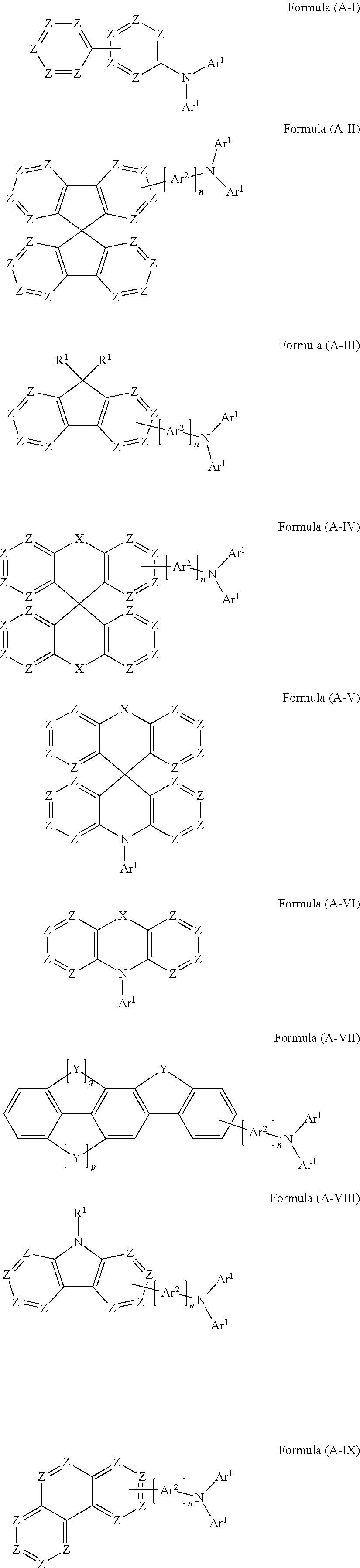
where one or more R¹ radicals may be bonded to any of the unsubstituted positions shown, and:
Z is the same or different at each instance and is CR¹ or N;
X is the same or different at each instance and is a single bond, O, S, C(R¹)₂, Si(R¹)₂, PR¹, C(R¹)₂—C(R¹)₂, or CR¹═CR¹;
Y is the same or different at each instance and is O, S, C(R¹)₂, Si(R¹)₂, PR¹, NR¹, C(R¹)₂—C(R¹)₂, or CR¹═CR¹;
Ar² is an aromatic ring system which has 6 to 20 aromatic ring atoms and may be substituted by one or more R¹ radicals, or a heteroaromatic ring system which has 5 to 20 aromatic ring atoms and may be substituted by one or more R¹ radicals;
n, p, q are the same or different and are each 0 or 1.

9. An electronic device according to claim 7, characterized in that the electron-blocking layers EBL₁ and EBL₂ comprise, identically or differently, a hole-transport material selected from compounds of formula (A).

10. An electronic device according to claim 1, characterized in that it comprises a third subpixel comprising an anode, at least one hole-transport layer and an electron-blocking layer EBL₃, where the at least one hole-transport layer in the third subpixel is the common hole-transport layer c-HTL as defined in claim 1 and where EBL₃ adjoins the layer c-HTL.

11. An electronic device according to claim 10, characterized in that the interface charge density ICD₃ fulfill the following condition (5):
$$0 < {ICD}_{3} < 1. mC \cdot {m}^{- 2} \qquad ( 5 )$$
where ICD₃ is the difference between the surface charge density of layer EBL₃ and the surface charge density of layer c-HTL.

12. An electronic device according to claim 11, characterized in that the following condition (6) is fulfilled:
$${ICD}_{3} \geq {ICD}_{1} . \qquad ( 6 )$$

13. An electronic device according to claim 12, characterized in that the following condition (7) is fulfilled:
$$0 \leq {ICD}_{3} - {IDC}_{1} < 1. . \qquad ( 7 )$$

14. An electronic device according to claim 11, characterized in that the third subpixel comprising an electron-blocking layer EBL₃ also comprises an emitting layer EML₃.

15. An electronic device according to claim 14, characterized in that the emitting layer EML₃ has an emission maximum wavelength λ₃ which is higher than an emission maximum wavelength λ₂ of the emitting layer EML₂ as follows:
$${3}_{} > {2}_{} .$$

16. An electronic device according to claim 14, characterized in that the third emitting layer EML₃ has an emission maximum wavelength λ₃ of from 580 to 660 nm.

17. An electronic device according to claim 10, characterized in that the subpixels present in the electronic device are placed in a side-by-side geometry.

18. An electronic device according to claim 1, characterized in that that each subpixel comprises in the following order:
the anode,
optionally a hole-injection layer,
the common hole-transport layer c-HTL,
the electron blocking layer EBL,
an emitting layer EML,
optionally a hole-blocking layer,
an electron-transport layer,
optionally an electron-injection layer, and
a cathode.

19. Process for the production of an electronic device according to claim 1, characterized in that the process comprises the following steps:
a) Application of a common hole-transport layer c-HTL by a sublimation method;
b) Deposition of the electron-blocking layers EBL₁ and EBL₂, on the common hole-transport layer c-HTL by a sublimation method using a metal shadow mask technology.

20. The electronic device according to claim 18, wherein the hole-injection layer is p-doped.
